(19) United States
(12) Patent Application Publication
(10) Pub. No.: US 2025/0098417 A1
(43) Pub. Date: Mar. 20, 2025

(54) SEMICONDUCTOR DEVICE AND METHOD FOR MANUFACTURING SEMICONDUCTOR DEVICE

(71) Applicant: Semiconductor Energy Laboratory Co., Ltd., Atsugi-shi (JP)

(72) Inventors: Masami JINTYOU, Shimotsuga (JP); Daisuke KUROSAKI, Utsunomiya (JP); Shiori TAMURA, Tochigi (JP); Junichi KOEZUKA, Tochigi (JP); Takahiro IGUCHI, Nikko (JP); Eiji SHIODA, Kanuma (JP)

(21) Appl. No.: 18/828,036

(22) Filed: Sep. 9, 2024

(30) Foreign Application Priority Data
Sep. 14, 2023 (JP) 2023-149375

(51) Int. Cl. H10K 59/121; H10K 59/12

(52) U.S. Cl. CPC H10K 59/1213; H10K 59/1201

(57) ABSTRACT

A semiconductor device includes first to third insulating layers and a transistor including a semiconductor layer, first to fourth conductive layers, and fourth to sixth insulating layers. The first conductive layer, the first insulating layer, the third conductive layer, the fifth insulating layer, the second insulating layer, the third insulating layer, and the second conductive layer overlap in this order. The first to third insulating layers and the second and third conductive layers include an opening reaching the first conductive layer. In the opening, the first insulating layer includes a protruding portion, and the fourth insulating layer is in contact with the top surface of the first insulating layer and side surfaces of the fifth insulating layer and the second insulating layer. The fifth insulating layer, an oxide of the third conductive layer, is in contact with top and side surfaces of the third conductive layer. The semiconductor layer is in contact with the top surfaces of the first and second conductive layers and a side surface of the fourth insulating layer. The sixth insulating layer is in contact with the top surface of the semiconductor layer. The fourth conductive layer is over and in contact with the sixth insulating layer to overlap with the opening.

### BACKGROUND OF THE INVENTION

### 1. Field of the Invention

One embodiment of the present invention relates to a transistor, a semiconductor device, a display device, a display module, and an electronic device. One embodiment of the present invention relates to a method for manufacturing a transistor, a method for manufacturing a semiconductor device, and a method for manufacturing a display device.

Note that one embodiment of the present invention is not limited to the above technical field. Examples of the technical field of one embodiment of the present invention include a semiconductor device, a display device, a light-emitting apparatus, a power storage device, a memory device, a lighting device, an input device (e.g., a touch sensor), an input/output device (e.g., a touch panel), an electronic device including any of them, a method for driving any of them, and a method for manufacturing any of them.

### 2. Description of the Related Art

Semiconductor devices including transistors have been widely used in display devices and electronic devices, and required to achieve increasingly high integration and high-speed operation. Highly integrated semiconductor devices are required for application to high-resolution display devices, for example. One way of increasing the degree of integration of transistors is the recent development of miniaturized transistors.

In recent years, there has been a need for display devices applicable to virtual reality (VR), augmented reality (AR), substitutional reality (SR), or mixed reality (MR). VR, AR, SR, and MR are collectively referred to as extended reality (XR). Display devices for XR have been expected to have higher resolution and higher color reproducibility such that realistic feeling and the sense of immersion can be enhanced. Examples of apparatuses that can be used as such display devices include a liquid crystal display device and a light-emitting apparatus including a light-emitting device (also referred to as a light-emitting element) such as an organic electroluminescent (EL) device or a light-emitting diode (LED).

Patent Document 1 discloses a display device using an organic EL device (also referred to as organic EL element) for VR.

### REFERENCE

[Patent Document 1] International Publication No. WO2018/087625

### SUMMARY OF THE INVENTION

For higher integration of a semiconductor device, further reduction in size of transistors included in the semiconductor device is required. In the case where a semiconductor device is used in a display device, an electronic device, and the like, the semiconductor device is required to have higher speed. In view of the above, an object of one embodiment of the present invention is to provide a semiconductor device including a miniaturized transistor and a method for manufacturing the semiconductor device. Another object of one embodiment of the present invention is to provide a small-sized semiconductor device and a method for manufacturing the semiconductor device. Another object of one embodiment of the present invention is to provide a semiconductor device including a transistor with high on-state current and a method for manufacturing the semiconductor device. Another object of one embodiment of the present invention is to provide a semiconductor device having favorable electrical characteristics and a method for manufacturing the semiconductor device. Another object of one embodiment of the present invention is to provide a semiconductor device with high reliability and a method for manufacturing the semiconductor device. Another object of one embodiment of the present invention is to provide a method for manufacturing a semiconductor device with high productivity. Another object of one embodiment of the present invention is to provide a novel semiconductor device and a method for manufacturing the semiconductor device.

Note that the description of these objects does not preclude the existence of other objects. One embodiment of the present invention does not necessarily achieve all of these objects. Other objects can be derived from the description of the specification, the drawings, the claims, and the like.

One embodiment of the present invention is a semiconductor device including a transistor, a first insulating layer, a second insulating layer, and a third insulating layer. The transistor includes a semiconductor layer, a first conductive layer, a second conductive layer, a third conductive layer, a fourth conductive layer, a fourth insulating layer, a fifth insulating layer, and a sixth insulating layer. The first conductive layer, the first insulating layer, the third conductive layer, the fifth insulating layer, the second insulating layer, the third insulating layer, and the second conductive layer are stacked in this order and overlap with one another. The first insulating layer, the third conductive layer, the second insulating layer, the third insulating layer, and the second conductive layer include an opening reaching the first conductive layer. The first insulating layer includes a portion protruding in the opening more than a side surface of the third conductive layer, a side surface of the second insulating layer, a side surface of the third insulating layer, and a side surface of the second conductive layer. The fifth insulating layer is in contact with a top surface of the third conductive layer and side surfaces including the side surface of the third conductive layer. The fourth insulating layer is in contact with a top surface of the first insulating layer in the opening, a side surface of the fifth insulating layer in the opening, and the side surface of the second insulating layer in the opening. The semiconductor layer is in contact with a top surface of the first conductive layer in the opening, a side surface of the fourth insulating layer in the opening, and a top surface of the second conductive layer. The sixth insulating layer is in contact with a top surface of the semiconductor layer. The fourth conductive layer is placed over the sixth insulating layer to overlap with the opening in a plan view. The third conductive layer includes a first element. The fifth insulating layer includes an oxide of the first element.

In the above embodiment, it is preferable that the semiconductor layer include a metal oxide; the metal oxide include two or three selected from indium, an element M, and zin; the element M include one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium; and the fourth insulating layer include silicon oxide or silicon oxynitride.

In the above embodiment, it is preferable that the third conductive layer include aluminum and the fifth insulating layer include aluminum oxide.

In the above embodiment, it is preferable that the first insulating layer and the third insulating layer each include silicon nitride, silicon nitride oxide, hafnium oxide, or aluminum oxide; and the second insulating layer include silicon oxide or silicon oxynitride.

Another embodiment of the present invention is a semiconductor device including a transistor, a first insulating layer, a second insulating layer, and a third insulating layer. The transistor includes a semiconductor layer, a first conductive layer, a second conductive layer, a third conductive layer, a fourth insulating layer, a fifth insulating layer, and a sixth insulating layer. The first conductive layer, the first insulating layer, the second conductive layer, the fifth insulating layer, the second insulating layer, and the third insulating layer are stacked in this order and overlap with one another. The first insulating layer, the second conductive layer, the second insulating layer, and the third insulating layer include an opening reaching the first conductive layer. The first insulating layer includes a portion protruding in the opening more than a side surface of the second conductive layer, a side surface of the second insulating layer, and a side surface of the third insulating layer. The fifth insulating layer is in contact with a top surface of the second conductive layer and side surfaces including the side surface of the second conductive layer. The fourth insulating layer is in contact with a top surface of the first insulating layer in the opening, a side surface of the fifth insulating layer in the opening, and the side surface of the second insulating layer in the opening. The semiconductor layer is in contact with a top surface of the first conductive layer in the opening, a side surface of the fourth insulating layer in the opening, and a top surface of the third insulating layer. The sixth insulating layer is in contact with a top surface of the semiconductor layer. The third conductive layer is placed over the sixth insulating layer to overlap with the opening in a plan view. The second conductive layer includes a first element. The fifth insulating layer includes an oxide of the first element.

In the above embodiment, it is preferable that the semiconductor layer include a metal oxide; the metal oxide include two or three selected from indium, an element M, and zin; the element M include one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium; and the fourth insulating layer include silicon oxide or silicon oxynitride.

In the above embodiment, it is preferable that the second conductive layer include aluminum and the fifth insulating layer include aluminum oxide.

In the above embodiment, it is preferable that the first insulating layer and the third insulating layer each include silicon nitride, silicon nitride oxide, hafnium oxide, or aluminum oxide; and the second insulating layer include silicon oxide or silicon oxynitride.

Another embodiment of the present invention is a method for manufacturing a semiconductor device, including the steps of forming a first conductive layer; forming a first insulating film over the first conductive layer; forming a second conductive layer over the first insulating film to include a region overlapping with the first conductive layer; oxidizing a surface of the second conductive layer, thereby forming a first insulating layer on a top surface and a side surface of the second conductive layer; forming a second insulating film, a third insulating film, and a third conductive layer in this order over the first insulating film and the first insulating layer; partly removing the third conductive layer, the third insulating film, the second insulating film, the first insulating layer, and the second conductive layer, thereby forming a first opening and forming a fourth conductive layer, a second insulating layer, a third insulating layer, a fourth insulating layer, and a fifth conductive layer; oxidizing a side surface of the fifth conductive layer exposed in the first opening, thereby forming the fourth insulating layer on the side surface of the fifth conductive layer; forming a fourth insulating film in contact with a top surface of the fourth conductive layer, a side surface of the fourth conductive layer in the first opening, a side surface of the second insulating layer in the first opening, a side surface of the third insulating layer in the first opening, a side surface of the fourth insulating layer in the first opening, and a top surface of the first insulating film in the first opening; partly removing the fourth insulating film and the first insulating film, thereby forming a second opening reaching the first conductive layer and forming a fifth insulating layer including a protruding portion in the second opening and a sixth insulating layer in contact with the side surface of the fourth conductive layer in the second opening, the side surface of the second insulating layer in the second opening, the side surface of the third insulating layer in the second opening, the side surface of the fourth insulating layer in the second opening, and a top surface of the protruding portion in the second opening; forming a semiconductor layer in contact with the top surface of the fourth conductive layer, a side surface of the sixth insulating layer in the second opening, and a top surface of the first conductive layer in the second opening; forming a seventh insulating layer in contact with a top surface and a side surface of the semiconductor layer, the top surface of the fourth conductive layer, and a top surface of the second insulating layer; and forming, over the seventh insulating layer, a sixth conductive layer including a region overlapping with the semiconductor layer and the sixth insulating layer in a plan view.

In the above embodiment, it is preferable that part of the first insulating film be removed when the first opening is formed, thereby forming an eighth insulating layer including a recess portion in a region overlapping with the first opening.

One embodiment of the present invention can provide a semiconductor device including a miniaturized transistor and a method for manufacturing the semiconductor device. Another embodiment of the present invention can provide a small-sized semiconductor device and a method for manufacturing the semiconductor device. Another embodiment of the present invention can provide a semiconductor device including a transistor with high on-state current and a method for manufacturing the semiconductor device. Another embodiment of the present invention can provide a semiconductor device having favorable electrical characteristics and a method for manufacturing the semiconductor device. Another embodiment of the present invention can provide a semiconductor device with high reliability and a method for manufacturing the semiconductor device. Another embodiment of the present invention can provide a method for manufacturing a semiconductor device with high productivity. Another embodiment of the present invention can provide a novel semiconductor device and a method for manufacturing the semiconductor device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings,

FIG. 1A is a plan view illustrating an example of a semiconductor device, and FIG. 1B is a cross-sectional view illustrating an example of a semiconductor device;

FIG. 2 is a cross-sectional view illustrating an example of a semiconductor device;

FIGS. 3A to 3D are cross-sectional views illustrating examples of a semiconductor device;

FIGS. 4A and 4B are cross-sectional views illustrating examples of semiconductor devices;

FIGS. 5A and 5B are cross-sectional views illustrating examples of semiconductor devices;

FIGS. 6A and 6B are cross-sectional views illustrating examples of semiconductor devices;

FIGS. 7A to 7D are cross-sectional views illustrating an example of a method for manufacturing a semiconductor device;

FIGS. 8A to 8C are cross-sectional views illustrating an example of a method for manufacturing a semiconductor device;

FIGS. 9A to 9D are cross-sectional views illustrating an example of a method for manufacturing a semiconductor device;

FIGS. 10A to 10C are cross-sectional views illustrating an example of a method for manufacturing a semiconductor device;

FIG. 11 is a perspective view illustrating an example of a display device;

FIG. 12 is a cross-sectional view illustrating an example of a display device;

FIG. 13 is a cross-sectional view illustrating an example of a display device;

FIG. 14 is a cross-sectional view illustrating an example of a display device;

FIG. 15 is a cross-sectional view illustrating an example of a display device;

FIG. 16 is a cross-sectional view illustrating an example of a display device;

FIGS. 17A and 17B illustrate a structure example of a display device;

FIG. 18 illustrates a structure example of a display device;

FIG. 19 illustrates a structure example of a display device;

FIG. 20 illustrates a structure example of a display device;

FIG. 21 is a block diagram of a display device;

FIGS. 22A to 22D are circuit diagrams of pixel circuits;

FIGS. 23A to 23D are circuit diagrams of pixel circuits;

FIGS. 24A and 24B are circuit diagrams of pixel circuits;

FIGS. 25A to 25D illustrate examples of electronic devices;

FIGS. 26A to 26F illustrate examples of electronic devices; and

FIGS. 27A to 27G illustrate examples of electronic devices.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the present invention described below, the same portions or portions having similar functions are denoted by the same reference numerals in different drawings, and the description thereof is not repeated. The same hatching pattern is used for portions having similar functions, and the portions are not denoted by specific reference numerals in some cases.

Note that the position, size, range, or the like of each component illustrated in drawings is not accurately represented in some cases for easy understanding. Therefore, the disclosed invention is not necessarily limited to the position, size, range, or the like disclosed in the drawings.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

A transistor is a kind of semiconductor element and enables amplification of current or voltage, switching operation for controlling conduction or non-conduction, and the like. A transistor in this specification and the like includes, in its category, an insulated-gate field effect transistor (IGFET) and a thin film transistor (TFT).

The functions of a “source” and a “drain” are sometimes replaced with each other when a transistor of opposite polarity is used or when the direction of current flow is changed in circuit operation, for example. Thus, the terms “source” and “drain” can be used interchangeably in this specification and the like. Note that the source and the drain of a transistor can also be referred to as a source terminal and a drain terminal or a source electrode and a drain electrode, for example, as appropriate depending on the situation.

A “gate” and a “back gate” can be interchanged with each other. Thus, the terms “gate” and “back gate” can be used interchangeably in this specification and the like. Note that the gate and the back gate of a transistor can also be referred to as a gate electrode and a back gate electrode, for example, as appropriate depending on the situation.

In this specification and the like, the term “connection” includes “electrical connection”.

The expression “A and B are electrically connected” means that, in the case where A and B are connected not through an insulator (i.e., connected through a conductor or a semiconductor or in contact with each other), transmission and reception of an electric signal or interaction of a potential occurs between A and B in a certain period in operation of a circuit including A and B. In other words, even when the circuit operation has a period during which neither transmission and reception of an electric signal nor interaction of a potential occurs between A and B, the expression “A and B are electrically connected” can be used as long as transmission and reception of an electric signal or interaction of a potential occurs between A and B in another period.

The term “electrical connection” includes direct connection that is connection not through a circuit element (e.g., a transistor, with the exception of a wiring) and indirect connection that is connection through at least one circuit element.

Examples of the expression “A and B are electrically connected” include the case where A and B are connected not through a circuit element, and the case where A and B are connected through a source and a drain of at least one transistor, assuming that transmission and reception of an electric signal or interaction of a potential occurs between A and B in a certain period.

Examples of the case where the expression “A and B are electrically connected” cannot be used because A and B are connected through an insulator include the case where a dielectric of a capacitor, a gate insulating film of a transistor, or the like is positioned between A and B.

Examples of the case where the expression “A and B are electrically connected” cannot be used because neither transmission and reception of an electric signal nor interaction of a potential occurs between A and B although A and B are connected not through an insulator include the case where a potential V is supplied from a power source, a signal source, or the like to the path between A and B (except for the case where the potential V is supplied through a circuit element), and the case where A and C are connected through a source and a drain of a transistor TrP and B and C are connected through a source and a drain of a transistor TrQ, but both of the transistors TrP and TrQ are not in the on state at the same time.

In this specification and the like, a structure in which at least light-emitting layers of light-emitting devices having different emission wavelengths are separately formed is sometimes referred to as a side-by-side (SBS) structure. The SBS structure can optimize materials and structures of light-emitting devices and thus can extend freedom of choice of materials and structures, whereby the luminance and the reliability can be easily improved.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that the above-described carrier-injection layer, carrier-transport layer, and carrier-blocking layer cannot be distinguished from each other depending on the cross-sectional shape or properties in some cases. One layer may have two or three functions of the carrier-injection layer, the carrier-transport layer, and the carrier-blocking layer in some cases.

In this specification and the like, a light-emitting device includes an EL layer between a pair of electrodes. The EL layer includes at least a light-emitting layer. Examples of layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a light-receiving device (also referred to as a light-receiving element) includes at least an active layer functioning as a photoelectric conversion layer between a pair of electrodes.

In this specification and the like, a tapered shape refers to a shape such that at least part of a side surface of a component is inclined with respect to the substrate surface or the formation surface. For example, a tapered shape refers to a shape including a region where the angle between the inclined side surface and the substrate surface or the formation surface of the component (such an angle is also referred to as a taper angle) is less than 90°. Note that the side surface of the component, the substrate surface, and the formation surface are not necessarily completely flat and may be substantially flat with a slight curvature or with slight unevenness.

In this specification and the like, step disconnection refers to a phenomenon in which a layer, a film, or an electrode is split because of the shape of the formation surface (e.g., a step).

In this specification and the like, the expression “having substantially the same top surface shapes” means that the outlines of stacked layers at least partly overlap with each other. For example, the case of patterning or partly patterning an upper layer and a lower layer with the use of the same mask pattern is included. The expression “having substantially the same top surface shapes” also includes the case where the outlines do not completely overlap with each other in some cases; for instance, the edge of the upper layer may be positioned on the inner side or the outer side of the edge of the lower layer.

Note that in this specification and the like, a top surface shape of a component means an outline shape of the component in a plan view. A plan view means that the component is observed from a direction normal to a surface where the component is formed or from a direction normal to a surface of a support (e.g., a substrate) where the component is formed.

In this specification and the like, the expression “substantially level with each other” indicates components having substantially the same level from a reference surface (e.g., a flat surface such as a substrate surface) in a cross-sectional view. For example, surfaces processed by planarization treatment (typically, chemical mechanical polishing (CMP) treatment) are substantially level with each other. Although surfaces processed by planarization treatment are not exactly level with each other in some cases depending on materials of films or the like, such a case is also expressed as “substantially level with each other” in this specification and the like.

### Embodiment 1

In this embodiment, a transistor of one embodiment of the present invention, a method for manufacturing the transistor, and the like will be described.

One embodiment of the present invention is a semiconductor device including a transistor, a first insulating layer, a second insulating layer, and a third insulating layer.

The transistor is a vertical transistor in which a source electrode and a drain electrode are provided at different levels from a substrate surface to overlap with each other and a drain current flows in the height direction (vertical direction). Thus, the transistor can achieve miniaturization and reduction in area, as compared with a planar transistor in which a source electrode and a drain electrode are provided on the same plane. The transistor having the above-described structure enables miniaturization and high integration of the semiconductor device.

The transistor includes a first gate electrode provided to sandwich a semiconductor layer functioning as a channel formation region and a second gate electrode (also referred to as a back gate electrode). Specifically, the first gate electrode is provided to be surrounded by the semiconductor layer in a plan view, and the second gate electrode is provided to surround the semiconductor layer in the plan view. Thus, a gate electric field can be applied from both surfaces of the semiconductor layer to carriers in the channel formation region. Accordingly, an on-state current higher than that of a transistor including only one gate electrode can be achieved. A low off-state current can be achieved. The threshold voltage can be shifted so that the transistor is normally off. Saturation characteristics of current flowing when the transistor operates in a saturation region can be improved (i.e., the amount of drain current hardly changes with respect to an increase in drain voltage).

The first insulating layer, the second insulating layer, and the third insulating layer are provided in this order when seen from the substrate side. The first insulating layer, the second insulating layer, and the third insulating layer each include a region overlapping with the source electrode, the drain electrode, and the second gate electrode of the transistor.

Specifically, in the region, the first insulating layer is provided over one of the source electrode and the drain electrode of the transistor. The second gate electrode of the transistor is provided over the first insulating layer. The second insulating layer is provided over the second gate electrode of the transistor. The third insulating layer is provided over the second insulating layer. The other of the source electrode and the drain electrode of the transistor is provided over the third insulating layer.

The second insulating layer is formed using a material that contains oxygen and releases oxygen by heat treatment or the like. Meanwhile, each of the first insulating layer and the third insulating layer is formed using a material having a blocking property against a gas such as oxygen and hydrogen. Thus, oxygen contained in the second insulating layer can be inhibited from diffusing below the second insulating layer (to the substrate side) through the first insulating layer. Furthermore, oxygen contained in the second insulating layer can be inhibited from diffusing above the second insulating layer through the third insulating layer.

The second gate electrode of the transistor includes an insulating layer (a fourth insulating layer) formed of an oxide of an element that is included in the second gate electrode, along the top surface and a side surface of the second gate electrode. Like the first insulating layer and the third insulating layer, the fourth insulating layer has a blocking property against a gas such as oxygen and hydrogen. The fourth insulating layer can be formed, for example, by performing plasma treatment on a surface of a conductive layer to be the second gate electrode in an oxygen-containing atmosphere to oxidize part of the conductive layer. Thus, the insulating layer having a function similar to those of the first and third insulating layers can be formed without using a deposition method such as a plasma CVD method or a sputtering method, for example; hence, the number of times of employing the above-described deposition method can be reduced. As described above, the second insulating layer is provided over the second gate electrode of the transistor. Accordingly, oxygen contained in the second insulating layer can be inhibited from diffusing into the second gate electrode through the fourth insulating layer.

The first insulating layer, the second gate electrode, the second insulating layer, the third insulating layer, and the other of the source electrode and the drain electrode of the transistor include an opening reaching the one of the source electrode and the drain electrode in a region overlapping with the one of the source electrode and the drain electrode. In the opening, the first insulating layer preferably includes a portion protruding more than a side surface of the second gate electrode, a side surface of the second insulating layer, a side surface of the third insulating layer, and a side surface of the other of the source electrode and the drain electrode.

A gate insulating layer (also referred to as a first gate insulating layer, or a back gate insulating layer because of corresponding to the second gate electrode) of the transistor is provided in contact with the top surface of the first insulating layer (the top surface of the above-described protruding portion) in the opening, the side surface of the second gate electrode of the transistor in the opening, the side surface of the second insulating layer in the opening, the side surface of the third insulating layer in the opening, and the side surface of the other of the source electrode and the drain electrode of the transistor in the opening. Like the second insulating layer, the first gate insulating layer of the transistor is formed using a material that contains oxygen and releases oxygen by heat treatment or the like.

The semiconductor layer including the channel formation region of the transistor is provided in contact with the top surface of the one of the source electrode and the drain electrode of the transistor in the opening, a side surface of the first insulating layer in the opening, a side surface of the first gate insulating layer of the transistor in the opening, and the top surface of the other of the source electrode and the drain electrode of the transistor. As described above, in the transistor of one embodiment of the present invention, the first gate insulating layer is formed using a material that releases oxygen. Thus, for example, in the case where a metal oxide is used as a material of the semiconductor layer, oxygen contained in the second insulating layer and oxygen contained in the first gate insulating layer can be supplied to the metal oxide through the first gate insulating layer, whereby oxygen vacancies in the metal oxide can be repaired. Accordingly, the electrical characteristics and reliability of the transistor can be improved.

As described above, in the opening, the first insulating layer includes the protruding portion, and the first gate insulating layer of the transistor is provided in contact with the top surface of the protruding portion. That is, the first gate insulating layer of the transistor is provided over the one of the source electrode and the drain electrode of the transistor with the first insulating layer therebetween. Thus, oxygen released from the first gate insulating layer is blocked by the first insulating layer and can be inhibited from diffusing into the one of the source electrode and the drain electrode. Hence, even in the case where a low-resistance conductive material such as a metal is used for the one of the source electrode and the drain electrode, for example, the material can be inhibited from being oxidized by the above oxygen and having high resistance. Accordingly, the electrical characteristics and reliability of the transistor can be further improved.

Specific structure examples of the transistor of one embodiment of the present invention will be described below with reference to drawings.

### Structure Example 1

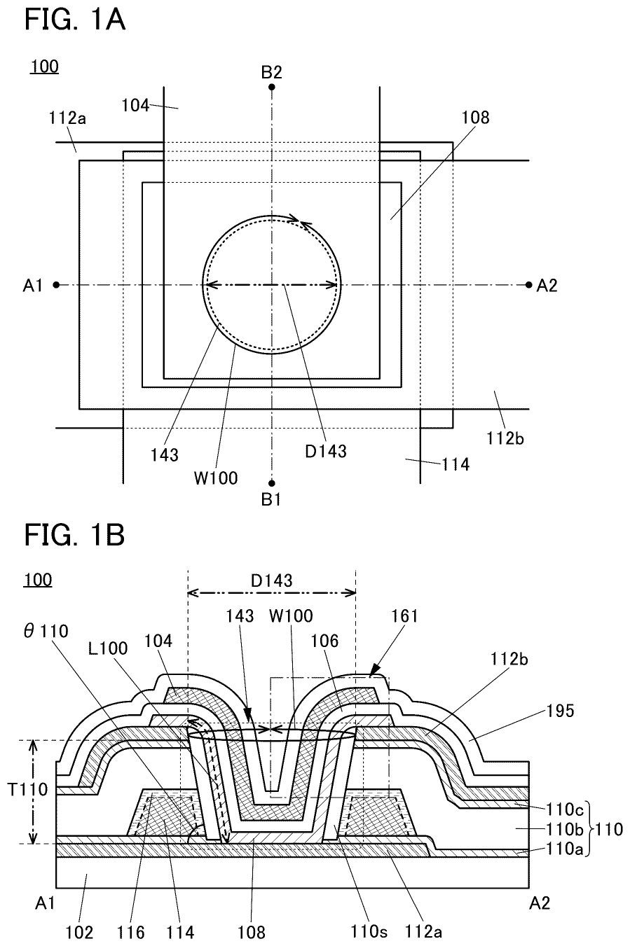

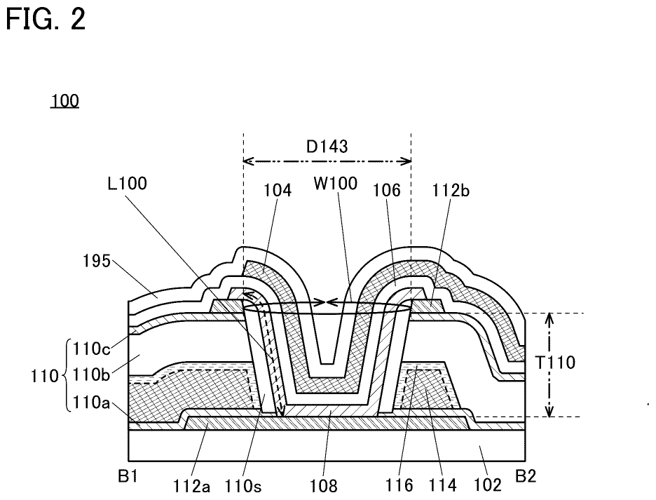

FIG. 1A is a plan view (also referred to as a top view) of a transistor 100. FIG. 1B is a cross-sectional view along the dashed-dotted line A1-A2 in FIG. 1A, and FIG. 2 is a cross-sectional view along the dashed-dotted line B1-B2 in FIG. 1A. Note that some components of the transistor 100 (e.g., an insulating layer) are not illustrated in FIG. 1A. Some components are not illustrated in plan views of transistors and the like in the following drawings, as in FIG. 1A.

The transistor 100 is provided over a substrate 102. The transistor 100 includes a conductive layer 104, an insulating layer 106, a semiconductor layer 108, a conductive layer 114, an insulating layer 116, an insulating layer 110s, a conductive layer 112a, and a conductive layer 112b. The conductive layer 104 functions as a first gate electrode. The conductive layer 114 functions as a second gate electrode (also referred to as a back gate electrode). Part of the insulating layer 106 functions as a first gate insulating layer. The insulating layer 110s functions as a second gate insulating layer (also referred to as a back gate insulating layer). Part of the insulating layer 116 can function as the second gate insulating layer. The conductive layer 112a functions as one of a source electrode and a drain electrode. The conductive layer 112b functions as the other of the source electrode and the drain electrode. In the semiconductor layer 108, between the source electrode and the drain electrode, the entire region that overlaps with the gate electrode with the gate insulating layer therebetween functions as a channel formation region. In the semiconductor layer 108, a region in contact with the source electrode functions as a source region and a region in contact with the drain electrode functions as a drain region.

The structure of the transistor 100 is described in detail.

The conductive layer 112a is provided over the substrate 102. An insulating layer 110a is provided over the conductive layer 112a and the substrate 102. The conductive layer 114 is provided over the insulating layer 110a. The insulating layer 116 is provided over the conductive layer 114. An insulating layer 110b is provided over the insulating layer 110a and the insulating layer 116. An insulating layer 110c is provided over the insulating layer 110b. The conductive layer 112b is provided over the insulating layer 110c. Note that the insulating layers 110a, 110b, and 110c are collectively referred to as an insulating layer 110 in some cases.

The conductive layer 112a, the conductive layer 114, the insulating layer 116, the insulating layer 110, and the conductive layer 112b include an overlap region. In this region, the conductive layer 114 is provided to be placed between the conductive layer 112a and the conductive layer 112b. In this region, the conductive layer 112a overlaps with the conductive layer 114 with the insulating layer 110a therebetween, and the conductive layer 112b overlaps with the conductive layer 114 with the insulating layer 116, the insulating layer 110b, and the insulating layer 110c therebetween. The insulating layer 116 is provided in contact with a side surface and the top surface of the conductive layer 114.

The insulating layer 110a, the conductive layer 114, the insulating layer 110b, the insulating layer 110c, and the conductive layer 112b include an opening 143 reaching the conductive layer 112a. The opening 143 is provided in a region overlapping with the conductive layer 112a, the conductive layer 114, and the conductive layer 112b.

The insulating layer 110a is provided to include a protruding portion in the opening 143. That is, in the cross-sectional views (FIG. 1B and FIG. 2), the side surface of the insulating layer 110a on the opening 143 side extends toward the inner side of the opening 143 beyond the side surfaces of the conductive layer 114, the insulating layer 116, the insulating layer 110b, the insulating layer 110c, and the conductive layer 112b on the opening 143 side. In other words, the opening 143 can be regarded as being a combination of an opening provided in the conductive layer 114, the insulating layer 110b, the insulating layer 110c, and the conductive layer 112b and a smaller-diameter opening provided in the insulating layer 110a.

The insulating layer 110s is provided in contact with the top surface of the insulating layer 110a (the top surface of the protruding portion) in the opening 143, the side surface of the insulating layer 116 in the opening 143, the side surface of the insulating layer 110b in the opening 143, the side surface of the insulating layer 110c in the opening 143, and the side surface of the conductive layer 112b in the opening 143. The insulating layer 110s includes a curved upper end portion. The insulating layer 110s is referred to as a sidewall, a sidewall insulating layer, a sidewall protective layer, or the like in some cases.

Although FIG. 1B and FIG. 2 illustrate a structure in which the thickness of the insulating layer 110a in a region overlapping with the opening 143 is smaller than that of the insulating layer 110a in a region not overlapping with the opening 143, one embodiment of the present invention is not limited thereto. The thickness of the insulating layer 110a in the region overlapping with the opening 143 can be the same as that of the insulating layer 110a in the region not overlapping with the opening 143.

The semiconductor layer 108 is provided in contact with the top surface of the conductive layer 112a in the opening 143, the side surface of the insulating layer 110a in the opening 143, the side surface of the insulating layer 110s in the opening 143, the curved portion of the insulating layer 110s, and the top surface of the conductive layer 112b.

The semiconductor layer 108 includes a region facing a side surface of the conductive layer 114 with the insulating layers 110s and 116 therebetween in the opening 143. The region functions as a channel formation region (also referred to as a back channel formation region). Regions of the insulating layers 110s and 116 in the opening 143 that face the side surface of the conductive layer 114 function as a second gate insulating layer.

Here, the insulating layers 110b and 110s are preferably insulating layers containing oxygen. Moreover, the insulating layers 110b and 110s are preferably insulating layers from which oxygen is released by heating. Accordingly, in the case where a metal oxide is used for the semiconductor layer 108, for example, oxygen contained in the insulating layer 110s can be supplied to the metal oxide. Alternatively, oxygen contained in the insulating layer 110b can be supplied to the metal oxide through the insulating layer 110s. Hence, oxygen vacancies in the metal oxide can be repaired, so that the electrical characteristics and reliability of the transistor 100 can be improved. That is, in the transistor 100, the insulating layer 110s has a function of the second gate insulating layer and also has a function of supplying oxygen to the semiconductor layer 108 (mainly the channel formation region).

Meanwhile, the insulating layers 110a and 110c are preferably insulating layers having a blocking property against a gas such as oxygen and hydrogen. In that case, oxygen contained in the insulating layer 110b can be inhibited from being released to the outside through the insulating layer 110a or the insulating layer 110c.

As described above, the insulating layer 110a includes the protruding portion in the opening 143, and the protruding portion makes the conductive layer 112a and the insulating layer 110s not in direct contact with each other. Thus, it is possible to inhibit the conductive layer 112a from having increased resistance due to oxidation caused by oxygen that is released from the insulating layer 110s and diffused to the conductive layer 112a side, and accordingly can inhibit, for example, a defect in which the on-state current of the transistor peaks out (i.e., a drain current (Id) is less likely to increase with an increasing gate voltage (Vg) in the Id-Vg characteristics).

As described above, the insulating layer 116 is provided in contact with the side surface and the top surface of the conductive layer 114. The insulating layer 116 is preferably an insulating layer formed of an oxide of an element included in the conductive layer 114. The material of the conductive layer 114 is preferably a conductive material that is easily oxidized. In that case, plasma treatment or the like performed on the surface of the conductive layer 114 in an oxygen atmosphere, for example, enables formation of the insulating layer 116 in contact with the side surface and the top surface of the conductive layer 114. Note that like the insulating layers 110a and 110c, the insulating layer 116 is preferably an insulating layer having a blocking property against a gas such as oxygen and hydrogen. Accordingly, oxygen released from the insulating layers 110s and 110b can be inhibited from diffusing to the conductive layer 114 side through the insulating layer 116. Furthermore, with the above-described structure, the insulating layer having the same function as the insulating layers 110a and 110c can be formed without using a deposition method such as a plasma CVD method or a sputtering method; hence, the number of times of employing the above deposition method can be reduced, and the productivity can be increased in some cases.

The insulating layer 106 is provided over the semiconductor layer 108. The insulating layer 106 includes a region in contact with the top surface and a side surface of the semiconductor layer 108, the top surface and a side surface of the conductive layer 112b, and the top surface of the insulating layer 110c.

The conductive layer 104 is provided over the insulating layer 106. The conductive layer 104 is provided to include a region overlapping with the opening 143 in the plan view. The conductive layer 104 includes a region facing the semiconductor layer 108 with the insulating layer 106 therebetween. The conductive layer 104 includes a region facing a side surface of the conductive layer 114 with the insulating layer 106, the semiconductor layer 108, the insulating layer 110s, and the insulating layer 116 therebetween in the opening 143.

In the opening 143, one of the surfaces the semiconductor layer 108 includes a region facing the conductive layer 104 with the insulating layer 106 therebetween, and the other surface of the semiconductor layer 108 includes a region facing the conductive layer 114 with the insulating layers 110s and 116 therebetween.

In the transistor 100, the source electrode and the drain electrode are positioned at different levels with respect to the surface of the substrate 102 over which the transistor 100 is formed, and a drain current flows in a direction perpendicular or substantially perpendicular to the surface of the substrate 102. In the transistor 100, a drain current can also be regarded as flowing in the vertical direction or the substantially vertical direction. Accordingly, the transistor of one embodiment of the present invention can be referred to as a vertical transistor, a vertical-channel transistor, or a vertical field-effect transistor (VFET).

In the transistor 100, the source electrode and the drain electrode can be provided to overlap with each other; thus, the transistor size can be reduced and the area occupied by the transistor in the substrate plane can be significantly reduced as compared to a planar transistor in which a source electrode and a drain electrode are arranged in a planar manner.

An insulating layer 195 is provided to cover the conductive layer 112a, the semiconductor layer 108, the conductive layer 112b, the insulating layer 106, the conductive layer 104, and the like included in the transistor 100. The insulating layer 195 functions as a protective layer for the transistor 100.

One of the conductive layers 104 and 114 can function as the gate electrode (first gate electrode), and the other can function as the back gate electrode (second gate electrode). The conductive layers 104 and 114 are preferably placed to sandwich the channel formation region of the semiconductor layer 108. Accordingly, a gate voltage can be applied to the channel formation region from both of these conductive layers, between which the channel formation region is sandwiched; thus, the effect of the gate voltage on carriers in the channel formation region can be intensified. Thus, the on-state current of the transistor 100 can be increased. The off-state current can be reduced. The threshold voltage can be shifted so that the transistor is normally off.

When a potential for turning on the transistor is applied to the back gate electrode (second gate electrode), the field-effect mobility of the transistor can be increased. By changing the potential of the back gate electrode, the threshold voltage of the transistor can be changed. The potential of the back gate electrode can be the same potential as the gate electrode (first gate electrode). Alternatively, the potential of the back gate electrode can be a ground potential or a given potential. Alternatively, the potential of the back gate electrode can be the same potential as the source electrode or the drain electrode. Accordingly, the potential of a region of the semiconductor layer on the side facing the back gate electrode can be fixed, so that variations in electrical characteristics of the transistor can be inhibited.

In the case where the same potential is applied to the back gate electrode and the gate electrode, the back gate electrode and the gate electrode are connected to each other to establish electrical continuity. In the case where the same potential is applied to the back gate electrode and the source or drain electrode, the back gate electrode and the source or drain electrode are connected to each other to establish electrical continuity. When the gate electrode or the back gate electrode is connected to the source electrode, the reliability of the transistor can be increased, for example.

In the case where the potential of the back gate electrode is a ground potential or a given potential, a common wiring connected to the back gate electrodes of a plurality of transistors may be provided and supplied with the potential.

When the transistor includes a back gate electrode, variations in electrical characteristics between a plurality of transistors can be reduced in some cases. For example, variations in threshold voltage between a plurality of transistors can be reduced in some cases.

The top surface shape of the opening 143 can be circular or elliptic, for example. Examples of the top surface shape of the opening 143 include polygons such as a triangle, a tetragon (including a rectangle, a rhombus, and a square), and a pentagon; and polygons with rounded corners. The top surface shape of the opening 143 is preferably circular as illustrated in FIG. 1A. When the top surface of the opening 143 has a circular shape, high processing accuracy to form the opening 143 in a minute size is possible. Note that in this specification and the like, a circular shape is not necessarily a perfect circular shape.

The channel length and the channel width of the transistor 100 are described.

In the semiconductor layer 108, a region in contact with the conductive layer 112a functions as one of a source region and a drain region, a region in contact with the conductive layer 112b functions as the other of the source region and the drain region, and a region between the source region and the drain region functions as a channel formation region.

The channel length of the transistor 100 is a distance between the source region and the drain region. In FIG. 1B and FIG. 2, a channel length L100 of the transistor 100 is indicated by a dashed double-headed arrow. In FIG. 1B and FIG. 2, the distance along the side surface and the curved portion of the insulating layer 110s and the side surface of the insulating layer 110a between the top surface of the conductive layer 112a and the top surface of the conductive layer 112b is shown as the channel length L100 of the transistor 100.

Note that as the channel length L100 of the transistor 100, a thickness T110 that is the total thickness of the insulating layer 110a, the conductive layer 114, the insulating layer 116, the insulating layer 110b, and the insulating layer 110c in a region between the top surface of the conductive layer 112a and the bottom surface of the conductive layer 112b (the thickness T110 is indicated by a dashed-dotted double-headed arrow in FIG. 1B and FIG. 2) is sometimes used. Alternatively, the sum of the thickness T110 and the thickness of the conductive layer 112b is sometimes used as the channel length L100 of the transistor 100. Alternatively, the height of the insulating layer 110s (the distance between the upper end portion and the lower end portion of the insulating layer 110s in the direction perpendicular to the substrate surface) is sometimes used as the channel length L100 of the transistor 100.

Here, the channel length L100 of the transistor 100 is determined, for example, by the thickness of the insulating layer 110a, the thickness of the conductive layer 114, the thickness of the insulating layer 116, the thickness of the insulating layer 110b, the thickness of the insulating layer 110c, the thickness of the conductive layer 112b, an angle θ110 between the formation surface of the insulating layer 110s (here, the side surfaces of the insulating layer 110a, the insulating layer 116, the insulating layer 110b, the insulating layer 110c, and the conductive layer 112b) and the formation surface of the insulating layer 110a (here, the top surface of the conductive layer 112a). The channel length L100 is not affected by the performance of a light-exposure apparatus used for manufacturing the transistor. Hence, the channel length L100 can be a smaller value than the resolution limit of the light-exposure apparatus and thus the transistor can be miniaturized.

The channel length L100 can be, for example, greater than or equal to 5 nm and less than 3 μm, greater than or equal to 7 nm and less than or equal to 2.5 μm, greater than or equal to 10 nm and less than or equal to 2 μm, greater than or equal to 10 nm and less than or equal to 1.5 μm, greater than or equal to 10 nm and less than or equal to 1.2 μm, greater than or equal to 10 nm and less than or equal to 1 μm, greater than or equal to 10 nm and less than or equal to 500 nm, greater than or equal to 10 nm and less than or equal to 300 nm, greater than or equal to 10 nm and less than or equal to 200 nm, greater than or equal to 10 nm and less than or equal to 100 nm, greater than or equal to 10 nm and less than or equal to 50 nm, greater than or equal to 10 nm and less than or equal to 30 nm, or greater than or equal to 10 nm and less than or equal to 20 nm. For example, the channel length L100 can be greater than or equal to 100 nm and less than or equal to 1 μm.

The thickness T110 can be, for example, greater than or equal to 5 nm and less than 3 μm, greater than or equal to 7 nm and less than or equal to 2.5 μm, greater than or equal to 10 nm and less than or equal to 2 μm, greater than or equal to 10 nm and less than or equal to 1.5 μm, greater than or equal to 10 nm and less than or equal to 1.2 μm, greater than or equal to 10 nm and less than or equal to 1 μm, greater than or equal to 10 nm and less than or equal to 500 nm, greater than or equal to 10 nm and less than or equal to 300 nm, greater than or equal to 10 nm and less than or equal to 200 nm, greater than or equal to 10 nm and less than or equal to 100 nm, greater than or equal to 10 nm and less than or equal to 50 nm, greater than or equal to 10 nm and less than or equal to 30 nm, or greater than or equal to 10 nm and less than or equal to 20 nm.

The angle θ110 can be, for example, greater than or equal to 30° and less than 90°, greater than or equal to 35° and less than or equal to 85°, greater than or equal to 40° and less than or equal to 80°, greater than or equal to 450 and less than or equal to 80°, greater than or equal to 50° and less than or equal to 80°, greater than or equal to 55° and less than or equal to 80°, greater than or equal to 60° and less than or equal to 80°, greater than or equal to 65° and less than or equal to 80°, or greater than or equal to 70° and less than or equal to 80°. Note that the angle θ110 can also be 90°. A smaller angle θ110 is preferable because of higher coverage with layers (e.g., the insulating layer 110s and the semiconductor layer 108) formed along the sidewall of the opening 143. Meanwhile, the angle θ110 closer to 90° is preferable because of a smaller area occupied by the transistor in the substrate plane.

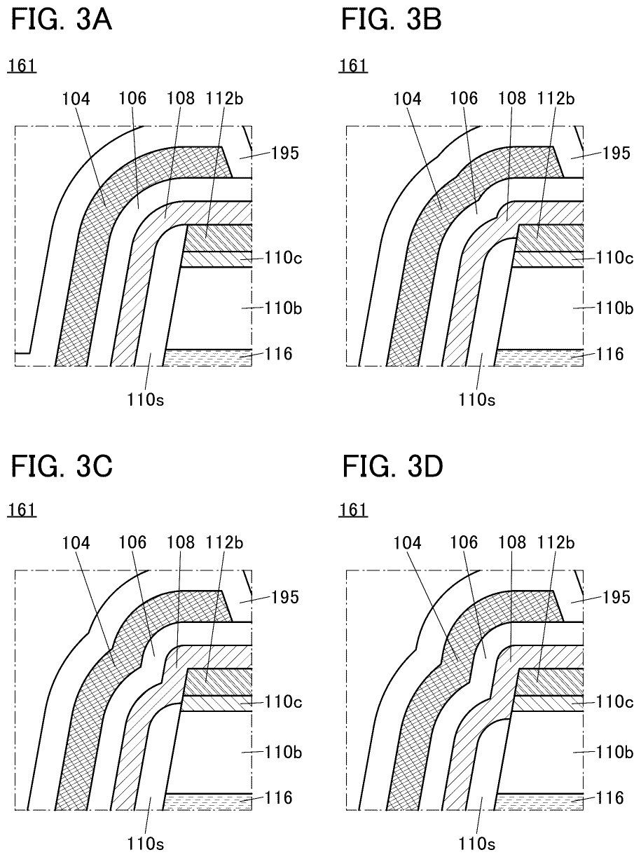

FIG. 3A is an enlarged view of a region 161 in FIG. 1B. FIG. 3A illustrates a structure in which the upper end portion of the insulating layer 110s is level with or substantially level with the top surface of the conductive layer 112b (the structure illustrated in FIG. 1B and the like). In this structure, a step is not formed between the upper end portion of the insulating layer 110s and the side surface of the conductive layer 112b. Thus, the coverage with the semiconductor layer 108 provided in contact with the side surface of the insulating layer 110s and the top surface of the conductive layer 112b can be improved as compared to a structure including the step.

The transistor 100 does not necessarily has a structure in which the upper end portion of the insulating layer 110s is level with or substantially level with the top surface of the conductive layer 112b as illustrated in FIG. 1B and the like. Structures illustrated in FIGS. 3B to 3D are examples of structures in which the level of the upper end portion of the insulating layer 110s, for example, is different from that in FIG. 3A.

FIG. 3B illustrates a structure in which the level of the upper end portion of the insulating layer 110s is lower than that of the top surface of the conductive layer 112b and higher than that of the top surface of the insulating layer 110c placed below the conductive layer 112b. In the structure illustrated in FIG. 3B, the side surface of the conductive layer 112b includes a region in contact with the semiconductor layer 108. When the semiconductor layer 108 is in contact with the side surface of the conductive layer 112b, the contact area between the semiconductor layer 108 and the conductive layer 112b is increased, so that the contact resistance between the semiconductor layer 108 and the conductive layer 112b is reduced in some cases.

FIG. 3C illustrates a structure in which the level of the upper end portion of the insulating layer 110s is lower than that of the top surface of the insulating layer 110c. In the structure illustrated in FIG. 3C, the side surface of the conductive layer 112b includes a region in contact with the semiconductor layer 108, and the side surface of the insulating layer 110c includes a region in contact with the semiconductor layer 108. In this structure, the semiconductor layer 108 is in contact with the entire side surface of the conductive layer 112b; thus, the contact resistance between the semiconductor layer 108 and the conductive layer 112b is sometimes lower than that in the structure illustrated in FIG. 3B.

FIG. 3D illustrates a structure in which the level of the upper end portion of the insulating layer 110s is lower than that of the top surface of the insulating layer 110b. In the structure illustrated in FIG. 3D, the side surface of the conductive layer 112b includes a region in contact with the semiconductor layer 108, the side surface of the insulating layer 110c includes a region in contact with the semiconductor layer 108, and the side surface of the insulating layer 110b includes a region in contact with the semiconductor layer 108. This structure may obtain an effect similar to that obtained with the structure illustrated in FIG. 3C.

When the time of etching for forming the insulating layer 110s is increased, the height of the insulating layer 110s (the distance between the upper end portion and the lower end portion of the insulating layer 110s in the direction perpendicular to the substrate surface) can be decreased in some cases. When the etching time is increased, the level of the upper end portion of the insulating layer 110s is lower than that of the top surface of the conductive layer 112b in some cases. The level of the upper end portion of the insulating layer 110s is preferably higher than at least the level of the top surface of the conductive layer 114. That is, the insulating layer 110s preferably faces the entire side surface of the conductive layer 114 with the insulating layer 116 therebetween in the opening 143. As described above, the insulating layer 110s is an insulating layer functioning as the second gate insulating layer (back gate insulating layer) of the transistor 100. Thus, when the insulating layer 110s includes a region facing the entire side surface of the conductive layer 114, a region of the semiconductor layer 108 that faces the conductive layer 114 with the insulating layer 110s therebetween in the opening 143 can function entirely as a channel formation region (back channel formation region).

When the channel length L100 is small, the transistor 100 can have a high on-state current. With the use of the transistor 100, a circuit capable of high-speed operation can be manufactured. Furthermore, the area occupied by a circuit can be reduced. Accordingly, when the transistor of one embodiment of the present invention is used in a semiconductor device, the semiconductor device can be downsized.

For example, when the transistor of one embodiment of the present invention is used in a display device, the bezel of the display device can be narrowed. As another example, in a large-sized or high-resolution display device including a large number of wirings, the use of the transistor of one embodiment of the present invention can reduce signal delay in the wirings and reduce display unevenness.

The channel width of the transistor 100 is the length of the source region or the length of the drain region in the plan view (FIG. 1A). In other words, the channel width of the transistor 100 is the length of a region where the semiconductor layer 108 is in contact with the conductive layer 112a or the length of a region where the semiconductor layer 108 is in contact with the conductive layer 112b in the plan view. Alternatively, the length of the perimeter of the side surface of the insulating layer 110s in the plan view is sometimes used as the channel width of the transistor 100. Alternatively, the length of the perimeter of a region where the insulating layer 110s is in contact with the conductive layer 112b in the plan view is sometimes used as the channel width of the transistor 100.

Here, the channel width of the transistor 100 is described as the length of the perimeter of the region where the insulating layer 110s is in contact with the conductive layer 112b in the plan view. In FIGS. 1A, 1B, and 2, a channel width W100 of the transistor 100 is indicated by a solid double-headed arrow. The channel width W100 can also be referred to as the length of the perimeter of the opening 143 in the plan view.

The channel width W100 is determined by the top surface shape of the opening 143, for example. In FIGS. 1A, 1B, and 2, a width D143 of the opening 143 is indicated by a dashed-two-dotted double-headed arrow. The width D143 is the shorter side of the smallest rectangle circumscribing the opening 143 in the plan view. In the case where the opening 143 is formed by a photolithography method, the width D143 of the opening 143 is larger than or equal to the resolution limit of a light-exposure apparatus. The width D143 is, for example, greater than or equal to 0.20 μm and less than 5.0 μm. Note that when the top surface shape of the opening 143 is circular, the width D143 corresponds to the diameter of the opening 143, and the channel width W100 can be calculated to be “D143×π”.

### [Semiconductor Layer 108]

A semiconductor material that can be used for the semiconductor layer 108 is not particularly limited. For example, a single-element semiconductor or a compound semiconductor can be used. As the single-element semiconductor, silicon or germanium can be used, for example. Examples of the compound semiconductor include gallium arsenide and silicon germanium. As the compound semiconductor, a semiconducting organic substance or a semiconducting metal oxide (also referred to as an oxide semiconductor) can be used. Note that these semiconductor materials may include an impurity functioning as a dopant (e.g., an element such as phosphorus or boron is typically used in the case where silicon is used as the semiconductor material).

There is no particular limitation on the crystallinity of the semiconductor material used for the semiconductor layer 108, and an amorphous semiconductor or a semiconductor having crystallinity (a single crystal semiconductor, a polycrystalline semiconductor, a microcrystalline semiconductor, or a semiconductor partly including crystal regions) may be used. A semiconductor having crystallinity is preferably used, in which case deterioration of transistor characteristics can be inhibited.

For the semiconductor layer 108, silicon can be used. Examples of silicon include single crystal silicon, polycrystalline silicon, microcrystalline silicon, and amorphous silicon. An example of polycrystalline silicon is low-temperature polysilicon (LTPS).

The transistor including amorphous silicon in the semiconductor layer 108 can be formed over a large-sized glass substrate, thereby reducing the manufacturing cost. The transistor including polycrystalline silicon in the semiconductor layer 108 has high field-effect mobility and high operating speed. The transistor including microcrystalline silicon in the semiconductor layer 108 has higher field-effect mobility and higher operating speed than the transistor including amorphous silicon.

The semiconductor layer 108 preferably includes a metal oxide (an oxide semiconductor). Examples of the metal oxide that can be used for the semiconductor layer 108 include indium oxide, gallium oxide, and zinc oxide. The metal oxide preferably includes at least indium (In) or zinc (Zn). The metal oxide preferably includes one or more selected from indium, an element M, and zinc. The element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. Specifically, the element M is preferably one or more selected from aluminum, gallium, yttrium, and tin. The element M is further preferably gallium.

The semiconductor layer 108 can be formed using, for example, indium oxide, indium zinc oxide (In—Zn oxide), indium tin oxide (In—Sn oxide), indium titanium oxide (In—Ti oxide), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO). Alternatively, indium tin oxide containing silicon or the like can be used.

A sputtering method or an atomic layer deposition (ALD) method can be suitably used to form a film of the metal oxide. Note that in the case where the metal oxide film is formed by a sputtering method, the atomic ratio in the metal oxide film may be different from the atomic ratio in a target. In particular, the atomic ratio of zinc in the metal oxide film may be smaller than the atomic ratio of zinc in the target. Specifically, the atomic ratio of zinc in the metal oxide film may be approximately higher than or equal to 40% and lower than or equal to 90% of the atomic ratio of zinc in the target.

Specific examples of ALD methods used to form the semiconductor layer 108 include a thermal ALD method and a plasma enhanced ALD (PEALD) method. The thermal ALD method is preferable because of its capability of forming a film with extremely high step coverage. The PEALD method is preferable because of its capability of forming a film at low temperatures, in addition to its capability of forming a film with high step coverage.

The composition of the metal oxide included in the semiconductor layer 108 significantly affects the electrical characteristics and reliability of the transistor 100.

For example, a metal oxide with a higher indium content enables the transistor to have a higher on-state current. As another example, with the use of a metal oxide that does not contain gallium or has a low gallium content for the semiconductor layer 108, the transistor can be highly reliable against positive bias application. As another example, with the use of a metal oxide with a low content of the element M for the semiconductor layer 108, the transistor can be highly reliable against positive bias application. As another example, a high content of the element M in a metal oxide enables the transistor to be highly reliable against light.

The composition of the metal oxide included in the semiconductor layer 108 will be described later in detail.

A metal oxide layer having crystallinity is preferably used as the semiconductor layer 108. For example, a metal oxide layer having a c-axis-aligned crystal (CAAC) structure, a polycrystalline structure, a nano-crystal (nc) structure, or the like can be used. By using a metal oxide layer having crystallinity as the semiconductor layer 108, the density of defect states in the semiconductor layer 108 can be reduced, which enables the transistor to have high reliability. Note that the CAAC structure is a crystal structure in which a plurality of nanocrystals (typically, a plurality of IGZO nanocrystals) have c-axis alignment and are connected on the a-b plane without alignment. The CAAC structure, in which grain boundaries (grains) are not clearly observed in the a-b plane as compared to the polycrystalline structure, achieves a highly reliable transistor.

The higher the crystallinity of the metal oxide layer used as the semiconductor layer 108 is, the lower the density of defect states in the semiconductor layer 108 can be. In contrast, with the use of a metal oxide layer having low crystallinity, a large amount of current can flow through the transistor.

The semiconductor layer 108 may have a stacked-layer structure of two or more metal oxide layers having different crystallinities. For example, a stacked-layer structure of a first metal oxide layer and a second metal oxide layer over the first metal oxide layer can be employed; the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer 108 may have the same composition or substantially the same compositions. Employing a stacked-layer structure of metal oxide layers having the same composition can reduce the manufacturing cost because the metal oxide layers can be formed using, for example, the same sputtering target. For example, by varying the flow rate ratio of an oxygen gas to the entire deposition gas used for the film formation while using the same sputtering target, a stacked-layer structure of two or more metal oxide layers having different crystallinities can be formed. The two or more metal oxide layers included in the semiconductor layer 108 may have different compositions.

The thickness of the semiconductor layer 108 (the thickness on the film formation surface) is preferably larger than or equal to 3 nm and smaller than or equal to 100 nm, further preferably larger than or equal to 5 nm and smaller than or equal to 100 nm, further preferably larger than or equal to 10 nm and smaller than or equal to 100 nm, further preferably larger than or equal to 10 nm and smaller than or equal to 70 nm, further preferably larger than or equal to 15 nm and smaller than or equal to 70 nm, further preferably larger than or equal to 15 nm and smaller than or equal to 50 nm, further preferably larger than or equal to 20 nm and smaller than or equal to 50 nm, further preferably larger than or equal to 20 nm and smaller than or equal to 40 nm, further preferably larger than or equal to 25 nm and smaller than or equal to 40 nm.

Here, oxygen vacancies that might be formed in the semiconductor layer 108 are described.

In the case where the semiconductor layer 108 is formed using an oxide semiconductor, hydrogen contained in the oxide semiconductor reacts with oxygen bonded to a metal atom to be water, and thus an oxygen vacancy (V_{O}) is sometimes formed in the oxide semiconductor. In some cases, a defect that is an oxygen vacancy into which hydrogen enters (hereinafter referred to as V_{O}H) functions as a donor and generates an electron serving as a carrier. In other cases, bonding of part of hydrogen to oxygen bonded to a metal atom generates an electron serving as a carrier. Thus, a transistor including an oxide semiconductor that contains a large amount of hydrogen is likely to have normally-on characteristics. Moreover, hydrogen in an oxide semiconductor is easily transferred by a stress such as heat or an electric field; thus, a large amount of hydrogen in an oxide semiconductor might degrade the reliability of a transistor.

V_{O}H can serve as a donor of an oxide semiconductor. However, it is difficult to evaluate the defects quantitatively. Thus, the oxide semiconductor is sometimes evaluated by not its donor concentration but its carrier concentration. Therefore, in this specification and the like, the carrier concentration assuming the state where an electric field is not applied is sometimes used, instead of the donor concentration, as a parameter of the oxide semiconductor. That is, “carrier concentration” in this specification and the like can be replaced with “donor concentration” in some cases.

Therefore, when an oxide semiconductor is used for the semiconductor layer 108, the V_{O}H in the semiconductor layer 108 is preferably reduced as much as possible so that the semiconductor layer 108 becomes a highly purified intrinsic or substantially highly purified intrinsic semiconductor layer. In order to obtain such an oxide semiconductor with sufficiently reduced V_{O}H, it is important to remove impurities such as water and hydrogen in the oxide semiconductor (this treatment is sometimes referred to as dehydration or dehydrogenation treatment) and supply oxygen to the oxide semiconductor to repair oxygen vacancies (V_{O}). When an oxide semiconductor with sufficiently reduced defects such as V_{O}H is used for a channel formation region of a transistor, the transistor can have stable electrical characteristics. Supplying oxygen to the oxide semiconductor to repair oxygen vacancies (V_{O}) is sometimes referred to as oxygen adding treatment.

When an oxide semiconductor is used for the semiconductor layer 108, the carrier concentration of the oxide semiconductor functioning as a channel formation region is preferably lower than or equal to 1×10¹⁸ cm⁻³, further preferably lower than 1×10¹⁷ cm⁻³, further preferably lower than 1×10¹⁶ cm⁻³, further preferably lower than 1×10¹³ cm⁻³, further preferably lower than 1×10¹² cm⁻³. The minimum carrier density of an oxide semiconductor in the region functioning as a channel formation region is not limited and can be 1×10⁻⁹ cm⁻³, for example.

A transistor including an oxide semiconductor (hereinafter referred to as an OS transistor) has much higher field-effect mobility than a transistor including amorphous silicon. The OS transistor has an extremely low leakage current between a source and a drain in an off state (hereinafter also referred to as off-state current), and electric charge accumulated in a capacitor that is connected in series to the transistor can be held for a long period. When OS transistors are used in a semiconductor device, power consumption of the semiconductor device can be reduced.

An OS transistor can also be used in a display device. To increase the luminance of a light-emitting device included in a pixel circuit of a display device, it is necessary to increase the amount of current flowing through the light-emitting device. To increase the current amount, the source-drain voltage of a driving transistor included in the pixel circuit needs to be increased. Since an OS transistor has a higher breakdown voltage between the source and the drain than a transistor including silicon (hereinafter referred to as a Si transistor), a high voltage can be applied between the source and the drain of the OS transistor. Thus, with the use of an OS transistor as the driving transistor in the pixel circuit, the amount of current flowing through the light-emitting device can be increased, resulting in an increase in luminance of the light-emitting device.

When transistors operate in a saturation region, a change in source-drain current relative to a change in gate-source voltage can be smaller in an OS transistor than in a Si transistor. Therefore, when an OS transistor is used as the driving transistor included in the pixel circuit, the current flowing between the source and the drain can be determined minutely by the change in the gate-source voltage, so that the amount of current flowing through the light-emitting device can be controlled minutely. Consequently, the number of gray levels expressed by the pixel circuit can be increased.

Regarding saturation characteristics of current flowing when transistors operate in a saturation region, even in the case where the source-drain voltage of an OS transistor increases gradually, a more stable current (saturation current) can flow through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor operates in the saturation region, the source-drain current hardly changes with an increase in the source-drain voltage; hence, the luminance of the light-emitting device can be stable.

As described above, by using OS transistors as the driving transistors included in the pixel circuits, it is possible to inhibit black-level degradation, increase the luminance, increase the number of gray levels, and suppress variations in light-emitting devices, for example.

A change in electrical characteristics of an OS transistor due to exposure to radiation is small, i.e., an OS transistor has a high resistance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a neutron beam, and a proton beam).

### [Insulating Layer]

In the transistor of one embodiment of the present invention and a semiconductor device, a display device, and the like each including the transistor of one embodiment of the present invention, insulating layers (the insulating layers 110, 106, 110s, 116, and 195) can be formed using an inorganic insulating material or an organic insulating material. The insulating layers may have a stacked-layer structure of an inorganic insulating material and an organic insulating material.

As the inorganic insulating material, one or more of an oxide, an oxynitride, a nitride oxide, and a nitride can be used.

Note that in this specification and the like, an oxynitride refers to a material in which an oxygen content is higher than a nitrogen content. A nitride oxide refers to a material in which a nitrogen content is higher than an oxygen content. For example, silicon oxynitride refers to a material in which an oxygen content is higher than a nitrogen content, and silicon nitride oxide refers to a material in which a nitrogen content is higher than an oxygen content.

The oxygen content and the nitrogen content can be analyzed by secondary ion mass spectrometry (SIMS) or X-ray photoelectron spectroscopy (XPS). XPS is suitable when the content of a target element is high (e.g., 0.5 atomic % or more, or 1 atomic % or more). In contrast, SIMS is suitable when the content of a target element is low (e.g., less than 0.5 atomic %, or less than 1 atomic %). To compare the contents of elements, analysis with a combination of SIMS and XPS is preferably used.

The film density of an insulating layer or the like can be evaluated by Rutherford backscattering spectrometry (RBS) or X-ray reflection (XRR), for example. A difference in film density can sometimes be evaluated using a cross-sectional transmission electron microscopy (TEM) image. In TEM observation, the transmission electron (TE) image is dark-colored (dark) when the film density is high, and the transmission electron (TE) image is pale (bright) when the film density is low. Note that when insulating layers formed using the same material have different film densities, it is sometimes possible to identify the boundary between the insulating layers by a difference in contrast in a cross-sectional TEM image.

The nitrogen content in an insulating layer can be recognized by EDX, for example. In the case where silicon nitride or silicon oxynitride, for example, is used for the insulating layer, the nitrogen content can be evaluated with the ratio of the peak height of nitrogen to the peak height of silicon. Note that in EDX, the peak of a certain element refers to a point at which the number of counts of the element reaches a local maximum value in a spectrum of a graph where the horizontal axis represents the energy of characteristic X-rays and the vertical axis represents the counts (the detected value) of characteristic X-rays. Alternatively, the counts at an energy of a characteristic X-ray unique to the element may be used to evaluate a difference in the nitrogen content with the ratio of the counts of nitrogen to the counts of silicon. For example, the counts at 1.739 keV (Si—Kα) can be used for silicon, and the counts at 0.392 keV (N—Kα) can be used for nitrogen.

The hydrogen concentration of an insulating layer can be evaluated by SIMS, for example.

Hydrogen diffused in the semiconductor layer 108 reacts with an oxygen atom contained in an oxide semiconductor to be water, and thus an oxygen vacancy (V_{O}) is sometimes formed in the semiconductor layer 108. Furthermore, V_{O}H is formed in the semiconductor layer 108 and the carrier concentration in the semiconductor layer 108 is increased in some cases. When a blocking film that inhibits hydrogen diffusion is used as the insulating layer in contact with the semiconductor layer 108 or the insulating layer around the semiconductor layer 108, oxygen vacancies (V_{O}) and V_{O}H can be reduced in the semiconductor layer 108, so that the transistor can have favorable electrical characteristics and high reliability.

Oxygen vacancies (V_{O}) and V_{O}H are preferably reduced in the channel formation region of the transistor 100. Particularly in the case where the channel length L100 is small, oxygen vacancies (V_{O}) and V_{O}H in the channel formation region greatly affect the electrical characteristics and reliability of the transistor 100. For example, diffusion of V_{O}H from the source region or the drain region into the channel formation region increases the carrier concentration in the channel formation region, which might cause a change in the threshold voltage or a reduction in the reliability of the transistor 100. As the channel length L100 of the transistor 100 becomes smaller, the influence of such diffusion of V_{O}H on electrical characteristics and reliability of the transistor 100 becomes greater. Reducing oxygen vacancies (V_{O}) and V_{O}H in the semiconductor layer 108, particularly in the channel formation region of the semiconductor layer 108, enables the transistor with a small channel length to have favorable electrical characteristics and high reliability.

When an insulating layer that releases oxygen is used as the insulating layer in contact with the semiconductor layer 108 (e.g., the insulating layers 106 and 110s) or the insulating layer around the semiconductor layer 108 (e.g., the insulating layer 110), oxygen can be supplied from the insulating layer to the semiconductor layer 108. Supplying oxygen to the channel formation region of the semiconductor layer 108 allows the amount of oxygen vacancies (V_{O}) and V_{O}H to be reduced in the semiconductor layer 108, so that the transistor can have favorable electrical characteristics and high reliability. Examples of treatment for supplying oxygen to the semiconductor layer 108 include heat treatment in an oxygen-containing atmosphere and plasma treatment in an oxygen-containing atmosphere.

The amount of impurities (e.g., water and hydrogen) released from the insulating layer in contact with the semiconductor layer 108 or the insulating layer around the semiconductor layer 108 is preferably small. Note that impurities here refer to substances that might adversely affect the electrical characteristics of the transistor by generating oxygen vacancies (V_{O}) and V_{O}H in the semiconductor layer 108, for example, when diffusing into the semiconductor layer 108. When the amount of impurities released from the insulating layer is small, diffusion of the impurities into the semiconductor layer 108 can be inhibited, so that the transistor can have favorable electrical characteristics and high reliability.

In some cases, oxygen is released from the semiconductor layer 108 by heat applied in a step after the formation of the semiconductor layer 108. However, when oxygen is supplied to the semiconductor layer 108 from the insulating layer in contact with the semiconductor layer 108 or the insulating layer around the semiconductor layer 108, the amount of oxygen vacancies (V_{O}) and V_{O}H can be inhibited from increasing in the semiconductor layer 108. In addition, the temperature of treatment in a step after the formation of the semiconductor layer 108 can be set more flexibly. Specifically, the temperature of treatment can be set high even in a step after the formation of the semiconductor layer 108. Accordingly, the transistor 100 can be formed to have favorable electrical characteristics and high reliability.

### [Insulating Layer 110]

For the insulating layer 110 (the insulating layers 110a, 110b, and 110c), an inorganic insulating material or an organic insulating material can be used. The insulating layer 110 may have a stacked-layer structure of an inorganic insulating material and an organic insulating material.

For the insulating layer 110, an inorganic insulating material can be suitably used. As the inorganic insulating material, one or more of an oxide, an oxynitride, a nitride oxide, and a nitride can be used. For the insulating layer 110, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

The insulating layer 110 may have a stacked-layer structure of two or more layers. The insulating layer 110 illustrated in FIG. 1B and the like has a stacked-layer structure of the insulating layer 110a, the insulating layer 110b over the insulating layer 110a, and the insulating layer 110c over the insulating layer 110b. For the insulating layers 110a, 110b, and 110c, the same material or different materials may be used.

The amount of impurities (e.g., water and hydrogen) released from the insulating layer 110 is preferably small.

The thickness of the insulating layer 110b can be larger than those of the insulating layers 110a and 110c. As described above, the insulating layer 110b is an insulating layer containing oxygen to be supplied to the semiconductor layer 108. Thus, when the thickness of the insulating layer 110b is the largest among the three insulating layers (the insulating layers 110a, 110b, and 110c) included in the insulating layer 110, the amount of oxygen that can be contained in the whole insulating layer 110 can be increased. The film formation rate of the insulating layer 110b is preferably higher than those of the insulating layers 110a and 110c. By increasing the film formation rate of a film with a large thickness, the productivity can be increased.

The insulating layers 110a and 110c each function as a blocking film that inhibits release of gas from the insulating layer 110b. Each of the insulating layers 110a and 110c is preferably formed using a material that does not easily allow diffusion of gas. Each of the insulating layers 110a and 110c preferably includes a region having a higher film density than the insulating layer 110b. An insulating layer having a high film density can have a high blocking property against gas. An insulating layer formed at a low film formation rate can have a high film density and a high blocking property against gas.

The insulating layer 110b is preferably formed using an oxide or an oxynitride. A film from which oxygen is released by heating is preferably used for the insulating layer 110b. For example, silicon oxide or silicon oxynitride can be suitably used for the insulating layer 110b.

When the insulating layer 110b releases oxygen, oxygen can be supplied from the insulating layer 110b to the semiconductor layer 108 through the insulating layer 110s. The insulating layer 110b preferably has a high oxygen diffusion coefficient. Oxygen is easily diffused in the insulating layer 110b having a high oxygen diffusion coefficient, so that oxygen can be efficiently supplied to the semiconductor layer 108. When the thickness of the insulating layer 110b is larger than those of the insulating layers 110a and 110c as described above, a larger amount of oxygen can be supplied to the semiconductor layer 108.

The insulating layer 110 is preferably formed by a deposition method such as a sputtering method, an ALD method, or a plasma CVD method.

In particular, by a sputtering method using a deposition gas not containing hydrogen, a film having an extremely low hydrogen content can be formed. In that case, supply of hydrogen to the semiconductor layer 108 is inhibited and the electrical characteristics of the transistor 100 can be stable. In the case where a silicon oxide film is formed by a sputtering method, the film can be formed using a silicon target in an atmosphere containing an oxidizing gas, for example. In the case where a silicon nitride film is formed by a sputtering method, the film can be formed using a silicon target in an atmosphere containing a nitrogen gas, for example. In the case where an aluminum oxide film is formed by a sputtering method, the film can be formed using an aluminum target in an atmosphere containing an oxidizing gas, for example.

Silicon oxide and silicon nitride films can be formed by a PEALD method, for example. Aluminum oxide and hafnium oxide films can be formed by a thermal ALD method, for example. An insulating layer formed by a PEALD method or a thermal ALD method can be dense and thus have a high blocking property against oxygen and hydrogen.

A material containing more nitrogen than the insulating layer 110b can be used for the insulating layers 110a and 110c. The insulating layers 110a and 110c with a high nitrogen content can have a high blocking property against oxygen and hydrogen.

The insulating layers 110a and 110c may each include a region having a lower hydrogen concentration than the insulating layer 110b.

It is preferably that oxygen be less likely to pass through the insulating layers 110a and 110c. It is further preferable that hydrogen be less likely to pass through the insulating layers 110a and 110c. The insulating layers 110a and 110c function as blocking films that inhibit diffusion of hydrogen into the semiconductor layer 108 from the outside of the transistor through the insulating layers 110a and 110c. The film densities of the insulating layers 110a and 110c are preferably higher than that of the insulating layer 110b. The insulating layers 110a and 110c having a high film density can have a high blocking property against oxygen and hydrogen. In the case where silicon oxide or silicon oxynitride is used for the insulating layer 110b, silicon nitride or silicon nitride oxide can be used for each of the insulating layers 110a and 110c. In addition, hafnium oxide or aluminum oxide can be suitably used for each of the insulating layers 110a and 110c.

Each of the insulating layers 110a and 110c can be a stack of two or more layers selected from silicon nitride, silicon nitride oxide, hafnium oxide, and aluminum oxide layers.

If oxygen contained in the insulating layer 110b diffuses downward (to the substrate 102 side) from the insulating layer 110b, the amount of oxygen supplied from the insulating layer 110b to the semiconductor layer 108 might be reduced. Providing the insulating layer 110a under the insulating layer 110b can inhibit oxygen contained in the insulating layer 110b from diffusing below the insulating layer 110b. Moreover, providing the insulating layer 110c over the insulating layer 110b can inhibit oxygen contained in the insulating layer 110b from diffusing above the insulating layer 110b. Accordingly, the amount of oxygen supplied from the insulating layer 110b to the semiconductor layer 108 is increased, whereby the amount of oxygen vacancies (V_{O}) and V_{O}H in the semiconductor layer 108 can be reduced.

Providing the insulating layers 110a and 110c can inhibit diffusion of hydrogen into the semiconductor layer 108 and reduce the amount of oxygen vacancies (V_{O}) and V_{O}H in the semiconductor layer 108.

Each of the insulating layers 110a and 110c preferably has a thickness with which the insulating layer can function as a blocking film against oxygen and hydrogen. If the thickness is small, the function of a blocking film might deteriorate. Meanwhile, if the thickness is large, a region where the semiconductor layer 108 faces the insulating layer 110b is narrowed and the amount of oxygen supplied to the semiconductor layer 108 might be reduced. The thickness of each of the insulating layers 110a and 110c (the thickness on the film formation surface) is preferably greater than or equal to 1 nm and less than or equal to 200 nm, greater than or equal to 1 nm and less than or equal to 100 nm, greater than or equal to 1 nm and less than or equal to 60 nm, greater than or equal to 1 nm and less than or equal to 50 nm, greater than or equal to 1 nm and less than or equal to 40 nm, greater than or equal to 1 nm and less than or equal to 30 nm, greater than or equal to 1 nm and less than or equal to 20 nm, greater than or equal to 1 nm and less than or equal to 10 nm, greater than or equal to 1 nm and less than or equal to 5 nm, or greater than or equal to 2 nm and less than or equal to 5 nm.

[Insulating Layers 106 and 110s]

The insulating layers 106 and 110s each functioning as a gate insulating layer preferably have a low defect density. With the insulating layers 106 and 110s having a low defect density, the transistor can have favorable electrical characteristics. In addition, the insulating layers 106 and 110s preferably have high withstand voltage. With the insulating layers 106 and 110s having high withstand voltage, the transistor can have high reliability.

The insulating layers 106 and 110s are preferably insulating layers containing oxygen. Moreover, the insulating layers 106 and 110s are preferably insulating layers from which oxygen is released by heating. Accordingly, in the case where a metal oxide is used for the semiconductor layer 108, for example, oxygen contained in the insulating layers 106 and 110s can be supplied to the metal oxide. Hence, oxygen vacancies in the metal oxide can be repaired, so that the electrical characteristics and reliability of the transistor 100 can be improved.

For each of the insulating layers 106 and 110s, one or more of an insulating oxide, an insulating oxynitride, an insulating nitride oxide, and an insulating nitride can be used, for example. One or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga—Zn oxide can be used for the insulating layers 106 and 110s. The insulating layers 106 and 110s may each have a single-layer structure or a stacked-layer structure. The insulating layers 106 and 110s may have a stacked-layer structure of an oxide and a nitride, for example.

A miniaturized transistor including a thin gate insulating layer might have a large leakage current. When a high dielectric constant material (also referred to as a high-k material) is used for the gate insulating layer, the voltage at the time of operation of the transistor can be lowered while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layers 106 and 110s is preferably small. With the insulating layers 106 and 110s from which a small amount of impurities is released, diffusion of the impurities into the semiconductor layer 108 is inhibited, and the transistor can have favorable electrical characteristics and high reliability.

The insulating layer 106 is formed over the semiconductor layer 108, and thus is preferably a film that can be formed under conditions where damage to the semiconductor layer 108 is small. For example, the insulating layer 106 is preferably formed under conditions where the film formation rate (also referred to as deposition rate) is sufficiently low. For example, when the insulating layer 106 is formed by a plasma CVD method under a low-power condition, damage to the semiconductor layer 108 can be small.

Here, the insulating layers 106 and 110s will be specifically described with the use of a structure in which a metal oxide is used for the semiconductor layer 108 as an example.

To improve the properties of the interface with the semiconductor layer 108, one or more of an oxide and an oxynitride are preferably used for at least the side of the insulating layers 106 and 110s that is in contact with the semiconductor layer 108. For example, one or more of silicon oxide and silicon oxynitride can be suitably used for the insulating layers 106 and 110s. A film from which oxygen is released by heating is further preferably used as the insulating layers 106 and 110s.

Note that the insulating layers 106 and 110s may each have a stacked-layer structure. The insulating layer 106 can have a stacked-layer structure of an oxide film or an oxynitride film on the side in contact with the semiconductor layer 108 and a nitride film on the side in contact with the conductive layer 104. Similarly, the insulating layer 110s can have a stacked-layer structure of an oxide film or an oxynitride film on the side in contact with the semiconductor layer 108 and a nitride film on the side facing the conductive layer 114. For example, one or more of silicon oxide and silicon oxynitride can be suitably used for the oxide film or the oxynitride film. Silicon nitride can be suitably used for the nitride film.

The thickness of each of the insulating layers 106 and 110s (the thickness on the film formation surface) is preferably greater than or equal to 1 nm and less than or equal to 100 nm. Each of the insulating layers 106 and 110s at least partly includes a region with the above thickness.

[Conductive Layers 112a and 112b]

The conductive layers 112a and 112b functioning as the source electrode and the drain electrode can each be formed using one or more of chromium, copper, aluminum, gold, silver, zinc, tantalum, titanium, tungsten, manganese, nickel, iron, cobalt, molybdenum, and niobium; or an alloy including one or more of these metals as its components. A low-resistance conductive material containing one or more of copper, silver, gold, and aluminum can be suitably used for each of the conductive layers 112a and 112b. Copper or aluminum is particularly preferable because of its high mass-productivity.

For each of the conductive layers 112a and 112b, a metal oxide film (also referred to as an oxide conductor) can be used. Examples of the oxide conductor (OC) include In—Sn oxide (ITO), In—W oxide, In—W—Zn oxide, In—Ti oxide, In—Ti—Sn oxide, In—Zn oxide, In—Sn—Si oxide (ITSO), and In—Ga—Zn oxide.

Here, an oxide conductor (OC) is described. For example, when an oxygen vacancy is formed in a metal oxide having semiconductor properties and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

The conductive layers 112a and 112b may each have a stacked-layer structure of a conductive film including the above-described oxide conductor (metal oxide) and a conductive film including a metal or an alloy. The use of the conductive film including a metal or an alloy can reduce the wiring resistance.

A Cu—X alloy film (X is Mn, Ni, Cr, Fe, Co, Mo, Ta, or Ti) may be used for the conductive layers 112a and 112b. The use of a Cu—X alloy film enables the manufacturing cost to be reduced because processing can be performed by a wet etching method.

Note that the conductive layers 112a and 112b may be formed using the same material or different materials.

Here, the conductive layers 112a and 112b will be specifically described with the use of a structure in which a metal oxide is used for the semiconductor layer 108 as an example.

When an oxide semiconductor is used for the semiconductor layer 108, the conductive layers 112a and 112b are oxidized by oxygen contained in the semiconductor layer 108 and have high resistance in some cases. The conductive layers 112a and 112b are oxidized by oxygen contained in the insulating layers 110 and 110s and have high resistance in some cases. Moreover, when the conductive layers 112a and 112b are oxidized by oxygen contained in the semiconductor layer 108, the amount of oxygen vacancies (V_{O}) in the semiconductor layer 108 is increased in some cases. When the conductive layers 112a and 112b are oxidized by oxygen contained in the insulating layers 110 and 110s, the amount of oxygen supplied from the insulating layers 110 and 110s to the semiconductor layer 108 is reduced in some cases.

A material that is less likely to be oxidized is preferably used for the conductive layers 112a and 112b. An oxide conductor is preferably used for the conductive layers 112a and 112b. For example, In—Sn oxide (ITO) or In—Sn—Si oxide (ITSO) can be suitably used. A nitride conductor may be used for the conductive layers 112a and 112b. Examples of the nitride conductor include tantalum nitride and titanium nitride. Each of the conductive layers 112a and 112b may have a stacked-layer structure of the above-described materials.

The conductive layers 112a and 112b including a material that is less likely to be oxidized can be inhibited from being oxidized by oxygen contained in the semiconductor layer 108 or oxygen contained in the insulating layers 110 and 110s and having high resistance. Furthermore, it is possible to increase the amount of oxygen supplied from the insulating layers 110 and 110s to the semiconductor layer 108 while an increase in the amount of oxygen vacancy (V_{O}) in the semiconductor layer 108 is inhibited.

### [Conductive Layers 104 and 114]

The conductive layers 104 and 114 functioning as the gate electrode and the back gate electrode can each be formed using one or more of chromium, copper, aluminum, gold, silver, zinc, molybdenum, tantalum, titanium, tungsten, manganese, nickel, iron, cobalt, and niobium or an alloy including one or more of these metals as its components. A material that can be used for the conductive layers 112a and 112b may be used for the conductive layers 104 and 114. Since the insulating layer 116 that can be formed by plasma treatment or the like in an oxygen atmosphere is provided on the side surface and the top surface of the conductive layer 114 as described above, the conductive layer 114 is preferably formed using a conductive material that is easily oxidized. For example, aluminum is preferably used for the conductive layer 114.

Although the conductive layer 104 has a single-layer structure in FIG. 1B and the like, one embodiment of the present invention is not limited thereto. For example, the conductive layer 104 may have a stacked-layer structure of two or more layers. For example, when the conductive layer 104 has a two-layer structure, the first conductive layer (the conductive layer on the insulating layer 106 side) can be formed using a nitride or an oxide, and the second conductive layer can be formed using one or more of chromium, copper, aluminum, gold, silver, zinc, molybdenum, tantalum, titanium, tungsten, manganese, nickel, iron, cobalt, and niobium or an alloy containing one or more of these metals as its components. As another example, when the conductive layer 104 has a three-layer structure, the first conductive layer (the conductive layer on the insulating layer 106 side) can be formed using an alloy containing one or more of the above metals as a component or a nitride of the metal(s) or the alloy; the second conductive layer can be formed using an alloy containing one or more of the above metals as its components; and the third conductive layer can be formed using an alloy containing one or more of the above metals as its components or a nitride of the metal(s) or the alloy.

### [Insulating Layer 116]

The insulating layer 116 is an oxide including the element included in the conductive layer 114. Examples of the insulating layer 116 include an oxide of the conductive layer 114, specifically, a metal oxide such as aluminum oxide and tantalum oxide. For example, in the case where aluminum is used for the conductive layer 114, the insulating layer 116 is aluminum oxide. The insulating layer 116 is preferably an insulating layer that can be formed by plasma treatment or the like performed on the conductive layer 114 in an oxygen atmosphere.

Like the insulating layers 110a and 110c, the insulating layer 116 is preferably an insulating layer having a blocking property against oxygen. Accordingly, oxygen released from the insulating layers 110s and 110b can be inhibited from diffusing to the conductive layer 114 side through the insulating layer 116. Furthermore, the insulating layer having the same function as the insulating layers 110a and 110c can be formed without using a deposition method such as a plasma CVD method or a sputtering method; hence, the number of times of employing the above deposition method can be reduced, and the productivity can be increased in some cases. An example of the insulating layer 116 that satisfies the above is aluminum oxide.

### [Insulating Layer 195]

The insulating layer 195 functioning as the protective layer for the transistor 100 is preferably formed using a material that does not easily allow diffusion of impurities. Providing the insulating layer 195 can effectively inhibit diffusion of impurities into the transistor from the outside and increase the reliability of the transistor. Examples of impurities include water and hydrogen. The insulating layer 195 can be an insulating layer including an inorganic material or an insulating layer including an organic material. For example, an inorganic material such as an oxide, an oxynitride, a nitride oxide, or a nitride can be suitably used for the insulating layer 195. Specifically, one or more of silicon nitride, silicon nitride oxide, silicon oxynitride, aluminum oxide, aluminum oxynitride, aluminum nitride, hafnium oxide, and hafnium aluminate can be used. As an organic material, for example, one or more of an acrylic resin and a polyimide resin can be used. As an organic material, a photosensitive material may be used. A stack including two or more of the above insulating films may also be used. The insulating layer 195 may have a stacked-layer structure of an insulating layer including an inorganic material and an insulating layer including an organic material.

### [Substrate 102]

There is no particular limitation on the properties of the material of the substrate 102 as long as the material has heat resistance high enough to withstand at least heat treatment to be performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. Alternatively, any of these substrates provided with a semiconductor element may be used as the substrate 102. Note that the shape of a semiconductor substrate and an insulating substrate may be circular or square.

A flexible substrate may be used as the substrate 102, and the transistor 100 and the like may be formed directly on the flexible substrate. Alternatively, a separation layer may be provided between the substrate 102 and the transistor 100 and the like. The separation layer can be used when part or the whole of a semiconductor device completed thereover is separated from the substrate 102 and transferred onto another substrate. In that case, the transistor 100 and the like can be transferred onto a substrate having low heat resistance or a flexible substrate as well.

### [Composition of Metal Oxide Included in Semiconductor Layer 108]

The composition of the metal oxide included in the semiconductor layer 108 will be described below.

The composition of the metal oxide included in the semiconductor layer 108 significantly affects the electrical characteristics and reliability of the transistor 100.

For example, a metal oxide with a higher indium content enables the transistor to have a higher on-state current.

In the case where In—Zn oxide is used for the semiconductor layer 108, it is preferable to use a metal oxide in which the atomic ratio of indium is higher than or equal to that of zinc. For example, a metal oxide with metal elements in an atomic ratio of In:Zn=1:1, In:Zn=2:1, In:Zn=3:1, In:Zn=4:1, In:Zn=5:1, In:Zn=7:1, or In:Zn=10:1, or the neighborhood thereof can be used.

In the case where In—Sn oxide is used for the semiconductor layer 108, it is preferable to use a metal oxide in which the atomic ratio of indium is higher than or equal to that of tin. For example, a metal oxide with metal elements in an atomic ratio of In:Sn=1:1, In:Sn=2:1, In:Sn=3:1, In:Sn=4:1, In:Sn=5:1, In:Sn=7:1, or In:Sn=10:1, or the neighborhood thereof can be used.

In the case where In-M-Zn oxide is used for the semiconductor layer 108, it is possible to use a metal oxide in which the atomic ratio of indium is higher than that of the element M. It is further preferable to use a metal oxide in which the atomic ratio of zinc is higher than that of the element M. For example, a metal oxide with metal elements in an atomic ratio of In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or the neighborhood thereof can be used for the semiconductor layer 108.

In the case where a plurality of metal elements are contained as the element M, the sum of the atomic ratios of the metal elements can be the atomic ratio of the element M. In In—Ga—Al—Zn oxide where gallium and aluminum are contained as the element M, for example, the sum of the atomic ratios of gallium and aluminum can be the atomic ratio of the element M. The atomic ratio of indium to the element M and zinc is preferably within the range given above. In In—Ga—Sn—Zn oxide where gallium and tin are contained as the element M, for example, the sum of the atomic ratios of gallium and tin can be the atomic ratio of the element M. The atomic ratio of indium to the element M and zinc is preferably within the range given above.

It is preferable to use a metal oxide in which the proportion of the number of indium atoms to the number of atoms of the metal elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, further preferably higher than or equal to 35 atomic % and lower than or equal to 90 atomic %, further preferably higher than or equal to 40 atomic % and lower than or equal to 90 atomic %, further preferably higher than or equal to 45 atomic % and lower than or equal to 90 atomic %, further preferably higher than or equal to 50 atomic % and lower than or equal to 80 atomic %, further preferably higher than or equal to 60 atomic % and lower than or equal to 80 atomic %, further preferably higher than or equal to 70 atomic % and lower than or equal to 80 atomic %. For example, when In—Ga—Zn oxide is used for the semiconductor layer 108, the proportion of the number of indium atoms to the sum of the numbers of indium atoms, gallium atoms, and zinc atoms is preferably within the ranges given above.

In this specification and the like, the proportion of the number of indium atoms to the number of atoms of the metal elements contained is sometimes referred to as indium content. The same applies to other metal elements.

A transistor including a metal oxide with a higher indium content can have a higher on-state current. By using such a transistor as a transistor required to have a high on-state current, a semiconductor device having excellent electrical characteristics can be provided.

Analysis of the composition of the metal oxide can be performed by EDX, XPS, inductively coupled plasma-mass spectrometry (ICP-MS), or inductively coupled plasma-atomic emission spectrometry (ICP-AES). Alternatively, any of these methods may be combined with each other for the analysis. Note that as for an element whose content is low, the actual content may be different from the content obtained by analysis because of the influence of the analysis accuracy. For example, in the case where the content of the element M is low, the content of the element M obtained by analysis may be lower than the actual content or difficult to quantify or the element M is not detected in some cases.

In this specification and the like, a composition in the neighborhood includes ±30% of an intended atomic ratio. For example, in the case of describing an atomic ratio of In:M:Zn=4:2:3 or a composition in the neighborhood thereof, the case is included in which with the atomic ratio of indium being 4, the atomic ratio of M is higher than or equal to 1 and lower than or equal to 3 and the atomic ratio of zinc is higher than or equal to 2 and lower than or equal to 4. In the case of describing an atomic ratio of In:M:Zn=5:1:6 or a composition in the neighborhood thereof, the case is included in which with the atomic ratio of indium being 5, the atomic ratio of M is higher than 0.1 and lower than or equal to 2 and the atomic ratio of zinc is higher than or equal to 5 and lower than or equal to 7. In the case of describing an atomic ratio of In:M:Zn=1:1:1 or a composition in the neighborhood thereof, the case is included in which with the atomic ratio of indium being 1, the atomic ratio of M is higher than 0.1 and lower than or equal to 2 and the atomic ratio of zinc is higher than 0.1 and lower than or equal to 2.

Here, the reliability of a transistor is described. One of indexes for evaluating the reliability of a transistor is a gate bias temperature (GBT) stress test in which the transistor is kept at a high temperature with an electric field applied to its gate. The GBT stress test includes a positive bias temperature stress (PBTS) test in which a transistor is kept at a high temperature with a positive potential (positive bias) with respect to a source potential and a drain potential supplied to its gate and a negative bias temperature stress (NBTS) test in which a transistor is kept at a high temperature with a negative potential (negative bias) supplied to its gate. The PBTS test and the NBTS test conducted in a state where irradiation with light is performed are respectively referred to as a positive bias temperature illumination stress (PBTIS) test and a negative bias temperature illumination stress (NBTIS) test.

In an n-channel transistor, a positive potential is supplied to a gate to turn on the transistor (to allow a current to flow through the transistor); thus, the amount of change in the threshold voltage in a PBTS test is one of important indexes to be focused on as a reliability indicator of the transistor.

With the use of a metal oxide that does not contain gallium or has a low gallium content for the semiconductor layer 108, the transistor can be highly reliable against positive bias application. In other words, the amount of change in the threshold voltage of the transistor in the PBTS test can be small. In the case of using a metal oxide containing gallium, the gallium content is preferably lower than the indium content. As a result, the transistor can have high reliability.

One of the factors changing the threshold voltage in the PBTS test is carrier trapping by defect states at the interface between a semiconductor layer and a gate insulating layer or in the vicinity of the interface. As the density of defect states increases, the amount of carrier traps by defect states increases; thus, degradation in the PBTS test becomes more significant. Generation of a defect state can be inhibited by a reduction in the gallium content in a region of the semiconductor layer that is in contact with the gate insulating layer.

The following can be given, for example, as the reason why the amount of change in the threshold voltage in the PBTS test can be reduced when a metal oxide that does not contain gallium or has a low gallium content is used for the semiconductor layer. Gallium contained in the metal oxide more easily attracts oxygen than another metal element (e.g., indium or zinc). Therefore, when, at the interface between the metal oxide containing a large amount of gallium and the gate insulating layer, gallium is bonded to excess oxygen in the gate insulating layer, carrier (here, electron) trap sites are likely to be generated easily. This can cause the change in the threshold voltage when a positive potential is applied to a gate and carriers are trapped at the interface between the semiconductor layer and the gate insulating layer.

Specifically, in the case where In—Ga—Zn oxide is used for the semiconductor layer 108, a metal oxide in which the atomic ratio of indium is higher than that of gallium can be used for the semiconductor layer 108. It is preferable to use a metal oxide in which the atomic ratio of zinc is higher than that of gallium. In other words, a metal oxide with metal elements in an atomic ratio satisfying both relations In>Ga and Zn>Ga is preferably used for the semiconductor layer 108.

In the case where a metal oxide is used for the semiconductor layer 108, the proportion of the number of gallium atoms to the number of atoms of the metal elements contained in the metal oxide is preferably higher than 0 atomic % and lower than or equal to 50 atomic %, further preferably higher than or equal to 0.1 atomic % and lower than or equal to 40 atomic %, further preferably higher than or equal to 0.1 atomic % and lower than or equal to 35 atomic %, further preferably higher than or equal to 0.1 atomic % and lower than or equal to 30 atomic %, further preferably higher than or equal to 0.1 atomic % and lower than or equal to 25 atomic %, further preferably higher than or equal to 0.1 atomic % and lower than or equal to 20 atomic %, further preferably higher than or equal to 0.1 atomic % and lower than or equal to 15 atomic %, further preferably higher than or equal to 0.1 atomic % and lower than or equal to 10 atomic %. The reduction in the gallium content in the semiconductor layer enables the transistor to be highly resistant to the PBTS test. Note that oxygen vacancies (V_{O}) are less likely to be generated in the metal oxide when the metal oxide contains gallium.

A metal oxide that does not contain gallium may be used for the semiconductor layer 108. For example, In—Zn oxide can be used for the semiconductor layer 108. In this case, when the atomic ratio of indium to the metal elements contained in the metal oxide is increased, the field-effect mobility of the transistor can be increased. By contrast, when the atomic ratio of zinc to the metal elements contained in the metal oxide is increased, the metal oxide has high crystallinity; thus, a change in the electrical characteristics of the transistor can be suppressed and the reliability can be increased. A metal oxide that contains neither gallium nor zinc, such as indium oxide, may be used for the semiconductor layer 108. The use of a metal oxide that does not contain gallium can make a change in the threshold voltage particularly in the PBTS test extremely small.

For example, an oxide containing indium and zinc can be used for the semiconductor layer 108. In this case, a metal oxide with metal elements in an atomic ratio of In:Zn=2:3 or the neighborhood thereof, for example, can be used.

Although the case of using gallium is described as an example, the same applies to the case where the element M is used instead of gallium. A metal oxide in which the atomic ratio of indium is higher than that of the element M is preferably used for the semiconductor layer 108. Furthermore, a metal oxide in which the atomic ratio of zinc is higher than that of the element M is preferably used.

With the use of a metal oxide with a low content of the element M for the semiconductor layer 108, the transistor can be highly reliable against positive bias application. With the use of the transistor as a transistor that is required to have high reliability against positive bias application, a highly reliable semiconductor device can be provided.

Next, the reliability of a transistor against light is described.

Light incidence on a transistor may change its electrical characteristics. In particular, a transistor provided in a region on which light can be incident preferably exhibits a small change in electrical characteristics under light irradiation and has high reliability against light. The reliability against light can be evaluated by the amount of change in the threshold voltage in an NBTIS test, for example.

The high content of the element M in a metal oxide enables the transistor to be highly reliable against light. In other words, the amount of change in the threshold voltage of the transistor in the NBTIS test can be small. Specifically, in a metal oxide in which the atomic ratio of the element M is higher than or equal to that of indium, the band gap is increased and accordingly the amount of change in the threshold voltage of the transistor in the NBTIS test can be reduced. The band gap of the metal oxide in the semiconductor layer 108 is preferably greater than or equal to 2.0 eV, further preferably greater than or equal to 2.5 eV, further preferably greater than or equal to 3.0 eV, further preferably greater than or equal to 3.2 eV, further preferably greater than or equal to 3.3 eV, further preferably greater than or equal to 3.4 eV, further preferably greater than or equal to 3.5 eV.

For example, a metal oxide with metal elements in an atomic ratio of In:M:Zn=1:1:1, In:M:Zn=1:1:1.2, In:M:Zn=1:3:2, In:M:Zn=1:3:3, In:M:Zn=1:3:4, or the neighborhood thereof can be used for the semiconductor layer 108.

In particular, a metal oxide in which the proportion of the number of atoms of the element M to the number of atoms of the metal elements contained in the metal oxide is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, further preferably higher than or equal to 40 atomic % and lower than or equal to 60 atomic %, further preferably higher than or equal to 50 atomic % and lower than or equal to 60 atomic % can be suitably used for the semiconductor layer 108.

In the case where In—Ga—Zn oxide is used for the semiconductor layer 108, a metal oxide in which the atomic ratio of indium is lower than or equal to that of gallium can be used. For example, a metal oxide with metal elements in an atomic ratio of In:Ga:Zn=1:1:1, In:Ga:Zn=1:1:1.2, In:Ga:Zn=1:3:2, In:Ga:Zn=1:3:3, In:Ga:Zn=1:3:4, or the neighborhood thereof can be used.

In particular, a metal oxide in which the proportion of the number of gallium atoms to the number of atoms of the metal elements contained in the metal oxide is higher than or equal to 20 atomic % and lower than or equal to 60 atomic %, preferably higher than or equal to 30 atomic % and lower than or equal to 60 atomic %, further preferably higher than or equal to 40 atomic % and lower than or equal to 60 atomic %, further preferably higher than or equal to 50 atomic % and lower than or equal to 60 atomic % can be suitably used for the semiconductor layer 108.

With the use of a metal oxide with a high content of the element M for the semiconductor layer 108, the transistor can be highly reliable against light. With the use of the transistor as a transistor that is required to have high reliability against light, a highly reliable semiconductor device can be provided.

As described above, electrical characteristics and reliability of a transistor depend on the composition of the metal oxide used for the semiconductor layer 108. Therefore, by determining the composition of the metal oxide in accordance with the electrical characteristics and reliability required for the transistor, a semiconductor device can have both excellent electrical characteristics and high reliability.

The semiconductor layer 108 may have a stacked-layer structure of two or more metal oxide layers. The two or more metal oxide layers included in the semiconductor layer 108 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer 108 may have different compositions. For example, a stacked-layer structure of a first metal oxide layer having an atomic ratio of In:M:Zn=1:3:4 or a composition in the neighborhood thereof and a second metal oxide layer that has an atomic ratio of In:M:Zn=1:1:1 or a composition in the neighborhood thereof and is formed over the first metal oxide layer can be suitably employed. In particular, gallium or aluminum is preferably used as the element M. A stacked-layer structure of one selected from indium oxide, indium gallium oxide, and IGZO and one selected from IAZO, IAGZO, and ITZO (registered trademark) may be employed, for example.

### Structure Example 2

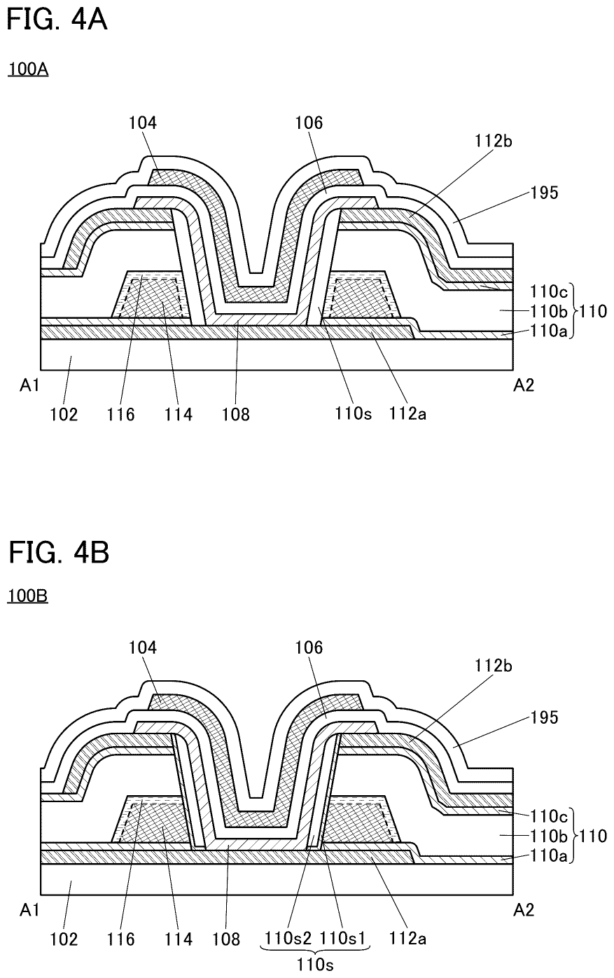

FIG. 4A illustrates a structure example of a transistor 100A having a structure different from that of the transistor 100 illustrated in FIG. 1A to FIG. 2. FIG. 4A is a cross-sectional view corresponding to the dashed-dotted line A1-A2 in the plan view of FIG. 1A.

The transistor 100A illustrated in FIG. 4A differs from the transistor 100 illustrated in FIG. 1B mainly in that the lower end portion of the insulating layer 110s is in contact with the top surface of the conductive layer 112a.

In the transistor 100A, the side surface of the insulating layer 110a, the side surface of the insulating layer 116, the side surface of the insulating layer 110b, the side surface of the insulating layer 110c, and the side surface of the conductive layer 112b are aligned or substantially aligned with each other in the opening 143. That is, the insulating layer 110a in the transistor 100A, unlike in the transistor 100, does not include a protruding portion in the opening 143. The insulating layer 110s is provided in contact with the top surface of the conductive layer 112a in the opening 143, the side surface of the insulating layer 110a in the opening 143, the side surface of the insulating layer 116 in the opening 143, the side surface of the insulating layer 110b in the opening 143, the side surface of the insulating layer 110c in the opening 143, and the side surface of the conductive layer 112b in the opening 143.

In the transistor 100A having the above structure, oxygen contained in the insulating layer 110s might be diffused into the conductive layer 112a. However, in the case where the above-described material that is less likely to be oxidized is used for the conductive layer 112a, part of the insulating layer 110a does not always need to be left between the insulating layer 110s and the conductive layer 112a. Employing the structure of the transistor 100A increases the degree of manufacturing freedom as compared to the transistor 100 and facilitates manufacture of the transistor in some cases.

The description of the transistor 100 can be referred to for the transistor 100A other than those described above.

### Structure Example 3

FIG. 4B illustrates a structure example of a transistor 100B having a structure different from that of the transistor 100 illustrated in FIG. 1A to FIG. 2. FIG. 4B is a cross-sectional view corresponding to the dashed-dotted line A1-A2 in the plan view of FIG. 1A.

The transistor 100B illustrated in FIG. 4B differs from the transistor 100 illustrated in FIG. 1B mainly in that the insulating layer 110s has a stacked-layer structure of an insulating layer 110s1 and an insulating layer 110s2 over the insulating layer 110s1. In the transistor 100B, the insulating layer 116 is not provided on the side surface of the conductive layer 114 on the opening 143 side. The insulating layer 110s1 is provided in contact with the top surface of the conductive layer 112a, the side surface of the insulating layer 110a, the side surface of the conductive layer 114, the side surface of the insulating layer 116, the side surface of the insulating layer 110b, the side surface of the insulating layer 110c, and the side surface of the conductive layer 112b. The insulating layer 110s2 is provided to face the top surface of the conductive layer 112a, the side surface of the insulating layer 110a, the side surface of the conductive layer 114, the side surface of the insulating layer 116, the side surface of the insulating layer 110b, the side surface of the insulating layer 110c, and the side surface of the conductive layer 112b with the insulating layer 110s1 therebetween.

For the insulating layer 110s1, the material, the manufacturing method, and the like used for the insulating layers 110a and 110c can be used, for example. For the insulating layer 110s2, the material, the manufacturing method, and the like used for the insulating layer 110b can be used, for example.

In the case where the insulating layer 110s2 having a function of supplying oxygen is in contact with the conductive layer 114, there is concern that the conductive layer 114 is oxidized, the amount of oxygen contained in the insulating layer 110s2 is reduced, and thus the amount of oxygen supplied from the insulating layer 110s2 to the semiconductor layer 108 is reduced. When the insulating layer 110s has a stacked-layer structure of the insulating layers 110s1 and 110s2, the insulating layer 110s2 and the conductive layer 114 can be prevented from being in contact with each other. Thus, oxidation of the conductive layer 114 due to oxygen contained in the insulating layer 110s2 can be inhibited. Moreover, a reduction in the amount of oxygen supplied from the insulating layer 110s2 to the semiconductor layer 108 can be inhibited.

Providing the insulating layer 110s1 can reduce the step of providing the insulating layer 116 on the side surface of the conductive layer 114 on the opening 143 side. Since the insulating layer 110s2 is in contact with neither the conductive layer 112a nor the conductive layer 112b, oxygen contained in the insulating layer 110s2 can be prevented from diffusing not only to the conductive layer 112a side but also to the conductive layer 112b side. Thus, a low-resistance conductive material that is easily oxidized can be used for both of the conductive layers 112a and 112b; hence, the range of choices for the materials can be widened.

The description of the transistor 100 can be referred to for the transistor 100B other than those described above.

### Structure Example 4

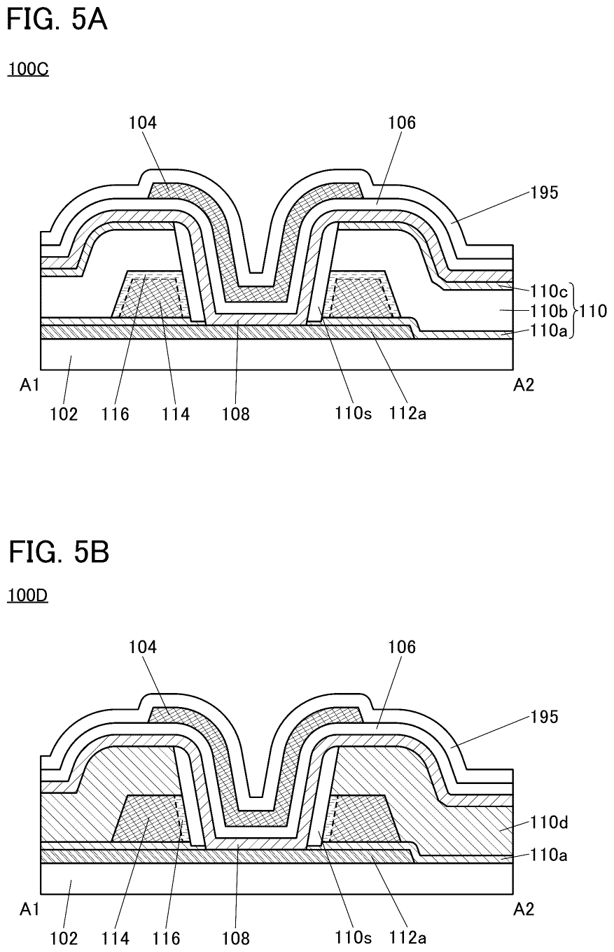

FIG. 5A illustrates a structure example of a transistor 100C having a structure different from that of the transistor 100 illustrated in FIG. 1A to FIG. 2. FIG. 5A is a cross-sectional view corresponding to the dashed-dotted line A1-A2 in the plan view of FIG. 1A.

The transistor 100C illustrated in FIG. 5A differs from the transistor 100 illustrated in FIG. 1B mainly in that the conductive layer 112b is not provided and the end portion of the semiconductor layer 108 extends beyond the end portions of the conductive layers 114 and 112a in the plan view.

In the transistor 100C, the semiconductor layer 108 includes regions in contact with the top surface of the conductive layer 112a, the side surface of the insulating layer 110s, and the top surface of the insulating layer 110c. The semiconductor layer 108 in the transistor 100C can have both the function of the semiconductor layer including the channel formation region and the function of the other of the source electrode and the drain electrode. For example, in the semiconductor layer 108, a region facing the insulating layer 110s in the opening 143 can function as the channel formation region, and a region on the outer side of the channel formation region (the region in contact with the top surface of the insulating layer 110c) can function as the other of the source electrode and the drain electrode.

By reducing the resistance of some regions of the semiconductor layer 108, the regions can serve as a source region and a drain region of the transistor. For example, the resistance of the semiconductor layer 108 can be reduced by supplying an impurity functioning as a dopant, such as boron, to the semiconductor layer 108 from a direction perpendicular to the substrate surface by an ion implantation method, an ion doping method, a plasma immersion ion implantation method, plasma treatment, or the like. Alternatively, in the case where an oxide semiconductor is used for the semiconductor layer 108, a silicon nitride film or the like is formed over regions of the semiconductor layer 108 that do not overlap with the opening 143 to change the regions into an oxide conductor (OC), whereby low-resistance regions can be formed in the semiconductor layer 108. In such a manner, the resistance of the regions of the semiconductor layer 108 corresponding to the source region and the drain region can be made lower than that of the channel formation region. Thus, the channel formation region and the source region and the drain region having lower resistance than the channel formation region can be formed in the semiconductor layer 108. Accordingly, in the transistor 100C, the regions corresponding to the source electrode and the drain electrode can be formed in the semiconductor layer 108 without providing the conductive layer 112b. Since the conductive layer 112b is not provided in the transistor 100C, the number of steps for manufacturing the transistor can be reduced.

The description of the transistor 100 can be referred to for the transistor 100C other than those described above.

### Structure Example 5

FIG. 5B illustrates a structure example of a transistor 100D having a structure different from that of the transistor 100 illustrated in FIG. 1A to FIG. 2. FIG. 5B is a cross-sectional view corresponding to the dashed-dotted line A1-A2 in the plan view of FIG. 1A.

The transistor 100D illustrated in FIG. 5B differs from the transistor 100C illustrated in FIG. 5A mainly in including an insulating layer 110d having a single-layer structure instead of the insulating layers 110b and 110c in the transistor 100.

In the transistor 100D, the insulating layer 110d is preferably formed using any of the materials that can be used for the insulating layers 110a and 110c described above. For example, silicon nitride or silicon nitride oxide is preferably used for the insulating layer 110d. That is, a material having a high blocking property against oxygen and hydrogen is preferably used. In that case, the conductive layer 114 can be inhibited from being oxidized by diffusion of oxygen from the outer side of the insulating layers 110a and 110d. Furthermore, oxygen in the semiconductor layer 108 can be inhibited from diffusing towards the insulating layers 110a and 110d and forming oxygen vacancies (V_{O}) in the semiconductor layer 108. Providing the insulating layer 110d can reduce the step of forming the insulating layer 116 at the contact interface between the conductive layer 114 and the insulating layer 110d. With the insulating layer 110d having a single-layer structure, the number of steps for forming the insulating layer 110 can be smaller than that in the transistor 100 and the like.

The description of the transistor 100C can be referred to for the transistor 100D other than those described above.

### Structure Example 6

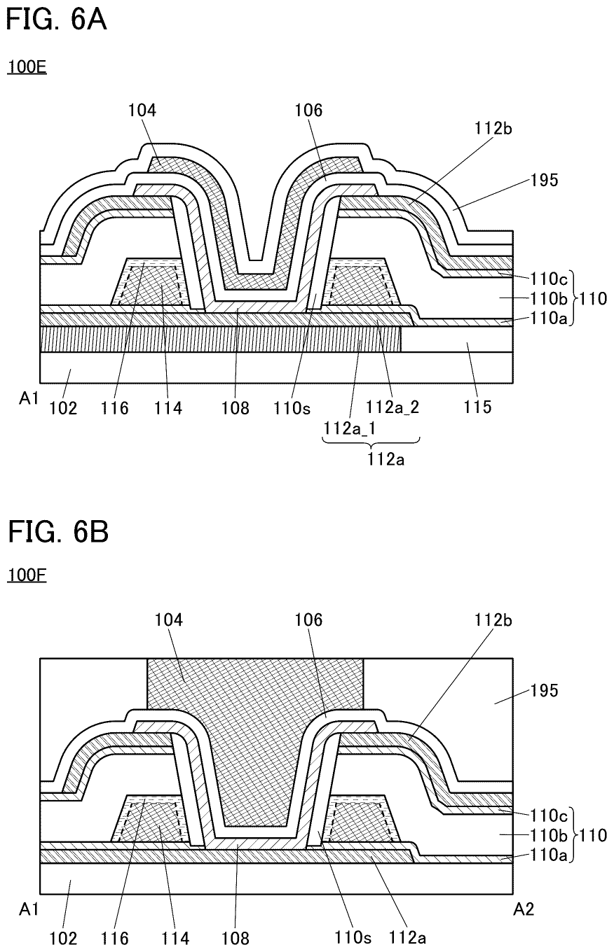

FIG. 6A illustrates a structure example of a transistor 100E having a structure different from that of the transistor 100 illustrated in FIG. 1A to FIG. 2. FIG. 6A is a cross-sectional view corresponding to the dashed-dotted line A1-A2 in the plan view of FIG. 1A.

The transistor 100E illustrated in FIG. 6A differs from the transistor 100 illustrated in FIG. 1B mainly in that the conductive layer 112a has a stacked-layer structure.

In the transistor 100E, the conductive layer 112a has a stacked-layer structure including a conductive layer 112a_1 and a conductive layer 112a_2 over the conductive layer 112a_1. The conductive layer 112a_1 is provided to be embedded in an opening formed in an insulating layer 115 over the substrate 102, and the top surface of the conductive layer 112a_1 and the top surface of the insulating layer 115 are planarized. The conductive layer 112a_2 is placed over the conductive layer 112a_1 and the insulating layer 115. In the transistor 100E, the top surface of the insulating layer 115 and the top surface of the conductive layer 112a_1 are level with or substantially level with each other.

In the transistor 100E, the top surface of the insulating layer 115 and the top surface of the conductive layer 112a_1 are level with or substantially level with each other, whereby a step caused on the formation surface of the insulating layer 110 and the conductive layer 112b can be small. Thus, a step that would be caused on the top surface of the conductive layer 112b and a step that would be caused on the top surface of the insulating layer 110 can be small. Accordingly, in the process of forming the insulating layer 110s (e.g., an etch-back step), the insulating layer can be inhibited from remaining on the top surface of the conductive layer 112b and the top surface of the insulating layer 110; hence, the insulating layer can be selectively formed only on the side surface of the insulating layer 116 in the opening 143, the side surface of the insulating layer 110b in the opening 143, the side surface of the insulating layer 110c in the opening 143, and the side surface of the conductive layer 112b in the opening 143.

Note that a step in which a planarization film is formed on the surface of an uneven film and highly anisotropic etching (e.g., dry etching) is performed on the uneven film together with the planarization film to reduce the unevenness of the film is sometimes referred to as an etch-back step.

Although an end portion of the conductive layer 112a_2 is positioned outward from an end portion of the conductive layer 112a_1 in the example of the transistor 100E, the end portion of the conductive layer 112a_2 may be positioned inward from the end portion of the conductive layer 112a_1. In the case of providing a plug that connects the conductive layer 112a and a conductive layer thereover, the top surface of the conductive layer 112a_2 in a region extending beyond the conductive layer 112a_1 may be in contact with the plug. The plug is provided to fill an opening in the insulating layer 110, the insulating layer 195, and the like.

As described above, a material that is less likely to be oxidized is preferably used for the conductive layers 112a and 112b in contact with the semiconductor layer 108. However, the use of a material that is less likely to be oxidized might increase the resistance of the conductive layers 112a and 112b. The conductive layers 112a and 112b function as wirings and thus preferably have low resistance. In view of this, a material that is less likely to be oxidized is used for the conductive layer 112a_2, which includes a region in contact with the semiconductor layer 108, and a low-resistance material is used for the conductive layer 112a_1, which does not include a region in contact with the semiconductor layer 108; thus, the resistance of the conductive layer 112a as a whole can be reduced.

As described above, particularly in the case where the channel length is small, oxygen vacancies (V_{O}) and V_{O}H in the channel formation region greatly affect the electrical characteristics and reliability of the transistor. When a material that is less likely to be oxidized is used for the conductive layer 112a_2, an increase in the amount of oxygen vacancy (V_{O}) and V_{O}H in the semiconductor layer 108 can be inhibited. Thus, the transistor with a small channel length can have favorable electrical characteristics and high reliability.

For the conductive layer 112a_2, one or more of an oxide conductor and a nitride conductor can be suitably used. For the conductive layer 112a_1, a material having lower resistance than the conductive layer 112a_2 can be used. For the conductive layer 112a_1, one or more of copper, aluminum, titanium, tungsten, and molybdenum or an alloy containing one or more of these metals as its components can be suitably used, for example. Specifically, In—Sn—Si oxide (ITSO) and tungsten can be suitably used for the conductive layer 112a_2 and the conductive layer 112a_1, respectively.

For the insulating layer 115, an inorganic insulating material or an organic insulating material can be used. The insulating layer 115 may have a stacked-layer structure of an inorganic insulating material and an organic insulating material. For example, any of the materials and structures given for the insulating layers 110a, 110c, and 195 and the like can be suitably used for the insulating layer 115.

The description of the transistor 100 can be referred to for the transistor 100E other than those described above.

### Structure Example 7

FIG. 6B illustrates a structure example of a transistor 100F having a structure different from that of the transistor 100 illustrated in FIG. 1A to FIG. 2. FIG. 6B is a cross-sectional view corresponding to the dashed-dotted line A1-A2 in the plan view of FIG. 1A.

The transistor 100F illustrated in FIG. 6B differs from the transistor 100 illustrated in FIG. 1B mainly in the structure of the conductive layer 104 and the structure of the insulating layer 195.

In the transistor 100F, the conductive layer 104 is provided to fill a concave portion that is defined by the semiconductor layer 108 and the insulating layer 106 reflecting the shape of the opening 143, and the insulating layer 195 is provided to embed the conductive layer 104. In the transistor 100F, the top surface of the conductive layer 104 and the top surface of the insulating layer 195 are planarized and are level with or substantially level with each other.

In the transistor 100F having the above structure, coverage with a film provided over the conductive layer 104 and the insulating layer 195 can be improved.

The description of the transistor 100 can be referred to for the transistor 100F other than those described above.

### <Example of Manufacturing Method>

A method for manufacturing the transistor of one embodiment of the present invention will be described below with reference to drawings. Here, the transistor 100 illustrated in FIG. 1B and the like will be described as an example.

Note that thin films (e.g., insulating films, semiconductor films, and conductive films) included in a semiconductor device can be formed by any of a sputtering method, a chemical vapor deposition (CVD) method, a vacuum evaporation method, a pulsed laser deposition (PLD) method, an ALD method, and the like.

Examples of a sputtering method include an RF sputtering method using a high-frequency power source for a sputtering power source, a DC sputtering method using a DC power source, and a pulsed DC sputtering method in which a voltage applied to an electrode is changed in a pulsed manner. An RF sputtering method is mainly used to form an insulating film, and a DC sputtering method is mainly used to form a metal conductive film. A pulsed DC sputtering method is mainly used in the case where a compound such as an oxide, a nitride, or a carbide is deposited by a reactive sputtering method.

CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas.

A high-quality film can be obtained at a relatively low temperature by a PECVD method. A thermal CVD method does not use plasma and thus can cause less plasma damage to an object. A wiring, an electrode, an element (e.g., a transistor or a capacitor), or the like included in a semiconductor device might be charged up by receiving charges from plasma, for example. In that case, accumulated charges might break the wiring, electrode, element, or the like included in the semiconductor device. A thermal CVD method, which does not use plasma, does not cause such plasma damage, and thus can increase the yield of the semiconductor device. A thermal CVD method yields a film with few defects because of no plasma damage during deposition.

As an ALD method, a thermal ALD method, in which a precursor and a reactant react with each other only by a thermal energy, a PEALD method, in which a reactant excited by plasma is used, or the like can be used.

A CVD method and an ALD method differ from a sputtering method by which particles ejected from a target or the like are deposited. Thus, an ALD method can provide good step coverage, almost regardless of the shape of an object. In particular, an ALD method can provide excellent step coverage and excellent thickness uniformity and thus can be suitably used for covering a surface of an opening portion with a high aspect ratio, for example. However, an ALD method has a relatively low deposition rate; hence, it is sometimes preferable to combine an ALD method with another deposition method with a high deposition rate, such as a CVD method.

By a CVD method, a film with a desired composition can be formed by adjusting the flow rate ratio of the source gases. For example, a CVD method enables formation of a film whose composition is gradually changed by changing the flow rate ratio of the source gases during deposition. In the case where the film is formed while changing the flow rate ratio of the source gases, as compared to the case where the film is formed using a plurality of film formation chambers, time taken for the film formation can be reduced because time taken for transfer or pressure adjustment is not required. Hence, the productivity of the semiconductor device can be improved in some cases.

An ALD method, in which a plurality of different kinds of precursors are introduced at a time, enables formation of a film with a desired composition. In the case where a plurality of different kinds of precursors are introduced, the number of cycles for each precursor is controlled, whereby a film with a desired composition can be formed.

The thin films (e.g., the insulating films, semiconductor films, and conductive films) included in the semiconductor device can be formed by a method such as spin coating, dipping, spray coating, inkjet printing, dispensing, screen printing, or offset printing or with a doctor knife, a slit coater, a roll coater, a curtain coater, or a knife coater.

To process the thin films included in the semiconductor device, a photolithography method or the like can be employed. Besides, a nanoimprinting method, a sandblasting method, a lift-off method, or the like may be employed to process the thin films. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by exposure and development.

As light used for exposure in the photolithography method, for example, light with the i-line (wavelength: 365 nm), light with the g-line (wavelength: 436 nm), light with the h-line (wavelength: 405 nm), or light in which two or more of the i-line, the g-line, and the h-line are mixed can be used. Alternatively, ultraviolet rays, KrF laser light, ArF laser light, or the like can be used. Exposure may be performed by liquid immersion exposure technique. As the light used for the exposure, extreme ultraviolet (EUV) light or X-rays may be used. Furthermore, instead of the light for exposure, an electron beam can be used. It is preferable to use EUV light, X-rays, or an electron beam to perform extremely minute processing. Note that a photomask is not needed when exposure is performed by scanning with a beam such as an electron beam.

For etching of thin films, a dry etching method, a wet etching method, or a sandblasting method can be used, for example.

For planarization treatment of thin films, typically, a polishing method such as a CMP method can be suitably used. A reflow method in which a conductive layer is fluidized by heat treatment can be suitably used. A combination of a reflow method and a CMP method may be used. Alternatively, dry etching treatment or plasma treatment may be used. Note that polishing treatment, dry etching treatment, or plasma treatment may be performed more than once, or these treatments may be performed in combination. In the case where the treatments are performed in combination, the order of steps is not particularly limited and can be set as appropriate in accordance with roughness of a surface to be processed.

In order to accurately process a thin film to have a desired thickness, a CMP method is employed, for example. In that case, first, polishing is performed at a constant processing rate until part of the top surface of the thin film is exposed. After that, polishing is performed under a condition with a lower processing rate until the thin film has a desired thickness, whereby highly accurate processing can be performed.

Examples of a method for detecting the end of the polishing include an optical method in which the surface to be processed is irradiated with light and a change in the reflected light is detected; a physical method in which a change in the polishing resistance received by the processing apparatus from the surface to be processed is detected; and a method in which a magnetic line is applied to the surface to be processed and a change in the magnetic line due to the generated eddy current is used.

After the top surface of the thin film is exposed, polishing treatment is performed under a condition with a low processing rate while the thickness of the thin film is monitored by an optical method using a laser interferometer or the like, whereby the thickness of the thin film can be controlled with high accuracy. Note that the polishing treatment may be performed a plurality of times until the thin film has a desired thickness, as necessary.

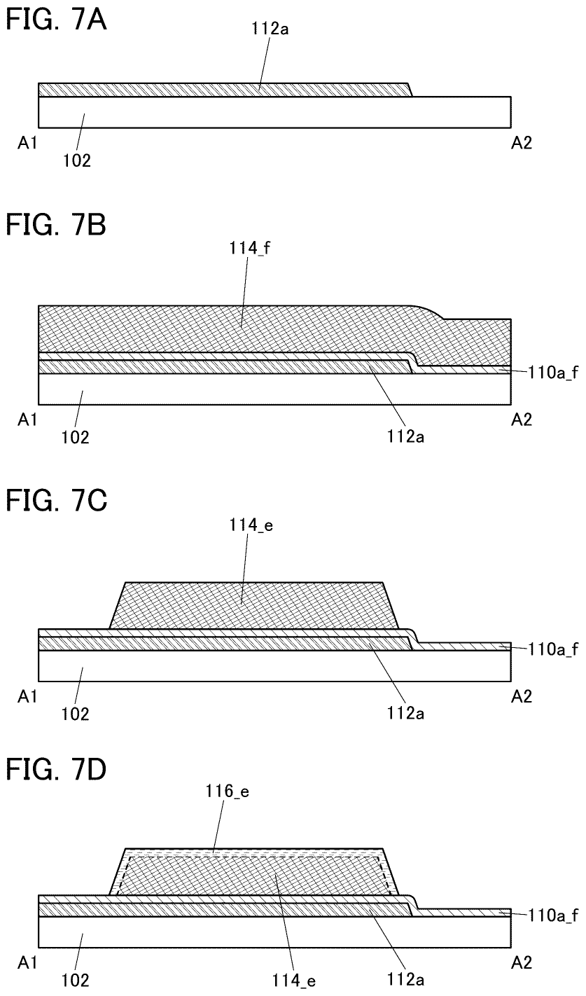

FIGS. 7A to 10C illustrate an example of a method for manufacturing the transistor 100. Each of the diagrams is a cross-sectional view along the dashed-dotted line A1-A2 in the plan view of FIG. 1A.

First, a conductive film to be the conductive layer 112a is formed over the substrate 102 and part of the conductive film is removed, whereby the conductive layer 112a is formed (FIG. 7A). The conductive film can be formed by a sputtering method, for example. The conductive film can be processed by one or both of a wet etching method and a dry etching method.

Then, an insulating film 110a_f is formed over the conductive layer 112a and the substrate 102.

For the insulating film 110a_f, any of the materials that can be used for the insulating layer 110a described above can be used as appropriate.

For the insulating film 110a_f, silicon nitride, silicon nitride oxide, aluminum oxide, hafnium oxide, or the like can be suitably used, for example.

Specifically, for the insulating film 110a_f, a silicon nitride film can be formed by a sputtering method, for example. As another example, a silicon nitride film can be formed by a PEALD method. As another example, an aluminum oxide film can be formed by a sputtering method.

As another example, a stack including aluminum oxide and silicon nitride can be used. For example, a stack of an aluminum oxide film formed by a sputtering method and a silicon nitride film formed by a PEALD method can be used.

Next, a conductive film 114_f is formed over the insulating film 110a_f (FIG. 7B).

For the conductive film 114_f, any of the materials that can be used for the conductive layer 114 described above can be used as appropriate. Note that the conductive film 114_f is preferably formed using a material that is easily oxidized because its surface is oxidized in a later step to form an insulating layer to be the insulating layer 116. For example, aluminum can be suitably used for the conductive layer 114.

The conductive film 114_f can be formed by a sputtering method, for example.

Then, the conductive film 114_f is processed to form a conductive layer 114_e (FIG. 7C). The conductive layer 114_e is formed to include a region overlapping with the conductive layer 112a.

Subsequently, plasma treatment is performed on the conductive layer 114_e in an oxygen-containing atmosphere to oxidize the surface of the conductive layer 114_e, whereby the insulating layer 116_e is formed on the top surface and a side surface of the conductive layer 114_e (FIG. 7D). For example, in the case where aluminum is used as the material of the conductive layer 114_e, the plasma treatment oxidizes the surface of the conductive layer 114_e, so that aluminum oxide is formed on the top surface and the side surface of the conductive layer 114_e and serves as the insulating layer 116_e.

Next, an insulating film 110b_f is formed over the insulating film 110a_f and the insulating layer 116_e, and an insulating film 110c_f is formed over the insulating film 110b_f.

For the insulating film 110b_f, any of the materials that can be used for the insulating layer 110b described above can be used as appropriate.

For the insulating film 110b_f, silicon oxide, silicon oxynitride, or the like can be suitably used, for example.

Specifically, for the insulating film 110b_f, a silicon oxide film can be formed by a sputtering method, for example. As another example, a silicon oxide film can be formed by a PECVD method. As another example, a silicon oxynitride film can be formed by a PECVD method.

As another example, a stack of a silicon oxide film formed by a sputtering method and a silicon oxide film or a silicon oxynitride film formed by a PECVD method can be used.

Heat treatment may be performed after the insulating film 110b_f is formed. By the heat treatment, water and hydrogen can be released from the surface and inside of the insulating film 110b_f.

The heat treatment temperature is preferably higher than or equal to 150° C. and lower than the strain point of the substrate, further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C., further preferably higher than or equal to 350° C. and lower than or equal to 400° C. The heat treatment can be performed in an atmosphere containing one or more of a noble gas, nitrogen, and oxygen.

As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the insulating film 110b_f can be prevented as much as possible. An oven or a rapid thermal annealing (RTA) apparatus can be used for the heat treatment, for example. With the RTA apparatus, the heat treatment time can be shortened.

After the heat treatment, a step of supplying oxygen to the insulating film 110b_f may be performed. For example, oxygen may be supplied to the insulating film 110b_f by forming a metal oxide layer over the insulating film 110b_f after the formation of the insulating film 110b_f. Heat treatment may be performed after the formation of the metal oxide layer. By the heat treatment performed after the formation of the metal oxide layer, oxygen can be effectively supplied from the metal oxide layer to the insulating film 110b_f, and oxygen can be contained in the insulating film 110b_f. Oxygen supplied to the insulating film 110b_f is supplied to the semiconductor layer 108 in a later step, whereby oxygen vacancies (V_{O}) and V_{O}H in the semiconductor layer 108 can be reduced.

After the formation of the metal oxide layer or the above-described heat treatment, oxygen may be further supplied to the insulating film 110b_f through the metal oxide layer. Oxygen can be supplied by, for example, an ion implantation method, an ion doping method, a plasma immersion ion implantation method, or plasma treatment. For the plasma treatment, an apparatus in which an oxygen gas is made to be plasma by high-frequency power can be suitably used. Examples of an apparatus in which gas is made to be plasma by high-frequency power include a plasma etching apparatus and a plasma ashing apparatus.

The metal oxide layer may be an insulating layer or a conductive layer. For the metal oxide layer, aluminum oxide, hafnium oxide, hafnium aluminate, indium oxide, indium tin oxide (ITO), or indium tin oxide containing silicon (ITSO) can be used, for example.

For the metal oxide layer, it is preferable to use an oxide material including one or more of the same elements as those of the semiconductor layer 108. It is particularly preferable to use an oxide semiconductor material that can be used for the semiconductor layer 108. In such a case, the metal oxide layer can be formed using the same sputtering target as the semiconductor layer 108; thus, the manufacturing cost can be reduced.

When a metal oxide material containing indium and gallium is used for the metal oxide layer, a material where the composition ratio (content) of gallium is higher than that in the semiconductor layer 108 can be used. With the use of a material having a high gallium composition ratio (content) for the metal oxide layer, an oxygen blocking property can be further increased. This can inhibit release of oxygen contained in the insulating film 110b_f to the outside, which is preferable.

The metal oxide layer is preferably formed in an oxygen-containing atmosphere, for example. In particular, the metal oxide layer is preferably formed by a sputtering method in an oxygen-containing atmosphere. Thus, oxygen can be favorably supplied to the insulating film 110b_f at the time of forming the metal oxide layer.

Next, the metal oxide layer is removed. For example, a wet etching method can be suitably used to remove the metal oxide layer.

The treatment for supplying oxygen to the insulating film 110b_f is not necessarily performed by the above-described method. For example, an oxygen radical, an oxygen atom, an oxygen atomic ion, an oxygen molecular ion, or the like is supplied to the insulating film 110b_f by an ion doping method, an ion implantation method, plasma treatment, or the like. Furthermore, a film that suppresses oxygen release may be formed over the insulating film 110b_f and then, oxygen may be supplied to the insulating film 110b_f through the film. After the supply of oxygen, the film that suppresses oxygen release is preferably removed. The film that suppresses oxygen release can be formed using a conductive film or a semiconductor film containing one or more of indium, zinc, gallium, tin, aluminum, chromium, tantalum, titanium, molybdenum, nickel, iron, cobalt, and tungsten.

For the insulating film 110c_f, any of the materials that can be used for the insulating layer 110c described above can be used as appropriate.

The description of the materials and the formation methods that can be used for the insulating film 110a_f can be referred to for the material and the formation method that can be used for the insulating film 110c_f.

Next, a conductive film 112b_f is formed over the insulating film 110c_f. For the conductive film 112b_f, any of the materials that can be used for the conductive layer 112b described above can be used as appropriate.

The conductive film 112b_f can be formed by a sputtering method, for example.

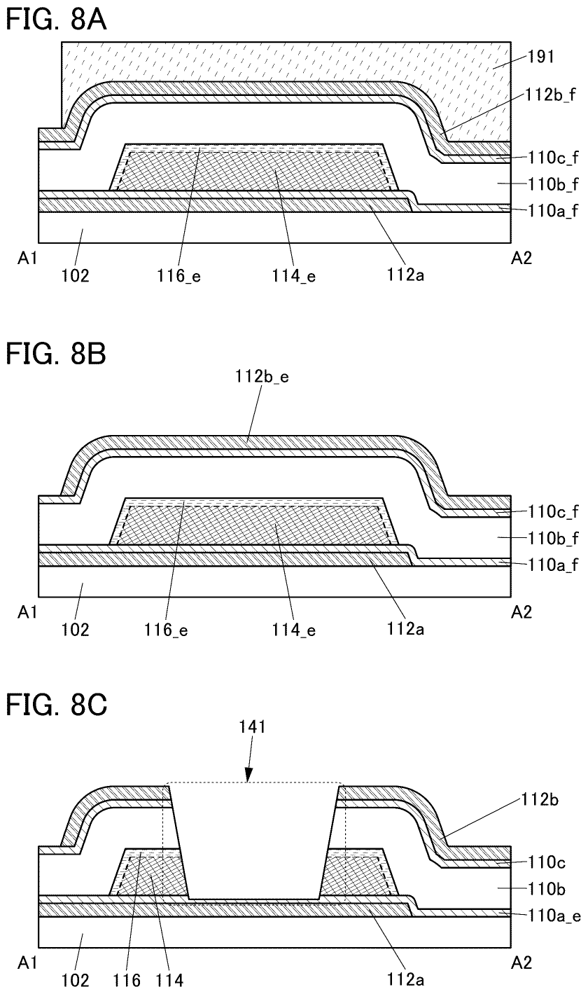

Subsequently, a resist mask 191 is formed over the conductive film 112b_f by a photolithography method (FIG. 8A).

Then, part of the conductive film 112b_f is removed with the use of the resist mask 191 as a mask, thereby forming a conductive layer 112b_e. After the conductive layer 112b_e is formed, the resist mask 191 is removed (FIG. 8B).

Next, the conductive layer 112b_e, the insulating film 110c_f, the insulating film 110b_f, the insulating layer 116_e, the conductive layer 114_e, and the insulating film 110a_f are partly removed, thereby forming an opening 141. A dry etching method can be suitably used for this processing, for example. By the processing, the conductive layer 112b, the insulating layer 110c, the insulating layer 110b, the insulating layer 116, and the conductive layer 114 that include an opening, and an insulating layer 110a_e including a recess portion are formed (FIG. 8C). The opening 141 can be regarded as being formed of the opening formed in the conductive layer 112b, the insulating layer 110c, the insulating layer 110b, the insulating layer 116, and the conductive layer 114 and the recess portion of the insulating layer 110a_e, which is formed in a region overlapping with the opening.

Although FIG. 8C illustrates an example in which part of the top surface of the insulating film 110a_f is removed by the formation of the opening 141 so that the insulating layer 110a_e including a recess portion is formed, one embodiment of the present invention is not limited thereto. The processing can be such that part of the top surface of the insulating film 110a_f is not removed at the time of forming the opening 141. In this case, the opening 141 can be regarded as being formed of the opening formed in the conductive layer 112b, the insulating layer 110c, the insulating layer 110b, the insulating layer 116, and the conductive layer 114.

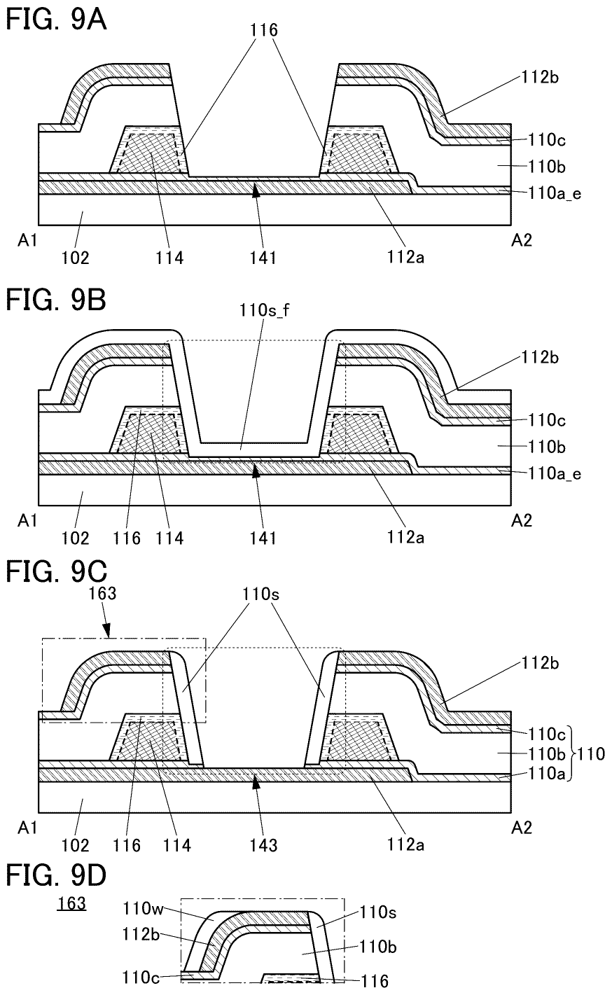

Then, plasma treatment is performed on a side surface of the conductive layer 114 exposed in the opening 141 in an oxygen-containing atmosphere to oxidize the side surface, whereby the insulating layer 116 is formed on the side surface (FIG. 9A). For example, in the case where aluminum is used as the material of the conductive layer 114, the exposed side surface of the conductive layer 114 is oxidized by the plasma treatment, so that aluminum oxide is formed on the side surface and serves as the insulating layer 116.

Subsequently, an insulating film 110s_f is formed in contact with the top surface of the conductive layer 112b, a side surface of the conductive layer 112b in the opening 141, a side surface of the insulating layer 110c in the opening 141, a side surface of the insulating layer 110b in the opening 141, a side surface of the insulating layer 116 in the opening 141, and a side surface and the top surface of the insulating layer 110a_e in the opening 141 (FIG. 9B).

For the insulating film 110s_f, any of the materials that can be used for the insulating layer 110s described above can be used as appropriate.

The insulating film 110s_f is preferably formed by a CVD method, an ALD method, or the like, in which case the insulating film 110s_f can favorably cover the side surfaces of the conductive layer 112b and the insulating layers 110c, 110b, 116, and 110a_e in the opening 141.

Next, processing of removing part of the insulating film 110s_f by etching is performed. Specifically, a region of the insulating film 110s_f that is in contact with the top surface of the conductive layer 112b and a region of the insulating film 110s_f that is in contact with the top surface of the insulating layer 110a_e in the opening 141 are removed. At this time, the insulating layer 110a_e overlapping with part of the top surface of the insulating film 110s_f in the opening 141 is also removed. Thus, the opening 143 reaching the conductive layer 112a is formed, and in addition, the insulating layer 110a including a portion protruding in the opening 143 and the insulating layer 110s in contact with the side surfaces of the conductive layer 112b and the insulating layers 110c, 110b, and 116 in the opening 143 and the top surface of the protruding portion of the insulating layer 110a in the opening 143 are formed (FIG. 9C). The opening 143 can be regarded as being formed of the opening 141 and an opening formed in the insulating layer 110a by the processing (an opening having a smaller diameter than the opening 141).

Etching of the insulating film 110s_f can be anisotropic etching, for example. Specifically, the insulating layer 110s can be formed by highly anisotropic dry etching, for example.

The insulating layer 110s includes a curved upper end portion. By changing the conditions of the anisotropic etching, the level of the upper end portion of the insulating layer 110s can be adjusted as illustrated in FIGS. 3A to 3D.

As illustrated in FIG. 9D, a sidewall insulating layer 110w is formed on the side surface of the conductive layer 112b outside the opening 143 in some cases depending on the manufacturing conditions of the insulating layer 110s. FIG. 9D corresponds to a region 163 surrounded by a dashed line in FIG. 9C. Such a sidewall insulating layer 110w can be formed not only on the side surface of the conductive layer 112b but also on a portion having unevenness on the formation surface of the insulating film 110s_f.

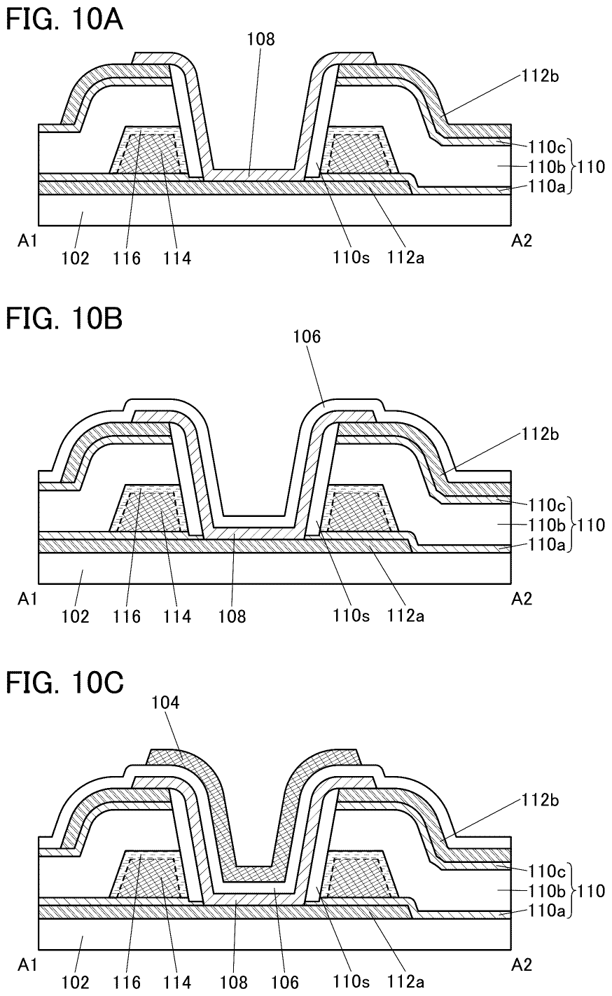

Then, a semiconductor film to be the semiconductor layer 108 is formed in contact with the top surface of the conductive layer 112a in the opening 143, the side surface of the insulating layer 110s in the opening 143, the curved portion of the insulating layer 110s, and the top surface of the conductive layer 112b. After that, part of the semiconductor film is removed by etching, whereby the semiconductor layer 108 is formed (FIG. 10A). The semiconductor layer 108 is provided to include a region overlapping with the opening 143. Moreover, the semiconductor layer 108 is provided such that its end portion includes a region in contact with the conductive layer 112b.

For the semiconductor film to be the semiconductor layer 108, any of the materials that can be used for the semiconductor layer 108 described above can be used as appropriate.

The semiconductor film to be the semiconductor layer 108 can be formed by a sputtering method, for example. For example, in the case where a metal oxide is used for the semiconductor layer 108, the semiconductor film can be formed by a sputtering method using a metal oxide target. The use of a sputtering method is preferable, in which case a film with a low hydrogen content can be formed relatively easily.

In the case where a metal oxide is used for the semiconductor layer 108, the semiconductor film can also be formed by an ALD method using an oxidizer and a precursor containing a constituent metal element.

For example, a film of In—Ga—Zn oxide can be formed using a precursor containing indium, a precursor containing gallium, and a precursor containing zinc. Alternatively, a precursor containing indium and a precursor containing gallium and zinc may be used.

As the precursor containing indium, it is possible to use triethylindium, tris(2,2,6,6-tetramethyl-3,5-heptanedionato)indium, cyclopentadienylindium, indium(III) chloride, or the like.

As the precursor containing gallium, it is possible to use trimethylgallium, triethylgallium, gallium trichloride, tris(dimethylamido)gallium(III), gallium(III) acetylacetonate, tris(2,2,6,6-tetramethyl-3,5-heptanedionato)gallium, dimethylchlorogallium, diethylchlorogallium, or the like.

As the precursor containing zinc, it is possible to use dimethylzinc, diethylzinc, bis(2,2,6,6-tetramethyl-3,5-heptanedionato)zinc, zinc chloride, or the like.

Ozone, oxygen, water, or the like can be used as the oxidizer.

As an example of a method for controlling the composition of a film to be formed, adjusting the flow rate ratio, flowing time, flowing order, or the like of the source gases is given. By adjusting such conditions, a film whose composition is gradually changed can be formed. Furthermore, films having different compositions can be formed successively.

The semiconductor film to be the semiconductor layer 108 is preferably formed by an ALD method, in which case the semiconductor layer 108 can be formed to have a uniform thickness on the side surface of the insulating layer 110s.

Heat treatment may be performed after the semiconductor film to be the semiconductor layer 108 is formed. The heat treatment can reduce water and hydrogen contained in the semiconductor film and allows oxygen to be supplied from the insulating layers 110 and 110s and the like to the semiconductor film. Note that the heat treatment may be performed after the semiconductor film is processed.

The substrate temperature at the time of forming the semiconductor layer 108 is preferably higher than or equal to room temperature (25° C.) and lower than or equal to 200° C., further preferably higher than or equal to room temperature and lower than or equal to 130° C. With the substrate temperature in the above range, the bending or warpage of the substrate can be suppressed in the case where the substrate is a large glass substrate.

The higher the substrate temperature (the stage temperature) in the formation of the metal oxide layer is, the higher the crystallinity of the metal oxide layer can be. Furthermore, the higher the oxygen flow rate ratio is, the higher the crystallinity of the metal oxide layer can be.

Then, the insulating layer 106 is formed to cover the semiconductor layer 108, the conductive layer 112b, and the insulating layer 110c (FIG. 10B). The insulating layer 106 includes a region in contact with the top surface and a side surface of the semiconductor layer 108, the top surface of the conductive layer 112b, and the top surface of the insulating layer 110c.

Any of the above-described materials can be used for the insulating layer 106 as appropriate.

The insulating layer 106 can be formed by an ALD method, for example. The use of an ALD method is preferable, in which case the insulating layer 106 can be formed to favorably cover the semiconductor layer 108, which is formed to cover the opening 143. Note that the insulating layer 106 may be formed by a method other than an ALD method as long as the insulating layer 106 can adequately cover the semiconductor layer 108. For example, a PECVD method, a sputtering method, or the like can be employed. In such a case, the deposition rate of the insulating layer 106 can be higher than that in the case of employing an ALD method, and thus the productivity can be increased.

Next, a conductive film to be the conductive layer 104 is formed over the insulating layer 106. For the conductive film, any of the materials that can be used for the conductive layer 104 described above can be used as appropriate. The conductive film can be formed by a sputtering method, a CVD method, an MBE method, a PLD method, an ALD method, or the like as appropriate. Here, the conductive film is preferably formed in contact with the insulating layer 106 that faces the side surface of the insulating layer 110s in the opening 143. Accordingly, the conductive film is preferably formed by a formation method achieving favorable coverage or embeddability, and is further preferably formed by a CVD method, an ALD method, or the like.

Subsequently, the conductive film to be the conductive layer 104 is processed, thereby forming the conductive layer 104 (FIG. 10C). The conductive layer 104 is formed to include a region overlapping with the semiconductor layer 108 and the insulating layer 110s in a plan view. The conductive layer 104 is formed by a photolithography method. The processing can be performed by a dry etching method or a wet etching method. A dry etching method is suitable for microfabrication.

Then, the insulating layer 195 is formed to cover the conductive layer 104 and the insulating layer 106 (FIG. 1B).

The insulating layer 195 can be formed using a material and a method that are similar to those for the insulating layers 110a and 110c, for example.

Through the above-described steps, a semiconductor device including the transistor 100 can be manufactured.

This embodiment can be combined with any of the other embodiments as appropriate. In this specification, in the case where a plurality of structure examples are described in one embodiment, the structure examples can be combined as appropriate.

### Embodiment 2

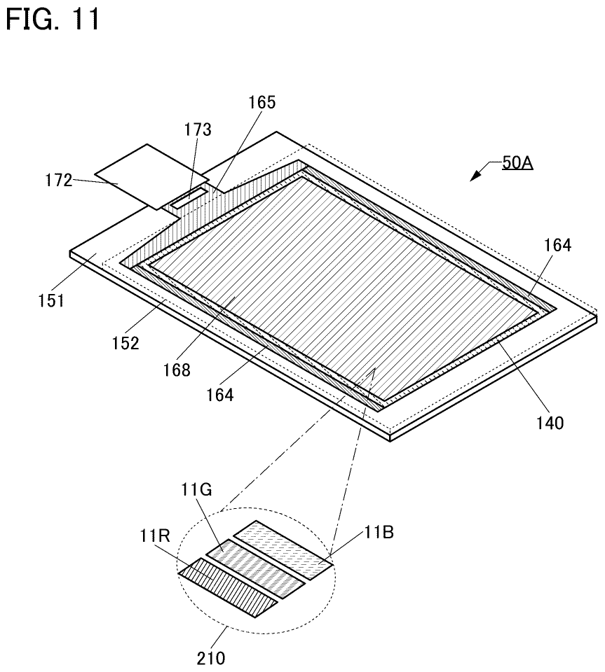

In this embodiment, a display device of one embodiment of the present invention will be described with reference to FIGS. 11 to 16.

The display device of this embodiment can be a high-definition display device or a large-sized display device. Accordingly, the display device of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, desktop and notebook personal computers, a monitor of a computer and the like, digital signage, and a large game machine such as a pachinko machine.

The display device of this embodiment can be a high-resolution display device. Accordingly, the display device of this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The semiconductor device of one embodiment of the present invention can be used for a display device or a module including the display device. Examples of the module including the display device include a module in which a connector such as a flexible printed circuit board (hereinafter referred to as an FPC) or a tape carrier package (TCP) is attached to the display device and a module that is mounted with an integrated circuit (IC) by a chip on glass (COG) method, a chip on film (COF) method, or the like.

### [Display Device 50A]

FIG. 11 is a perspective view of a display device 50A.

In the display device 50A, a substrate 152 and a substrate 151 are attached to each other. In FIG. 11, the substrate 152 is indicated by a dashed line.

The display device 50A includes a display portion 168, a connection portion 140, a circuit portion 164, a wiring 165, and the like. FIG. 11 illustrates an example where an IC 173 and an FPC 172 are implemented onto the display device 50A. Thus, the structure illustrated in FIG. 11 can be regarded as a display module including the display device 50A, the IC, and the FPC.

The connection portion 140 is provided outside the display portion 168. The connection portion 140 can be provided along one side or a plurality of sides of the display portion 168. The number of connection portions 140 may be one or more. FIG. 11 illustrates an example where the connection portion 140 is provided to surround the four sides of the display portion. In the connection portion 140, a common electrode of a display element is connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The wiring 165 has a function of supplying a signal and electric power to the display portion 168 and the circuit portion 164. The signal and power are input to the wiring 165 from the outside through the FPC 172 or from the IC 173.

FIG. 11 illustrates an example where the IC 173 is provided on the substrate 151 by a COG method, a COF method, or the like. An IC including one or both of a scan line driver circuit and a signal line driver circuit can be used as the IC 173, for example. Note that the display device 50A and the display module are not necessarily provided with an IC. The IC may be mounted on the FPC by a COF method or the like.

The transistor of one embodiment of the present invention can be used for one or both of the display portion 168 and the circuit portion 164 of the display device 50A, for example.

For example, when the transistor of one embodiment of the present invention is used for a pixel circuit of the display device, the area occupied by the pixel circuit can be reduced and the display device can have high resolution. As another example, when the transistor of one embodiment of the present invention is used for a driver circuit (e.g., one or both of a gate line driver circuit and a source line driver circuit) of the display device, the area occupied by the driver circuit can be reduced and the display device can have a narrow bezel. Since the transistor of one embodiment of the present invention has favorable electrical characteristics, a display device can have increased reliability by using the transistor.

The display portion 168 of the display device 50A is a region where an image is to be displayed, and includes a plurality of pixels 210 that are periodically arranged. FIG. 11 shows an enlarged view of one pixel 210.

There is no particular limitation on the pixel arrangement in the display device of one embodiment of the present invention, and a variety of arrangements can be employed. Examples of the pixel arrangement include stripe arrangement, S-stripe arrangement, matrix arrangement, delta arrangement, Bayer arrangement, and PenTile arrangement.

The pixel 210 illustrated in FIG. 11 includes a subpixel 11R that emits red light, a subpixel 11G that emits green light, and a subpixel 11B that emits blue light.

The subpixels 11R, 11G, and 11B each include a display element and a circuit for controlling the driving of the display element.

Any of a variety of elements can be used as the display element, and a liquid crystal element or a light-emitting element can be used, for example. Alternatively, a micro electro mechanical systems (MEMS) shutter element, an optical interference type MEMS element, or a display element using a microcapsule method, an electrophoretic method, an electrowetting method, an Electronic Liquid Powder (registered trademark) method, or the like can be used. Alternatively, a quantum-dot LED (QLED) employing a light source and color conversion technology using quantum dot materials may be used.

Examples of a display device that includes a liquid crystal element include a transmissive liquid crystal display device, a reflective liquid crystal display device, and a transflective liquid crystal display device.

As the light-emitting element, a self-luminous light-emitting element such as an LED, an organic LED (OLED), or a semiconductor laser can be used, for example. Examples of the LED include a mini LED and a micro LED.

Examples of a light-emitting substance contained in the light-emitting element include a substance that exhibits fluorescence (a fluorescent material), a substance that exhibits phosphorescence (a phosphorescent material), a substance that exhibits thermally activated delayed fluorescence (a thermally activated delayed fluorescent (TADF) material), and an inorganic compound (e.g., a quantum dot material).

The light-emitting element can emit infrared, red, green, blue, cyan, magenta, yellow, or white light, for example. When the light-emitting element has a microcavity structure, higher color purity can be achieved.

One of a pair of electrodes of the light-emitting element serves as an anode, and the other electrode serves as a cathode.

In this embodiment, the case where a light-emitting element is used as the display element is mainly described as an example.

The display device of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

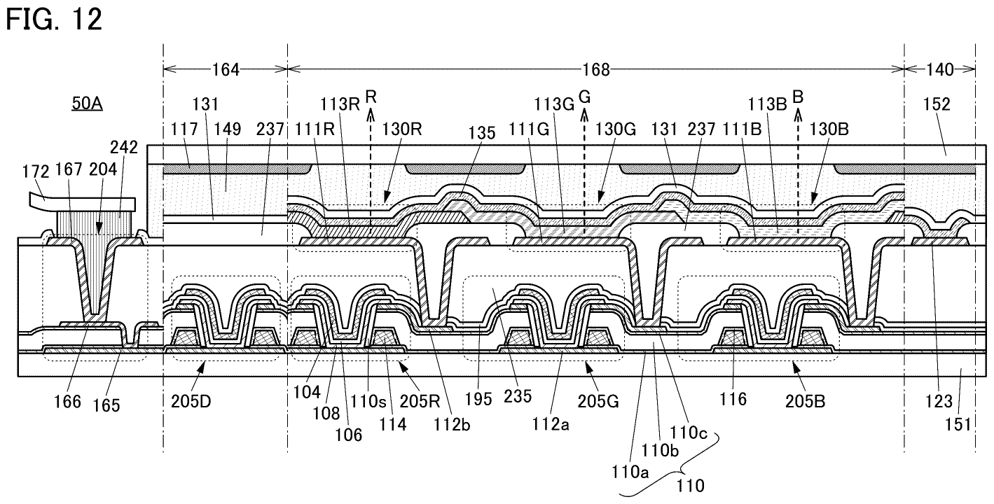

FIG. 12 illustrates an example of cross sections of part of a region including the FPC 172, part of the circuit portion 164, part of the display portion 168, part of the connection portion 140, and part of a region including an end portion of the display device 50A.

The display device 50A illustrated in FIG. 12 includes a transistor 205D, a transistor 205R, a transistor 205G, a transistor 205B, a light-emitting element 130R, a light-emitting element 130G, a light-emitting element 130B, and the like between the substrates 151 and 152. The light-emitting elements 130R, 130G, and 130B are display elements included in the subpixel 11R that emits red light, the subpixel 11G that emits green light, and the subpixel 11B that emits blue light, respectively.

The display device 50A employs an SBS structure. The SBS structure can optimize materials and structures of light-emitting elements and thus can extend freedom of choice of materials and structures, whereby the luminance and the reliability can be easily improved.

The display device 50A has a top-emission structure. The aperture ratio of pixels in a top-emission structure can be higher than that of pixels in a bottom-emission structure because a transistor and the like can be placed to overlap with a light-emitting region of a light-emitting element in the top-emission structure.

The transistors 205D, 205R, 205G, and 205B are formed over the substrate 151. These transistors can be manufactured using the same materials through the same process.

This embodiment describes an example where OS transistors are used as the transistors 205D, 205R, 205G, and 205B. The transistor of one embodiment of the present invention can be used as the transistors 205D, 205R, 205G, and 205B. In other words, the display device 50A includes the transistor of one embodiment of the present invention in both the display portion 168 and the circuit portion 164. When the display portion 168 includes the transistor of one embodiment of the present invention, the pixel size can be reduced and higher resolution can be achieved. When the circuit portion 164 includes the transistor of one embodiment of the present invention, the area occupied by the circuit portion 164 can be reduced and a narrower bezel can be achieved. The description in the above embodiment can be referred to for the transistor of one embodiment of the present invention.

Specifically, each of the transistors 205D, 205R, 205G, and 205B includes the conductive layer 104 functioning as one of a first gate electrode and a second gate electrode, the conductive layer 114 functioning as the other of the first gate electrode and the second gate electrode, the insulating layer 106 functioning as a gate insulating layer, the insulating layer 110s functioning as a gate insulating layer, the conductive layer 112a functioning as one of a source electrode and a drain electrode, the conductive layer 112b functioning as the other of the source electrode and the drain electrode, and the semiconductor layer 108 including a metal oxide.

Note that the transistor included in the display device of this embodiment is not limited to the transistor of one embodiment of the present invention. For example, the display device of this embodiment may include the transistor of one embodiment of the present invention and a transistor having another structure in combination.

The display device of this embodiment may include one or more of a planar transistor, a staggered transistor, and an inverted staggered transistor. A transistor included in the display device of this embodiment may have a top-gate structure or a bottom-gate structure. Alternatively, gates may be provided above and below a semiconductor layer where a channel is formed.

The display device of this embodiment may include a transistor using silicon in its channel formation region (a Si transistor).

Examples of silicon include single crystal silicon, polycrystalline silicon, and amorphous silicon. In particular, a transistor including LTPS in a semiconductor layer (hereinafter also referred to as an LTPS transistor) can be used. The LTPS transistor has high field-effect mobility and excellent frequency characteristics.

To increase the luminance of the light-emitting element included in the pixel circuit, it is necessary to increase the amount of current flowing through the light-emitting element. To increase the current amount, the source-drain voltage of a driving transistor included in the pixel circuit needs to be increased. An OS transistor has higher withstand voltage between a source and a drain than a Si transistor; hence, high voltage can be applied between the source and the drain of the OS transistor. Thus, with the use of an OS transistor as the driving transistor included in the pixel circuit, the amount of current flowing through the light-emitting element can be increased, resulting in an increase in luminance of the light-emitting element.

When transistors operate in a saturation region, a change in source-drain current relative to a change in gate-source voltage can be smaller in an OS transistor than in a Si transistor. Accordingly, when an OS transistor is used as the driving transistor included in the pixel circuit, a current flowing between the source and the drain can be set minutely by a change in gate-source voltage; hence, the amount of current flowing through the light-emitting element can be controlled. Consequently, the number of gray levels expressed by the pixel circuit can be increased.

Regarding saturation characteristics of current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can flow through light-emitting elements even when the current-voltage characteristics of the light-emitting elements vary, for example. In other words, when the OS transistor operates in the saturation region, the source-drain current hardly changes with a change in the source-drain voltage; hence, the luminance of the light-emitting element can be stable.

The transistor included in the circuit portion 164 and the transistor included in the display portion 168 may have the same structure or different structures. One structure or two or more kinds of structures may be employed for a plurality of transistors included in the circuit portion 164. Similarly, one structure or two or more kinds of structures may be employed for a plurality of transistors included in the display portion 168.

All of the transistors included in the display portion 168 may be OS transistors or Si transistors. Alternatively, some of the transistors included in the display portion 168 may be OS transistors and the others may be Si transistors.

For example, when both an LTPS transistor and an OS transistor are used in the display portion 168, the display device can have low power consumption and high driving capability. Note that a structure in which an LTPS transistor and an OS transistor are used in combination is referred to as LTPO in some cases. A favorable structure example is such that an OS transistor is used, for example, as a transistor functioning as a switch for controlling electrical continuity and discontinuity between wirings and an LTPS transistor is used, for example, as a transistor for controlling current.

For example, one transistor included in the display portion 168 functions as a transistor for controlling a current flowing through the light-emitting element and can also be referred to as a driving transistor. One of a source and a drain of the driving transistor is connected to the pixel electrode of the light-emitting element. An LTPS transistor is preferably used as the driving transistor. In that case, the amount of current flowing through the light-emitting element can be increased in the pixel circuit.

By contrast, another transistor included in the display portion 168 functions as a switch for controlling selection or non-selection of a pixel and can also be referred to as a selection transistor. A gate of the selection transistor is connected to a gate line, and one of a source and a drain thereof is connected to a source line (signal line). An OS transistor is preferably used as the selection transistor. In that case, the gray level of the pixel can be maintained even with an extremely low frame frequency (e.g., 1 fps or lower); thus, power consumption can be reduced by stopping the driver in displaying a still image.

The insulating layer 195 is provided to cover the transistors 205D, 205R, 205G, and 205B. An insulating layer 235 is provided over the insulating layer 195.

The insulating layer 195 preferably functions as a protective layer for the transistors. The insulating layer 195 is preferably formed using a material through which impurities such as water and hydrogen are less likely to be diffused, in which case the insulating layer 195 can function as a barrier layer. Such a structure can effectively inhibit diffusion of impurities into the transistors from the outside and increase the reliability of the display device.

The insulating layer 195 preferably includes one or more inorganic insulating films. Examples of the inorganic insulating film include an oxide insulating film, a nitride insulating film, an oxynitride insulating film, and a nitride oxide insulating film. Specific examples of these inorganic insulating films are as described above.

The insulating layer 235 preferably has a function of a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably has a function of an etching protective layer. In that case, the formation of a recess portion in the insulating layer 235 can be inhibited in processing pixel electrodes 111R, 111G, and 111B, for example. Alternatively, a recess portion may be formed in the insulating layer 235 in processing the pixel electrodes 111R, 111G, and 111B, for example.

The light-emitting elements 130R, 130G, and 130B are provided over the insulating layer 235.

The light-emitting element 130R includes the pixel electrode 111R over the insulating layer 235, an EL layer 113R over the pixel electrode 111R, and a common electrode 135 over the EL layer 113R. The light-emitting element 130R illustrated in FIG. 12 emits red light (R). The EL layer 113R includes a light-emitting layer that emits red light.

The light-emitting element 130G includes the pixel electrode 111G over the insulating layer 235, an EL layer 113G over the pixel electrode 111G, and the common electrode 135 over the EL layer 113G. The light-emitting element 130G illustrated in FIG. 12 emits green light (G). The EL layer 113G includes a light-emitting layer that emits green light.

The light-emitting element 130B includes the pixel electrode 111B over the insulating layer 235, an EL layer 113B over the pixel electrode 111B, and the common electrode 135 over the EL layer 113B. The light-emitting element 130B illustrated in FIG. 12 emits blue light (B). The EL layer 113B includes a light-emitting layer that emits blue light.

Although the EL layers 113R, 113G, and 113B have the same thickness in FIG. 12, one embodiment of the present invention is not limited thereto. The EL layers 113R, 113G, and 113B may have different thicknesses. For example, the thicknesses of the EL layers 113R, 113G, and 113B are preferably set to match an optical path length that intensifies light emitted from each EL layer. Thus, a microcavity structure is achieved, and the color purity of light emitted from each light-emitting element can be improved.

The pixel electrode 111R is connected to the conductive layer 112b included in the transistor 205R through an opening provided in the insulating layers 106, 195, and 235. In a similar manner, the pixel electrode 111G is connected to the conductive layer 112b included in the transistor 205G, and the pixel electrode 111B is connected to the conductive layer 112b included in the transistor 205B.

End portions of the pixel electrodes 111R, 111G, and 111B are covered with an insulating layer 237. The insulating layer 237 functions as a partition (also referred to as a bank or a spacer). The insulating layer 237 can have a single-layer structure or a stacked-layer structure including one or both of an inorganic insulating material and an organic insulating material. For the insulating layer 237, a material that can be used for the insulating layer 195 and a material that can be used for the insulating layer 235 can be used, for example. The insulating layer 237 can insulate the pixel electrode from the common electrode. Furthermore, the insulating layer 237 can insulate adjacent light-emitting elements from each other.

The common electrode 135 is one continuous film shared by the light-emitting elements 130R, 130G, and 130B. The common electrode 135 shared by the plurality of light-emitting elements is connected to a conductive layer 123 provided in the connection portion 140. As the conductive layer 123, a conductive layer formed using the same material and the same step as the pixel electrodes 111R, 111G, and 111B is preferably used.

In the display device of one embodiment of the present invention, a conductive film that transmits visible light is used for the electrode through which light is extracted, which is either the pixel electrode or the common electrode. A conductive film reflecting visible light is preferably used for the electrode through which light is not extracted.

A conductive film that transmits visible light may be used also for the electrode through which light is not extracted. In that case, this electrode is preferably provided between a reflective layer and the EL layer. In other words, light emitted by the EL layer may be reflected by the reflective layer to be extracted from the display device.

As the material of the pair of electrodes of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (In—Sn oxide, also referred to as ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (Ag—Pd—Cu, also referred to as APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting element preferably employs a microcavity structure. Therefore, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

A transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The EL layers 113R, 113G, and 113B are each provided to have an island shape. In FIG. 12, end portions of the adjacent EL layers 113R and 113G overlap with each other, end portions of the adjacent EL layers 113G and 113B overlap with each other, and end portions of the adjacent EL layers 113R and 113B overlap with each other. When island-shaped EL layers are formed using a fine metal mask, end portions of adjacent EL layers may overlap with each other as illustrated in FIG. 12; however, the present invention is not limited thereto. That is, adjacent EL layers may be apart from each other without overlap. Moreover, the display device may include both a portion where adjacent EL layers overlap with each other and a portion where adjacent EL layers are apart from each other without overlap.

Each of the EL layers 113R, 113G, and 113B includes at least a light-emitting layer. The light-emitting layer can include one or more kinds of light-emitting substances. As the light-emitting substance, a substance whose emission color is blue, violet, bluish violet, green, yellowish green, yellow, orange, red, or the like is appropriately used. As the light-emitting substance, a substance that emits near-infrared light can also be used.

Examples of the light-emitting substance include a fluorescent material, a phosphorescent material, a TADF material, and a quantum dot material.

The light-emitting layer may include one or more kinds of organic compounds (e.g., a host material and an assist material) in addition to the light-emitting substance (guest material). As the one or more kinds of organic compounds, one or both of a substance having a high hole-transport property (a hole-transport material) and a substance having a high electron-transport property (an electron-transport material) can be used. As the one or more kinds of organic compounds, a substance with a bipolar property (a substance with a high electron-transport property and a high hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer including a substance having a high hole-injection property (a hole-injection layer), a layer including a hole-transport material (a hole-transport layer), a layer including a substance having a high electron-blocking property (an electron-blocking layer), a layer including a substance having a high electron-injection property (an electron-injection layer), a layer including an electron-transport material (an electron-transport layer), and a layer including a substance having a high hole-blocking property (a hole-blocking layer). The EL layer may further include one or both of a bipolar material and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In the tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. The tandem structure enables a light-emitting element capable of high-luminance light emission. Furthermore, the tandem structure allows the amount of current needed for obtaining the same luminance to be reduced as compared to the case of using a single structure, and thus can improve the reliability. The tandem structure may be referred to as a stack structure.

In the case of using a tandem light-emitting element in FIG. 12, the EL layer 113R preferably includes a plurality of light-emitting units that emit red light, the EL layer 113G preferably includes a plurality of light-emitting units that emit green light, and the EL layer 113B preferably includes a plurality of light-emitting units that emit blue light.

A protective layer 131 is provided over the light-emitting elements 130R, 130G, and 130B. The protective layer 131 and the substrate 152 are bonded to each other with an adhesive layer 149. The substrate 152 is provided with a light-blocking layer 117. A solid sealing structure or a hollow sealing structure, for example, can be employed to seal the light-emitting elements. In FIG. 12, a solid sealing structure is employed, in which a space between the substrate 152 and the substrate 151 is filled with the adhesive layer 149. Alternatively, a hollow sealing structure may be employed, in which the space is filled with an inert gas (e.g., nitrogen or argon). In that case, the adhesive layer 149 may be provided not to overlap with the light-emitting elements. Alternatively, the space may be filled with a resin other than the frame-like adhesive layer 149.

The protective layer 131 is provided at least in the display portion 168, and preferably provided to cover the entire display portion 168. The protective layer 131 is preferably provided to cover not only the display portion 168 but also the connection portion 140 and the circuit portion 164. The protective layer 131 is further preferably provided to extend to the end portion of the display device 50A. Meanwhile, a connection portion 204 includes a portion not provided with the protective layer 131 so that the FPC 172 and a conductive layer 167 are connected to each other.

By providing the protective layer 131 over the light-emitting elements 130R, 130G, and 130B, the reliability of the light-emitting elements can be increased.

The protective layer 131 may have a single-layer structure or a stacked-layer structure of two or more layers. There is no limitation on the conductivity of the protective layer 131. For the protective layer 131, at least one of an insulating film, a semiconductor film, and a conductive film can be used.

The protective layer 131 including an inorganic film can inhibit degradation of the light-emitting elements by preventing oxidation of the common electrode 135 and inhibiting entry of impurities that induces degradation (e.g., water and oxygen) into the light-emitting elements, for example; thus, the reliability of the display device can be improved.

For the protective layer 131, an inorganic insulating film such as an oxide insulating film, a nitride insulating film, an oxynitride insulating film, or a nitride oxide insulating film can be used, for example. Specific examples of these inorganic insulating films are as described above. In particular, the protective layer 131 preferably includes a nitride insulating film or a nitride oxide insulating film, and further preferably includes a nitride insulating film.

An inorganic film including ITO, In—Zn oxide, Ga—Zn oxide, Al—Zn oxide, IGZO, or the like can be used for the protective layer 131. The inorganic film preferably has high resistance, specifically, higher resistance than the common electrode 135. The inorganic film may further contain nitrogen.

When light emitted from the light-emitting element is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can be, for example, a stack of an aluminum oxide film and a silicon nitride film over the aluminum oxide film, or a stack of an aluminum oxide film and an IGZO film over the aluminum oxide film. Such a stacked-layer structure can inhibit entry of impurities that might induce degradation of the light-emitting element (e.g., water and oxygen) into the EL layer.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 204 is provided in a region of the substrate 151 not overlapping with the substrate 152. In the connection portion 204, the wiring 165 is connected to the FPC 172 through a conductive layer 166, the conductive layer 167, and a connection layer 242. In this example, the wiring 165 is a single-layer conductive layer obtained by processing the same conductive film as the conductive layer 112a. In this example, the conductive layer 166 is a single-layer conductive layer obtained by processing the same conductive film as the conductive layer 112b. In this example, the conductive layer 167 is a single-layer conductive layer obtained by processing the same conductive film as the pixel electrodes 111R, 111G, and 111B. On the top surface of the connection portion 204, the conductive layer 167 is exposed. Thus, the connection portion 204 and the FPC 172 can be connected to each other through the connection layer 242.

The display device 50A has a top-emission structure. Light from the light-emitting element is emitted toward the substrate 152. For the substrate 152, a material having a high visible-light-transmitting property is preferably used. The pixel electrodes 111R, 111G, and 111B include a material that reflects visible light, and the counter electrode (the common electrode 135) include a material that transmits visible light.

The light-blocking layer 117 is preferably provided on the surface of the substrate 152 on the substrate 151 side. The light-blocking layer 117 can be provided over a region between adjacent light-emitting elements, in the connection portion 140, in the circuit portion 164, and the like.

A coloring layer such as a color filter may be provided on the surface of the substrate 152 on the substrate 151 side or over the protective layer 131. By providing the color filter so as to overlap with the light-emitting element, the color purity of light emitted from a pixel can be increased.

A variety of optical members can be provided on the outside of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 152. For example, a glass layer or a silica layer (SiOₓ layer) is preferably provided as the surface protective layer, in which case surface contamination or damage can be prevented. The surface protective layer may be formed using diamond-like carbon (DLC), aluminum oxide (AlOₓ), a polyester-based material, a polycarbonate-based material, or the like. The surface protective layer is preferably formed using a material having a high visible-light-transmitting property. The surface protective layer is preferably formed using a material with high hardness.

For each of the substrates 151 and 152, glass, quartz, ceramic, sapphire, a resin, a metal, an alloy, a semiconductor, or the like can be used. The substrate on the side from which light from the light-emitting element is extracted is formed using a material that transmits the light. When a flexible material is used for the substrates 151 and 152, the display device can have increased flexibility and a flexible display can be obtained. Furthermore, a polarizing plate may be used as at least one of the substrates 151 and 152.

For each of the substrates 151 and 152, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as at least one of the substrates 151 and 152.

In the case where a circularly polarizing plate overlaps with the display device, a highly optically isotropic substrate is preferably used as the substrate included in the display device. A highly optically isotropic substrate has a low birefringence (i.e., a small amount of birefringence). Examples of a highly optically isotropic film include a triacetyl cellulose (TAC, also referred to as cellulose triacetate) film, a cycloolefin polymer (COP) film, a cycloolefin copolymer (COC) film, and an acrylic film.

For the adhesive layer 149, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene-vinyl acetate (EVA) resin. In particular, a material with low moisture permeability, such as an epoxy resin, is preferable. A two-component-mixture-type resin may be used. An adhesive sheet or the like may be used.

For the connection layer 242, an anisotropic conductive film (ACF), an anisotropic conductive paste (ACP), or the like can be used.

### [Display Device 50B]

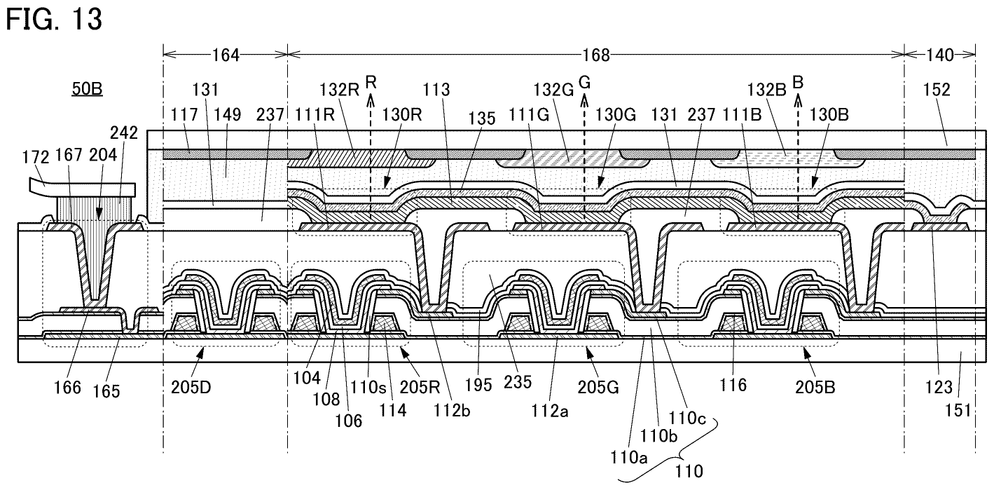

A display device 50B illustrated in FIG. 13 is different from the display device 50A mainly in that the subpixels of different colors include respective coloring layers (color filters or the like) and an EL layer 113 shared by the light-emitting elements. Note that in the following description of display devices, the description of portions similar to those of the above-described display devices may be omitted.

In the display device 50B illustrated in FIG. 13, the transistors 205D, 205R, 205G, and 205B, the light-emitting elements 130R, 130G, and 130B, a coloring layer 132R that transmits red light, a coloring layer 132G that transmits green light, a coloring layer 132B that transmits blue light, and the like are provided between the substrates 151 and 152.

The light-emitting element 130R includes the pixel electrode 111R, the EL layer 113 over the pixel electrode 111R, and the common electrode 135 over the EL layer 113. Light emitted from the light-emitting element 130R is extracted as red light to the outside of the display device 50B through the coloring layer 132R.

The light-emitting element 130G includes the pixel electrode 111G, the EL layer 113 over the pixel electrode 111G, and the common electrode 135 over the EL layer 113. Light emitted from the light-emitting element 130G is extracted as green light to the outside of the display device 50B through the coloring layer 132G.

The light-emitting element 130B includes the pixel electrode 111B, the EL layer 113 over the pixel electrode 111B, and the common electrode 135 over the EL layer 113. Light emitted from the light-emitting element 130B is extracted as blue light to the outside of the display device 50B through the coloring layer 132B.

The EL layer 113 and the common electrode 135 are shared between the light-emitting elements 130R, 130G, and 130B. The number of manufacturing steps can be smaller in the case where the EL layer 113 is shared between the subpixels of different colors than the case where the subpixels of different colors include different EL layers.

The light-emitting elements 130R, 130G, and 130B illustrated in FIG. 13 emit white light, for example. When white light emitted from the light-emitting elements 130R, 130G, and 130B passes through the coloring layers 132R, 132G, and 132B, light of desired colors can be obtained.

The light-emitting element that emits white light preferably includes two or more light-emitting layers. When two light-emitting layers are used to obtain white light, two light-emitting layers that emit light of complementary colors are selected. For example, when the emission colors of the first light-emitting layer and the second light-emitting layer are complementary colors, the light-emitting element can be configured to emit white light as a whole. When three or more light-emitting layers are used to obtain white light, the light-emitting element is configured to emit white light as a whole by combining the emission colors of the three or more light-emitting layers.

The EL layer 113 preferably includes, for example, a light-emitting layer including a light-emitting substance that emits blue light and a light-emitting layer including a light-emitting substance that emits visible light having a longer wavelength than blue light. For example, the EL layer 113 preferably includes a light-emitting layer that emits yellow light and a light-emitting layer that emits blue light. As another example, the EL layer 113 preferably includes a light-emitting layer that emits red light, a light-emitting layer that emits green light, and a light-emitting layer that emits blue light.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red and green light and a light-emitting unit that emits blue light; a three-unit tandem structure including a light-emitting unit that emits blue light, a light-emitting unit that emits yellow, yellow-green, or green light, and a light-emitting unit that emits blue light in this order; and a three-unit tandem structure including a light-emitting unit that emits blue light, a light-emitting unit that emits yellow, yellow-green, or green light and red light, and a light-emitting unit that emits blue light in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

As another example, the light-emitting elements 130R, 130G, and 130B illustrated in FIG. 13 emit blue light. In this case, the EL layer 113 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or 130G and the substrate 152 so that blue light emitted from the light-emitting element 130R or 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted through the color conversion layer without being converted. When light passing through the color conversion layer is extracted through the coloring layer, light other than light of a desired color can be absorbed by the coloring layer, and color purity of light emitted from a subpixel can be improved.

### [Display Device 50C]

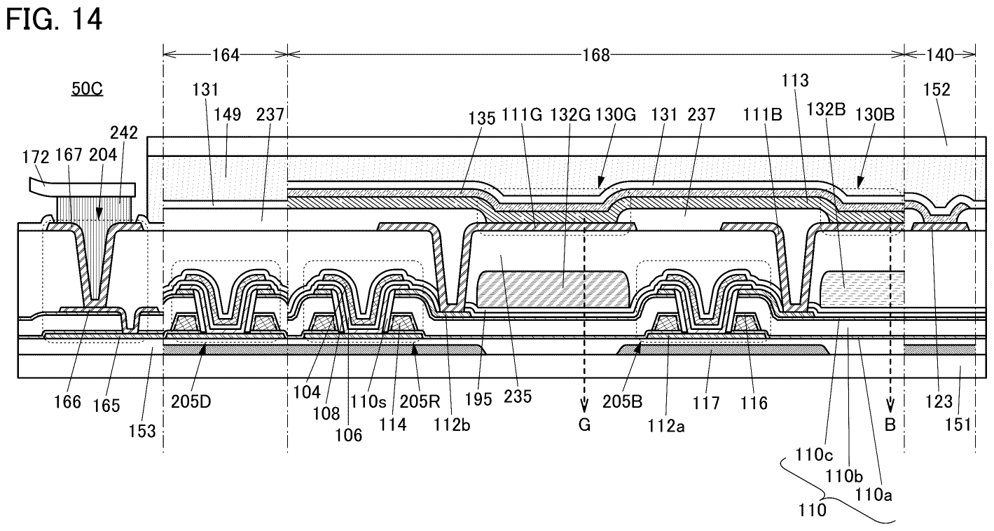

A display device 50C illustrated in FIG. 14 is different from the display device 50B mainly in having a bottom-emission structure.

Light from the light-emitting element is emitted toward the substrate 151. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 14 illustrates an example where the light-blocking layers 117 are provided over the substrate 151, an insulating layer 153 is provided over the light-blocking layers 117, and the transistors 205D, 205R (not illustrated), 205G, and 205B and the like are provided over the insulating layer 153. The coloring layers 132R (not illustrated), 132G, and 132B are provided over the insulating layer 195, and the insulating layer 235 is provided over the coloring layers 132R (not illustrated), 132G, and 132B.

The light-emitting element 130G overlapping with the coloring layer 132G includes the pixel electrode 111G, the EL layer 113, and the common electrode 135.

The light-emitting element 130B overlapping with the coloring layer 132B includes the pixel electrode 111B, the EL layer 113, and the common electrode 135.

A material having a high visible-light-transmitting property is used for each of the pixel electrodes 111G and 111B. A material that reflects visible light is preferably used for the common electrode 135. In the display device having a bottom-emission structure, a metal or the like having low resistance can be used for the common electrode 135; thus, a voltage drop due to the resistance of the common electrode 135 can be suppressed and the display quality can be improved.

The transistor of one embodiment of the present invention can be miniaturized and the area occupied by the transistor can be reduced, so that the aperture ratio of the pixel can be increased or the pixel size can be reduced in the display device having a bottom-emission structure.

### [Display Device 50D]

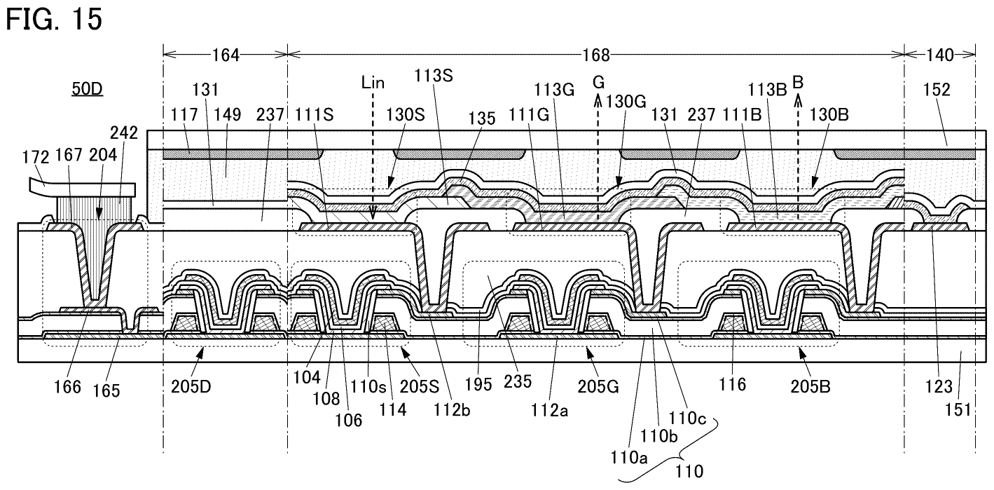

A display device 50D illustrated in FIG. 15 is different from the display device 50A mainly in including a light-receiving element 130S.

The display device 50D includes light-emitting elements and a light-receiving element in a pixel. In the display device 50D, organic EL elements are preferably used as the light-emitting elements and an organic photodiode is preferably used as the light-receiving element. The organic EL elements and the organic photodiodes can be formed over the same substrate. Thus, the organic photodiodes can be incorporated in a display device including the organic EL elements.

The display device 50D can detect the touch or approach of an object while displaying an image because the pixel includes the light-emitting element and the light-receiving element and thus has a light-receiving function. Accordingly, the display portion 168 has one or both of an image capturing function and a sensing function in addition to a function of displaying an image. For example, an image can be displayed by using all the subpixels included in the display device 50D; or light can be emitted by some of the subpixels as a light source, light can be detected by some other subpixels, and an image can be displayed by using the remaining subpixels.

Accordingly, a light-receiving portion and a light source do not need to be provided separately from the display device 50D; hence, the number of components of an electronic device can be reduced. For example, a biometric authentication device provided in an electronic device, a capacitive touch panel for scroll operation, or the like is not necessarily provided separately. Thus, with the use of the display device 50D, the electronic device can be provided at lower manufacturing costs.

When the light-receiving elements are used for an image sensor, the display device 50D can capture an image using the light-receiving elements. For example, image capturing for personal authentication with the use of a fingerprint, a palm print, the iris, the shape of a blood vessel (including the shape of a vein and the shape of an artery), a face, or the like is possible by using the image sensor.

Moreover, the light-receiving elements can be used in a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display device and the object come in direct contact with each other. The contactless sensor can detect the object even when the object is not in contact with the display device.

The light-receiving element 130S includes a pixel electrode 111S over the insulating layer 235, a functional layer 113S over the pixel electrode 111S, and the common electrode 135 over the functional layer 113S. The functional layer 113S is irradiated with light Lin coming from the outside of the display device 50D.

The pixel electrode 111S is connected to the conductive layer 112b included in a transistor 205S through an opening provided in the insulating layers 106, 195, and 235.

An end portion of the pixel electrode 111S is covered with the insulating layer 237.

The common electrode 135 is one continuous film shared by the light-receiving element 130S and the light-emitting elements 130R (not illustrated), 130G, and 130B. The common electrode 135 shared by the light-emitting elements and the light-receiving element is connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment shows an example where an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

In addition to the active layer, the functional layer 113S may further include a layer including a substance having a high hole-transport property, a substance having a high electron-transport property, a substance having a bipolar property (a substance having a high electron- and hole-transport property), or the like. Without limitation to the above, the functional layer may further include a layer including any of a substance having a high hole-injection property, a hole-blocking material, a substance having a high electron-injection property, an electron-blocking material, and the like. Layers other than the active layer in the light-receiving element can be formed using a material that can be used for the light-emitting element, for example.

Either a low molecular compound or a high molecular compound can be used in the light-receiving element, and an inorganic compound may also be included. Each layer included in the light-receiving element can be formed by any of the following methods: an evaporation method (including a vacuum evaporation method), a transfer method, a printing method, an inkjet method, a coating method, and the like.

### [Display Device 50E]

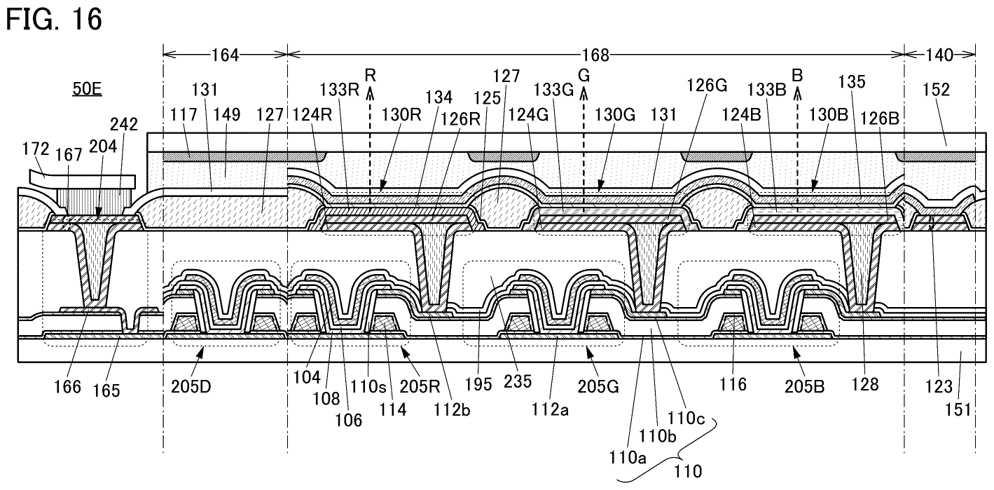

A display device 50E illustrated in FIG. 16 is an example of a display device having a metal maskless (MML) structure. In other words, the display device 50E includes a light-emitting element that is formed without using a fine metal mask. The stacked-layer structure from the substrate 151 to the insulating layer 235 and the stacked-layer structure from the protective layer 131 to the substrate 152 are similar to those in the display device 50A; therefore, the description thereof is omitted.

In FIG. 16, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 134 over the layer 133R, and the common electrode 135 over the common layer 134. The light-emitting element 130R illustrated in FIG. 16 emits red light (R). The layer 133R includes a light-emitting layer that emits red light. In the light-emitting element 130R, the layer 133R and the common layer 134 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 134 over the layer 133G, and the common electrode 135 over the common layer 134. The light-emitting element 130G illustrated in FIG. 16 emits green light (G). The layer 133G includes a light-emitting layer that emits green light. In the light-emitting element 130G, the layer 133G and the common layer 134 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 134 over the layer 133B, and the common electrode 135 over the common layer 134. The light-emitting element 130B illustrated in FIG. 16 emits blue light (B). The layer 133B includes a light-emitting layer that emits blue light. In the light-emitting element 130B, the layer 133B and the common layer 134 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the plurality of light-emitting elements is referred to as the common layer 134. Note that in this specification and the like, only the layers 133R, 133G, and 133B are sometimes referred to as island-shaped EL layers, EL layers formed in an island shape, or the like, in which case the common layer 134 is not included in the EL layer.

The layers 133R, 133G, and 133B are apart from each other. When the EL layer is provided in an island shape for each light-emitting element, leakage current between adjacent light-emitting elements can be inhibited. This can prevent crosstalk-induced unintended light emission, so that a display device with extremely high contrast can be obtained.

Although the layers 133R, 133G, and 133B have the same thickness in FIG. 16, the structure is not limited thereto. The layers 133R, 133G, and 133B may have different thicknesses.

The conductive layer 124R is connected to the conductive layer 112b included in the transistor 205R through an opening provided in the insulating layers 106, 195, and 235. In a similar manner, the conductive layer 124G is connected to the conductive layer 112b included in the transistor 205G, and the conductive layer 124B is connected to the conductive layer 112b included in the transistor 205B.

The conductive layers 124R, 124G, and 124B are formed to cover the openings provided in the insulating layer 235. A layer 128 is embedded in concave portions defined by the conductive layers 124R, 124G, and 124B.

The layer 128 has a function of filling the concave portions defined by the conductive layers 124R, 124G, and 124B. Over the conductive layers 124R, 124G, and 124B and the layer 128, the conductive layers 126R, 126G, and 126B that are respectively connected to the conductive layers 124R, 124G, and 124B are provided. Thus, regions overlapping with the concave portions defined by the conductive layers 124R, 124G, and 124B can also be used as the light-emitting regions, increasing the aperture ratio of the pixels. The conductive layer 124R and the conductive layer 126R each preferably include a conductive layer functioning as a reflective electrode.

The layer 128 may be an insulating layer or a conductive layer. Any of a variety of inorganic insulating materials, organic insulating materials, and conductive materials can be used as appropriate for the layer 128. Specifically, the layer 128 is preferably formed using an insulating material and is particularly preferably formed using an organic insulating material. For the layer 128, an organic insulating material that can be used for the insulating layer 237 can be used, for example.

Although the top surface of the layer 128 includes a flat portion in the example illustrated in FIG. 16, the shape of the layer 128 is not particularly limited. The top surface of the layer 128 can include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover a side surface of the end portion of the conductive layer 124R. The end portions of the conductive layers 124R and 126R each preferably have a tapered shape. Specifically, the end portions of the conductive layers 124R and 126R each preferably have a tapered shape with a taper angle less than 90°. In the case where the end portion of the pixel electrode has a tapered shape, the layer 133R provided along the side surface of the pixel electrode has an inclined portion. When the side surface of the pixel electrode has a tapered shape, coverage with an EL layer provided along the side surface of the pixel electrode can be improved.

Since the conductive layers 124G and 126G and the conductive layers 124B and 126B are similar to the conductive layers 124R and 126R, the detailed description thereof is omitted.

The top and side surfaces of the conductive layer 126R are covered with the layer 133R. Similarly, the top and side surfaces of the conductive layers 126G are covered with the layer 133G, and the top and side surfaces of the conductive layers 126B are covered with the layer 133B. Accordingly, regions provided with the conductive layers 126R, 126G, and 126B can be entirely used as the light-emitting regions of the light-emitting elements 130R, 130G, and 130B, thereby increasing the aperture ratio of the pixels.

The side surface and part of the top surface of each of the layers 133R, 133G, and 133B are covered with insulating layers 125 and 127. The common layer 134 is provided over the layers 133R, 133G, and 133B and the insulating layers 125 and 127, and the common electrode 135 is provided over the common layer 134. The common layer 134 and the common electrode 135 are each one continuous film shared by a plurality of light-emitting elements.

In FIG. 16, the insulating layer 237 illustrated in FIG. 12 and the like is not provided between the conductive layer 126R and the layer 133R. That is, the display device 50E is not provided with an insulating layer (also referred to as a partition wall, a bank, a spacer, or the like) that is in contact with the pixel electrode and covers an upper end portion of the pixel electrode. Thus, the interval between adjacent light-emitting elements can be extremely shortened. Accordingly, the display device can have high resolution or high definition. In addition, a mask for forming the insulating layer is not needed, which leads to a reduction in manufacturing cost of the display device.

As described above, the layers 133R, 133G, and 133B each include a light-emitting layer. The layers 133R, 133G, and 133B each preferably include a light-emitting layer and a carrier-transport layer (an electron-transport layer or a hole-transport layer) over the light-emitting layer. Alternatively, the layers 133R, 133G, and 133B each preferably include a light-emitting layer and a carrier-blocking layer (a hole-blocking layer or an electron-blocking layer) over the light-emitting layer. Alternatively, the layers 133R, 133G, and 133B each preferably include a light-emitting layer, a carrier-blocking layer over the light-emitting layer, and a carrier-transport layer over the carrier-blocking layer. Since the surfaces of the layers 133R, 133G, and 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 134 includes, for example, an electron-injection layer or a hole-injection layer. Alternatively, the common layer 134 may include a stack of an electron-transport layer and an electron-injection layer, or may include a stack of a hole-transport layer and a hole-injection layer. The common layer 134 is shared by the light-emitting elements 130R, 130G, and 130B.

The side surfaces of the layers 133R, 133G, and 133B are covered with the insulating layer 125. The insulating layer 127 covers the side surfaces of the layers 133R, 133G, and 133B with the insulating layer 125 therebetween.

The side surfaces (and part of the top surfaces) of the layers 133R, 133G, and 133B are covered with at least one of the insulating layers 125 and 127, so that the common layer 134 (or the common electrode 135) can be inhibited from being in contact with the pixel electrodes and the side surfaces of the layers 133R, 133G, and 133B, leading to inhibition of a short circuit of the light-emitting elements. Thus, the reliability of the light-emitting element can be increased.

The insulating layer 125 is preferably in contact with the side surfaces of the layers 133R, 133G, and 133B. The insulating layer 125 in contact with the layers 133R, 133G, and 133B can prevent film separation of the layers 133R, 133G, and 133B, whereby the reliability of the light-emitting element can be increased.

The insulating layer 127 is provided over the insulating layer 125 to fill a concave portion defined by the insulating layer 125. The insulating layer 127 preferably covers at least part of a side surface of the insulating layer 125.

The insulating layers 125 and 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 134 and the common electrode 135 are provided over the layers 133R, 133G, and 133B and the insulating layers 125 and 127. Before the insulating layers 125 and 127 are provided, a step is generated due to a level difference between a region where the pixel electrode and the island-shaped EL layer are provided and a region where neither the pixel electrode nor the island-shaped EL layer is provided (a region between the light-emitting elements). In the display device of one embodiment of the present invention, the step can be eliminated with the insulating layers 125 and 127, and the coverage with the common layer 134 and the common electrode 135 can be improved. Thus, connection defects caused by step disconnection of the common layer 134 or the common electrode 135 can be inhibited. In addition, an increase in electric resistance, which is caused by local thinning of the common electrode 135 due to the level difference, can be inhibited.

The top surface of the insulating layer 127 preferably has a shape with high flatness. The top surface of the insulating layer 127 may include at least one of a flat surface, a convex surface, and a concave surface. For example, the top surface of the insulating layer 127 preferably has a smooth convex shape with high flatness.

The insulating layer 125 can be formed using an inorganic material. As the insulating layer 125, an inorganic insulating film such as an oxide insulating film, a nitride insulating film, an oxynitride insulating film, or a nitride oxide insulating film can be used, for example. Specific examples of these inorganic insulating films are as described above. The insulating layer 125 may have a single-layer structure or a stacked-layer structure. In particular, aluminum oxide is preferably used because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an ALD method is used as the insulating layer 125, the insulating layer 125 can have few pinholes and an excellent function of protecting the EL layer. The insulating layer 125 may have a stacked-layer structure of a film formed by an ALD method and a film formed by a sputtering method. For example, the insulating layer 125 may have a stacked-layer structure of an aluminum oxide film formed by an ALD method and a silicon nitride film formed by a sputtering method.

The insulating layer 125 preferably has a function of a barrier insulating layer against at least one of water and oxygen. The insulating layer 125 preferably has a function of inhibiting diffusion of at least one of water and oxygen. The insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a particular substance (also referred to as a function of less easily transmitting the substance). Alternatively, a barrier property refers to a function of capturing or fixing (also referred to as gettering) a particular substance.

When the insulating layer 125 has a function of a barrier insulating layer or a gettering function, it is possible to inhibit entry of impurities that would diffuse into the light-emitting elements from the outside (a substance that might induce degradation of the light-emitting element, a typical example of which is at least one of water and oxygen). With this structure, a highly reliable light-emitting element and a highly reliable display device can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, one or both of the hydrogen concentration and the carbon concentration in the insulating layer 125 are preferably sufficiently low.

The insulating layer 127 provided over the insulating layer 125 has a function of filling large unevenness of the insulating layer 125, which is formed between the adjacent light-emitting elements. In other words, the insulating layer 127 has an effect of improving the flatness of the formation surface of the common electrode 135.

As the insulating layer 127, an insulating layer including an organic material can be favorably used. As the organic material, a photosensitive organic resin is preferably used, and for example, a photosensitive resin composite including an acrylic resin is preferably used. Note that in this specification and the like, an acrylic resin refers to not only a polymethacrylic acid ester or a methacrylic resin, but also all the acrylic polymer in a broad sense in some cases.

Alternatively, the insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, the insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive-type material or a negative-type material may be used.

The insulating layer 127 may be formed using a material absorbing visible light. When the insulating layer 127 absorbs light emitted from the light-emitting element, light leakage (stray light) from the light-emitting element to the adjacent light-emitting element through the insulating layer 127 can be suppressed. Thus, the display quality of the display device can be improved. Since no polarizing plate is required to improve the display quality of the display device, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). Using the resin material obtained by stacking or mixing color filter materials of two or three or more colors is particularly preferred, in which case the effect of blocking visible light is enhanced. In particular, mixing color filter materials of three or more colors enables the formation of a black or nearly black resin layer.

The transistor of one embodiment of the present invention can be miniaturized and the area occupied by the transistor can be reduced, so that the aperture ratio of the pixel can be increased or the pixel size can be reduced in the display device having a bottom-emission structure.

This embodiment can be combined with any of the other embodiments as appropriate.

### Embodiment 3

In this embodiment, structure examples of display devices that can include the semiconductor device of one embodiment of the present invention will be described.

Since the semiconductor device of one embodiment of the present invention can be extremely minute, a display device including the semiconductor device of one embodiment of the present invention can have extremely high resolution. For example, the display device of one embodiment of the present invention can be used for display portions of information terminals (wearable devices) such as watch-type and bracelet-type information terminals and display portions of wearable devices capable of being worn on a head, such as a VR device such as a head-mounted display (HMD) and a glasses-type AR device.

### [Display Module]

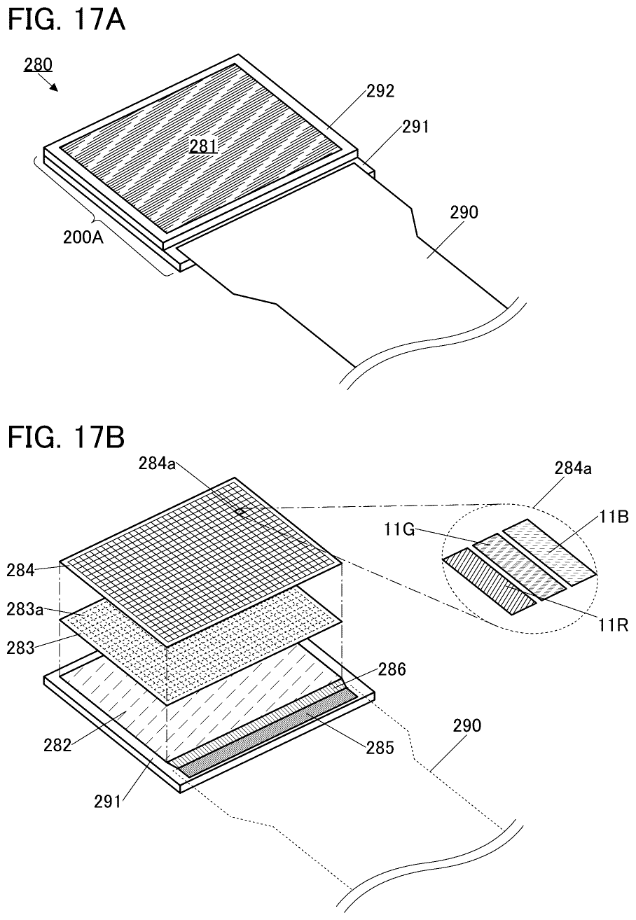

FIG. 17A is a perspective view of a display module 280. The display module 280 includes a display device 200A and an FPC 290. Note that a display panel included in the display module 280 is not limited to the display device 200A and may be a display device 200B or a display device 200C each of which will be described later.

The display module 280 includes a substrate 291 and a substrate 292. The display module 280 includes a display portion 281. The display portion 281 is a region where an image is displayed.

FIG. 17B is a perspective view schematically illustrating a structure on the substrate 291 side. Over the substrate 291, a circuit portion 282, a pixel circuit portion 283 over the circuit portion 282, and a pixel portion 284 over the pixel circuit portion 283 are stacked. In addition, a terminal portion 285 for connection to the FPC 290 is provided in a portion not overlapping with the pixel portion 284 over the substrate 291. The terminal portion 285 and the circuit portion 282 are connected to each other through a wiring portion 286 formed of a plurality of wirings.

The pixel portion 284 includes a plurality of pixels 284a arranged periodically. An enlarged view of one pixel 284a is illustrated on the right side in FIG. 17B. The pixel 284a includes the subpixel 11R that emits red light, the subpixel 11G that emits green light, and the subpixel 11B that emits blue light.

The pixel circuit portion 283 includes a plurality of pixel circuits 283a arranged periodically. One pixel circuit 283a controls light emission from three light-emitting devices included in one pixel 284a. One pixel circuit 283a may include three circuits each of which controls light emission from one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active matrix display panel is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like. A transistor included in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, or the like to the circuit portion 282 from the outside. An IC may be mounted on the FPC 290.

In the display module 280, one or both of the pixel circuit portion 283 and the circuit portion 282 can be stacked below the pixel portion 284; thus, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi and lower than or equal to 30000 ppi, preferably higher than or equal to 3000 ppi and lower than or equal to 20000 ppi, further preferably higher than or equal to 5000 ppi and lower than or equal to 20000 ppi, still further preferably higher than or equal to 6000 ppi and lower than or equal to 20000 ppi.

Such a display module 280 has extremely high resolution, and thus can be suitably used for a VR device such as a head-mounted display or a glasses-type AR device. For example, even in a structure in which the display portion of the display module 280 is seen through a lens, pixels of the extremely-high-resolution display portion 281 included in the display module 280 are prevented from being recognized when the display portion is magnified through the lens; thus, display providing a high sense of immersion can be performed. Without being limited thereto, the display module 280 can be suitably used for electronic devices including a relatively small display portion. For example, the display module 280 can be suitably used in a display portion of a wearable electronic device, such as a wrist watch.

### [Display Device 200A]

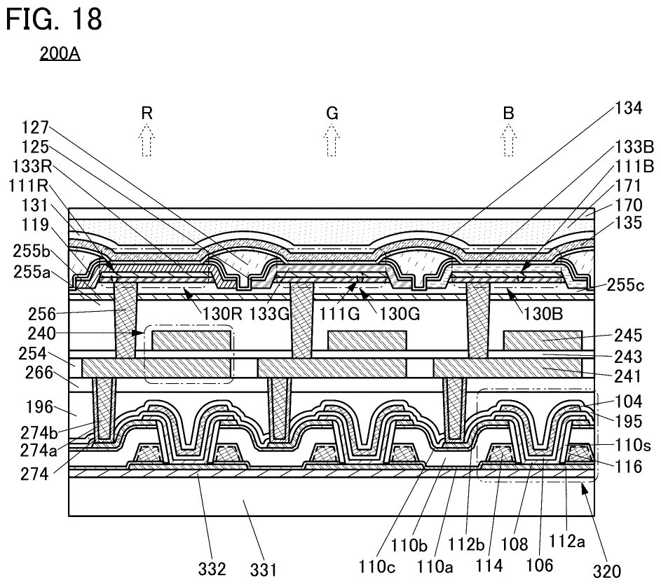

The display device 200A illustrated in FIG. 18 includes a substrate 331, the light-emitting elements 130R, 130G, and 130B, a capacitor 240, and a transistor 320. The light-emitting elements 130R, 130G, and 130B are display elements included in the subpixel 11R that emits red light, the subpixel 11G that emits green light, and the subpixel 11B that emits blue light, respectively.

The substrate 331 corresponds to the substrate 291 in FIG. 17A.

The transistor 320 is a vertical-channel transistor including an oxide semiconductor in a semiconductor layer where a channel is formed. As the transistor 320, a variety of transistors described in Embodiment 1 can be used.

An insulating layer 332 is provided over the substrate 331. The insulating layer 332 functions as a barrier layer for preventing diffusion of impurities that might adversely affect the electrical characteristics of the transistor, such as water or hydrogen, from the substrate 331 into the transistor 320 and release of oxygen from the semiconductor layer 108 to the insulating layer 332 side. As the insulating layer 332, a film in which hydrogen or oxygen is less likely to diffuse than in a silicon oxide film can be used, for example. Examples of such a film include an aluminum oxide film, a hafnium oxide film, and a silicon nitride film.

The conductive layer 112a is provided over the insulating layer 332. The insulating layer 110a, the conductive layer 114 over the insulating layer 110a, the insulating layer 110b over the conductive layer 114, and the conductive layer 112b over the insulating layer 110b are provided over the conductive layer 112a. An opening is provided in the insulating layer 110a, the conductive layer 114, the insulating layer 110b, and the conductive layer 112b. The insulating layer 110s is provided along the sidewall of the opening. The semiconductor layer 108 is provided to cover the top surface of the conductive layer 112a, the sidewall of the insulating layer 110s, and the top surface of the conductive layer 112b. The insulating layer 106 is provided over the semiconductor layer 108. The conductive layer 104 is provided over the insulating layer 106. The insulating layer 195 is provided over the insulating layer 106 and the conductive layer 104. An insulating layer 196 is provided over the insulating layer 195. The top surface of the insulating layer 196 is planarized, and an insulating layer 266 is provided over the insulating layer 196.

The insulating layers 196 and 266 each function as an interlayer insulating layer. A barrier layer for preventing impurities that might adversely affect the electrical characteristics of the transistor, such as water or hydrogen, from diffusing from the insulating layer 266 and the like into the transistor 320 may be provided between the insulating layer 266 and the insulating layer 196. As the barrier layer, an insulating film similar to the insulating layer 332 can be used.

A plug 274 connected to the conductive layer 112b is provided to be embedded in the insulating layers 266, 196, 195, and 106. Here, the plug 274 preferably includes a conductive layer 274a that covers a side surface of an opening in the insulating layers 266, 196, 195, and 106 and part of the top surface of the conductive layer 112b, and a conductive layer 274b in contact with the top surface of the conductive layer 274a. For the conductive layer 274a, a conductive material in which hydrogen and oxygen are less likely to diffuse is preferably used.

The capacitor 240 is provided over the insulating layer 266. The capacitor 240 includes a conductive layer 241, a conductive layer 245, and an insulating layer 243 between the conductive layers 241 and 245. The conductive layer 241 functions as one of the electrodes of the capacitor 240, the conductive layer 245 functions as the other electrode of the capacitor 240, and the insulating layer 243 functions as a dielectric of the capacitor 240.

The conductive layer 241 is provided over the insulating layer 266 and is embedded in an insulating layer 254. The conductive layer 241 is connected to the conductive layer 112b of the transistor 320 through the plug 274. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, an insulating layer 255b is provided over the insulating layer 255a, and an insulating layer 255c is provided over the insulating layer 255b.

An inorganic insulating film can be suitably used as each of the insulating layers 255a, 255b, and 255c. For example, it is preferable to use a silicon oxide film as the insulating layers 255a and 255c and use a silicon nitride film as the insulating layer 255b. This enables the insulating layer 255b to function as an etching protective film. Although this embodiment describes an example in which part of the insulating layer 255c is etched to form a recess portion, the recess portion is not necessarily provided in the insulating layer 255c.

The light-emitting elements 130R, 130G, and 130B are provided over the insulating layer 255c. The above embodiment can be referred to for the details of the light-emitting elements 130R, 130G, and 130B.

The light-emitting element 130R includes the pixel electrode 111R, the layer 133R, the common layer 134, and the common electrode 135. The light-emitting element 130G includes the pixel electrode 111G, the layer 133G, the common layer 134, and the common electrode 135. The light-emitting element 130B includes the pixel electrode 111B, the layer 133B, the common layer 134, and the common electrode 135. The common layer 134 and the common electrode 135 are shared by the light-emitting elements 130R, 130G, and 130B.

The layer 133R of the light-emitting element 130R includes at least a light-emitting organic compound that emits red light. The layer 133G of the light-emitting element 130G includes at least a light-emitting organic compound that emits green light. The layer 133B of the light-emitting element 130B includes at least a light-emitting organic compound that emits blue light. Each of the layers 133R, 133G, and 133B can also be referred to as an EL layer, and includes at least a layer including a light-emitting organic compound (a light-emitting layer).

In the display device 200A, since the light-emitting devices of different colors are separately formed, the difference between the chromaticity at low luminance emission and that at high luminance emission is small. Since the layers 133R, 133G, and 133B are separated from each other, crosstalk generated between adjacent subpixels can be inhibited while the display panel has high resolution. Accordingly, the display panel can have high resolution and high display quality.

In the region between adjacent light-emitting elements, an insulating layer 119, the insulating layer 125, and the insulating layer 127 are provided.

The insulating layer 119 is a remaining portion of an insulating layer (also referred to as a mask layer) provided in contact with the top surfaces of the layers 133R, 133G, and 133B at the time of processing the layers 133R, 133G, and 133B. In this manner, the mask layer used to protect the layers 133R, 133G, and 133B in manufacture of the display device of one embodiment of the present invention may partly remain in the display device. For the insulating layer 119, any of the materials that can be used for the insulating layer 125 described above can be used, for example.

The pixel electrodes 111R, 111G, and 111B of the light-emitting elements are each connected to the conductive layer 112b of the transistor 320 through a plug 256 embedded in the insulating layers 243, 255a, 255b, and 255c, the conductive layer 241 embedded in the insulating layer 254, and the plug 274. The top surface of the insulating layer 255c and the top surface of the plug 256 are level with or substantially level with each other. Any of a variety of conductive materials can be used for the plugs.

The protective layer 131 is provided over the light-emitting elements 130R, 130G, and 130B. A substrate 170 is attached above the protective layer 131 with an adhesive layer 171.

An insulating layer that covers an upper end portion of the pixel electrode 111 is not provided between two adjacent pixel electrodes 111 (the pixel electrodes 111R, 111G, and 111B). Thus, the interval between adjacent light-emitting elements can be extremely shortened. Accordingly, the display device can have high resolution or high definition.

### [Display Device 200B]

A display device having a structure partly different from the above-described structure will be described below. Note that the description of the display device 200A is referred to for common portions and the description thereof is omitted in some cases.

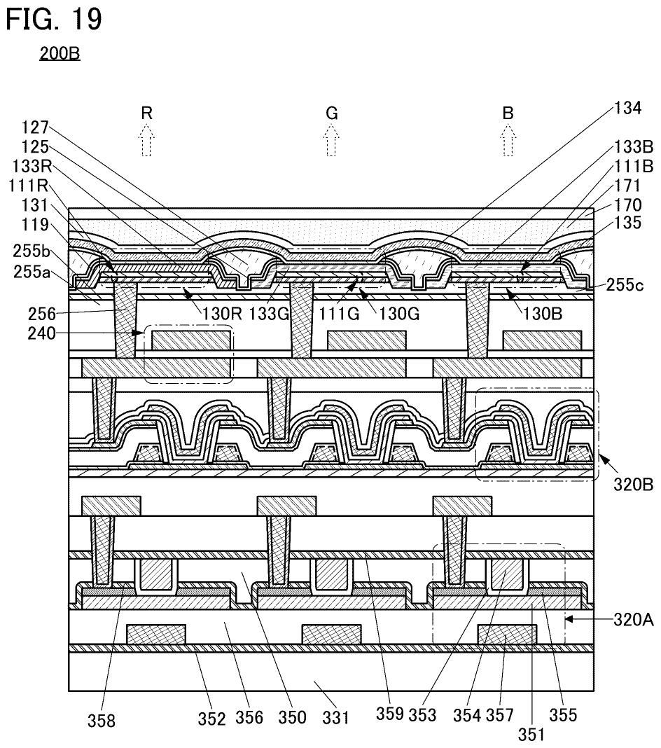

The display device 200B illustrated in FIG. 19 is an example in which a transistor 320A that is a planar transistor including a semiconductor layer formed on a plane and a transistor 320B that is a vertical-channel transistor are stacked. The transistor 320B has a structure similar to that of the transistor 320 in the display device 200A.

The transistor 320A includes a semiconductor layer 351, an insulating layer 353, a conductive layer 354, a pair of conductive layers 355, an insulating layer 356, and a conductive layer 357.

An insulating layer 352 is provided over the substrate 331. The insulating layer 352 functions as a barrier layer for preventing diffusion of impurities that might adversely affect the electrical characteristics of the transistor, such as water or hydrogen, from the substrate 331 into the transistor 320A and release of oxygen from the semiconductor layer 351 to the insulating layer 352 side. As the insulating layer 352, a film in which hydrogen or oxygen is less likely to diffuse than in a silicon oxide film can be used, for example. Examples of such a film include an aluminum oxide film, a hafnium oxide film, and a silicon nitride film.

The conductive layer 357 is provided over the insulating layer 352, and the insulating layer 356 is provided to cover the conductive layer 357. The conductive layer 357 functions as a first gate electrode of the transistor 320A, and part of the insulating layer 356 functions as a first gate insulating layer. An oxide insulating film such as a silicon oxide film is preferably used for at least a portion of the insulating layer 356 that is in contact with the semiconductor layer 351. The top surface of the insulating layer 356 is preferably planarized.

The semiconductor layer 351 is provided over the insulating layer 356. A metal oxide film having semiconductor properties (also referred to as an oxide semiconductor film) is preferably used as the semiconductor layer 351. The pair of conductive layers 355 are provided over and in contact with the semiconductor layer 351, and function as a source electrode and a drain electrode.

An insulating layer 358 and an insulating layer 350 are provided to cover the top and side surfaces of the pair of conductive layers 355, a side surface of the semiconductor layer 351, and the like. The insulating layer 358 functions as a barrier layer for preventing diffusion of impurities that might adversely affect the electrical characteristics of the transistor, such as water or hydrogen, into the semiconductor layer 351 and release of oxygen from the semiconductor layer 351. As the insulating layer 358, an insulating film similar to the insulating layer 352 can be used.

An opening reaching the semiconductor layer 351 is provided in the insulating layers 358 and 350. The insulating layer 353 that is in contact with the top surface of the semiconductor layer 351 and the conductive layer 354 are embedded in the opening. The conductive layer 354 functions as a second gate electrode, and the insulating layer 353 functions as a second gate insulating layer.

The top surface of the conductive layer 354, the top surface of the insulating layer 353, and the top surface of the insulating layer 350 are planarized so that they are level with or substantially level with each other, and an insulating layer 359 is provided to cover these layers. The insulating layer 359 functions as a barrier layer for preventing diffusion of impurities that might adversely affect the electrical characteristics of the transistor, such as water or hydrogen, into the transistor 320A. As the insulating layer 359, an insulating film similar to the insulating layer 352 can be used.

The transistor 320A employs a structure in which the semiconductor layer where a channel is formed is placed between the two gates. The two gates may be connected to each other and supplied with the same signal to operate the transistor. Alternatively, the threshold voltage of the transistor may be controlled by applying a potential for controlling the threshold voltage to one of the two gates and a potential for driving to the other gate.

### [Display Device 200C]

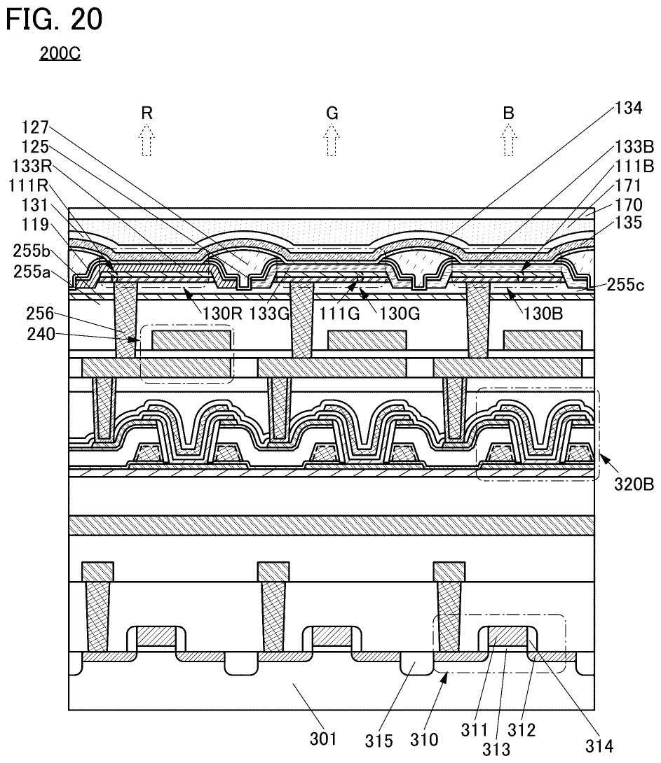

In the display device 200C illustrated in FIG. 20, a transistor 310 in which a channel is formed in a semiconductor substrate and the transistor 320B, which is a vertical-channel transistor, are stacked.

The transistor 310 includes a channel formation region in a substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is placed between the substrate 301 and the conductive layer 311 and functions as a gate insulating layer. The low-resistance regions 312 are regions where the substrate 301 is doped with an impurity serving as a dopant, and function as a source and a drain. The insulating layer 314 is provided to cover a side surface of the conductive layer 311.

An element isolation layer 315 is provided between two adjacent transistors 310 to be embedded in the substrate 301.

At least part of this embodiment can be implemented as appropriate in combination with any of the other embodiments described in this specification.

### Embodiment 4

In this embodiment, a circuit, a layout, and the like that can be employed in the display device of one embodiment of the present invention will be described.

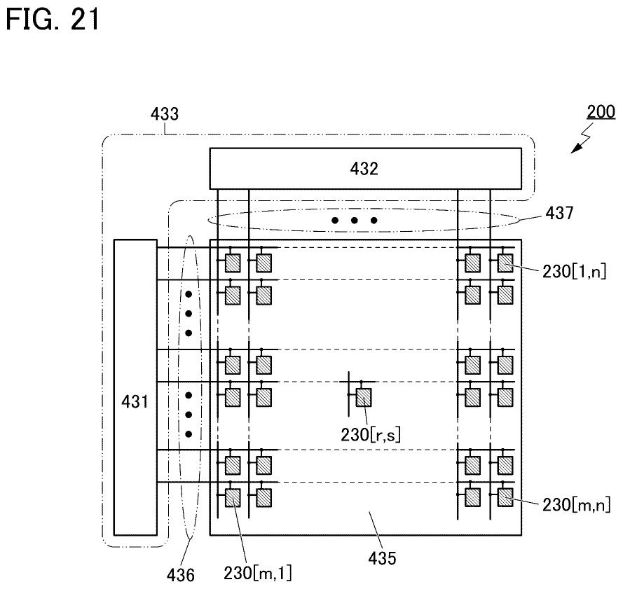

FIG. 21 is a block diagram illustrating a display device 200. The display device 200 includes a display portion 435, a first driver circuit portion 431, and a second driver circuit portion 432.

The display portion 435 includes a plurality of pixels 230 arranged in a matrix of m rows (m is an integer greater than or equal to 1) and n columns (n is an integer greater than or equal to 1).

The display portion 435 corresponds, for example, to the display portion 168 in FIG. 11. The pixel 230 corresponds, for example, to the subpixel 11R, the subpixel 11G, the subpixel 11B, and the pixel 210 in FIG. 11.

Alternatively, the display portion 435 corresponds, for example, to the display portion 281 in FIG. 17A and the pixel 230 corresponds, for example, to the subpixel 11R, the subpixel 11G, the subpixel 11B, and the pixel 284a in FIG. 17B.

In FIG. 21, the pixel 230 in the first row and the n-th column is denoted as a pixel 230[1,n], the pixel 230 in the m-th row and the first column is denoted as a pixel 230[m,1], and the pixel 230 in the m-th row and the n-th column is denoted as a pixel 230[m,n]. A given pixel 230 included in the display portion 435 is denoted as a pixel 230[r,s] in some cases. Note that r is an integer greater than or equal to 1 and less than or equal to m, and s is an integer greater than or equal to 1 and less than or equal to n.

A circuit included in the first driver circuit portion 431 functions as a scan line driver circuit, for example. A circuit included in the second driver circuit portion 432 functions as a signal line driver circuit, for example. A given circuit may be provided to face the first driver circuit portion 431 with the display portion 435 placed therebetween. A given circuit may be provided to face the second driver circuit portion 432 with the display portion 435 placed therebetween. Note that the circuits included in the first driver circuit portion 431 and the second driver circuit portion 432 are collectively referred to as a peripheral driver circuit 433.

As the peripheral driver circuit 433, a variety of circuits such as a shift register circuit, a level shifter circuit, an inverter circuit, a latch circuit, an analog switch circuit, a multiplexer circuit, a demultiplexer circuit, and a logic circuit can be used. In the peripheral driver circuit 433, the transistor 100 and the like of one embodiment of the present invention can be used. Note that a transistor included in the peripheral driver circuit and a transistor included in the pixel 230 may be formed through the same process.

The display device 200 includes m wirings 436 which are arranged substantially parallel to each other and whose potentials are controlled by the circuit included in the first driver circuit portion 431, and n wirings 437 which are arranged substantially parallel to each other and whose potentials are controlled by the circuit included in the second driver circuit portion 432.

FIG. 21 illustrates an example in which the wiring 436 and the wiring 437 are connected to the pixel 230. Note that the wirings 436 and 437 are merely examples, and wirings connected to the pixel 230 are not limited to the wirings 436 and 437.

### <Configuration Examples of Pixel Circuit>

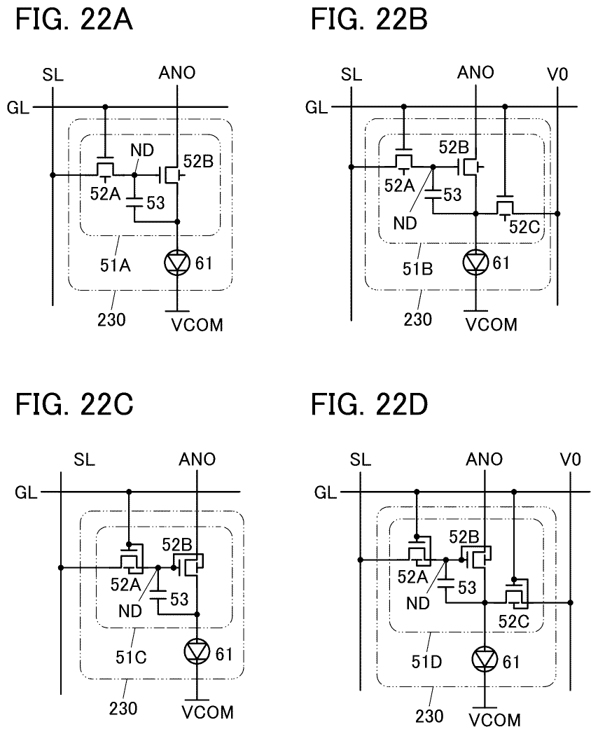

FIGS. 22A to 22D, FIGS. 23A to 23D, and FIGS. 24A and 24B illustrate configuration examples of the pixel 230. The pixel 230 includes a pixel circuit 51 (a pixel circuit 51A, a pixel circuit 51B, a pixel circuit 51C, a pixel circuit 51D, a pixel circuit 51E, a pixel circuit 51F, a pixel circuit 51G, a pixel circuit 51H, a pixel circuit 51I, or a pixel circuit 51J) and a light-emitting element 61.

A light-emitting element (also referred to as a light-emitting device) described in this embodiment and the like is a self-luminous display element such as an organic light-emitting diode (also referred to as OLED). Note that a light-emitting element connected to the pixel circuit can be a self-luminous light-emitting element such as an LED, a micro LED, a QLED, or a semiconductor laser.

The pixel circuit 51A illustrated in FIG. 22A is a 2Tr1C pixel circuit including a transistor 52A, a transistor 52B, and a capacitor 53.

One of a source and a drain of the transistor 52A is connected to a wiring SL, and a gate of the transistor 52A is connected to a wiring GL. The one of the source and the drain of the transistor 52A is connected to a gate of the transistor 52B and one terminal of the capacitor 53. One of a source and a drain of the transistor 52B is connected to a wiring ANO. The other of the source and the drain of the transistor 52B is connected to the other terminal of the capacitor 53 and an anode of the light-emitting element 61. A cathode of the light-emitting element 61 is connected to a wiring VCOM. A region where the other of the source and the drain of the transistor 52A, the gate of the transistor 52B, and the one terminal of the capacitor 53 are connected serves as a node ND.

The wiring GL corresponds to the wiring 436, and the wiring SL corresponds to the wiring 437. The wiring VCOM supplies a potential for supplying a current to the light-emitting element 61. The transistor 52A has a function of controlling electrical continuity between the wiring SL and the gate of the transistor 52B in accordance with the potential of the wiring GL. For example, VDD is supplied to the wiring ANO, and VSS is supplied to the wiring VCOM.

When the transistor 52A is turned on, an image signal is supplied from the wiring SL to the node ND. Then, the transistor 52A is turned off, whereby the image signal is held at the node ND. In order to surely hold the image signal supplied to the node ND, a transistor with a low off-state current is preferably used as the transistor 52A. For example, an OS transistor is preferably used as the transistor 52A.

The transistor 52B has a function of controlling the amount of current flowing through the light-emitting element 61. The capacitor 53 has a function of holding a gate potential of the transistor 52B. The intensity of light emitted from the light-emitting element 61 is controlled in accordance with an image signal supplied to the gate of the transistor 52B (the node ND).

In the pixel circuit 51A illustrated in FIG. 22A, each of the transistors 52A and 52B includes a back gate. A signal line or a power supply line can be connected to the back gate to supply a given potential. Alternatively, the back gate may be connected to the ground. The back gate may be connected to the gate. The back gate may be connected to the source or the drain. Although both the transistors have back gates in this example, only one of the transistors may have a back gate.

The pixel circuit 51B illustrated in FIG. 22B is a 3Tr1C pixel circuit including the transistor 52A, the transistor 52B, a transistor 52C, and the capacitor 53. The pixel circuit 51B in FIG. 22B has a configuration in which the transistor 52C is added to the pixel circuit 51A in FIG. 22A.

One of a source and a drain of the transistor 52C is connected to the other of the source and the drain of the transistor 52B. The other of the source and the drain of the transistor 52C is connected to a wiring V0. For example, a reference potential is supplied to the wiring V0.

The transistor 52C has a function of controlling electrical continuity between the other of the source or the drain of the transistor 52B and the wiring V0 in accordance with the potential of the wiring GL. The wiring V0 is a wiring for supplying the reference potential. When an n-channel transistor is used as the transistor 52B, variations in the gate-source voltage of the transistor 52B can be reduced by the reference potential of the wiring V0 supplied through the transistor 52C.

A current value that can be used for setting of pixel parameters can be obtained with the use of the wiring V0. Specifically, the wiring V0 can function as a monitor line for outputting a current flowing through the transistor 52B or a current flowing through the light-emitting element 61 to the outside. A current output to the wiring V0 is converted into a voltage by a source follower circuit or the like and can be output to the outside. Alternatively, the current is converted into a digital signal by an A/D converter or the like and can be output to the outside.

In the pixel circuit 51B illustrated in FIG. 22B, the transistor 52A, the transistor 52B, and the transistor 52C each include a back gate. A signal line or a power supply line can be connected to the back gate to supply a given potential. Alternatively, the back gate may be connected to the ground. The back gate may be connected to the gate. The back gate may be connected to the source or the drain. Although all the transistors have back gates in this example, only some of the transistors may have back gates.

The pixel circuit 51C illustrated in FIG. 22C is an example in which a transistor including a gate and a back gate that are connected to each other is used as each of the transistors 52A and 52B of the pixel circuit 51A. The pixel circuit 51D illustrated in FIG. 22D is an example of the case where such transistors are used in the pixel circuit 51B. With these configurations, a current that can flow through the transistors can be increased. Although a transistor including a gate and a back gate connected to each other is used as each of the transistors here, one embodiment of the present invention is not limited thereto. A transistor that includes a gate and a back gate that are connected to different wirings may be used. For example, with the use of a transistor in which one of a gate and a back gate is connected to a source, the reliability can be increased.

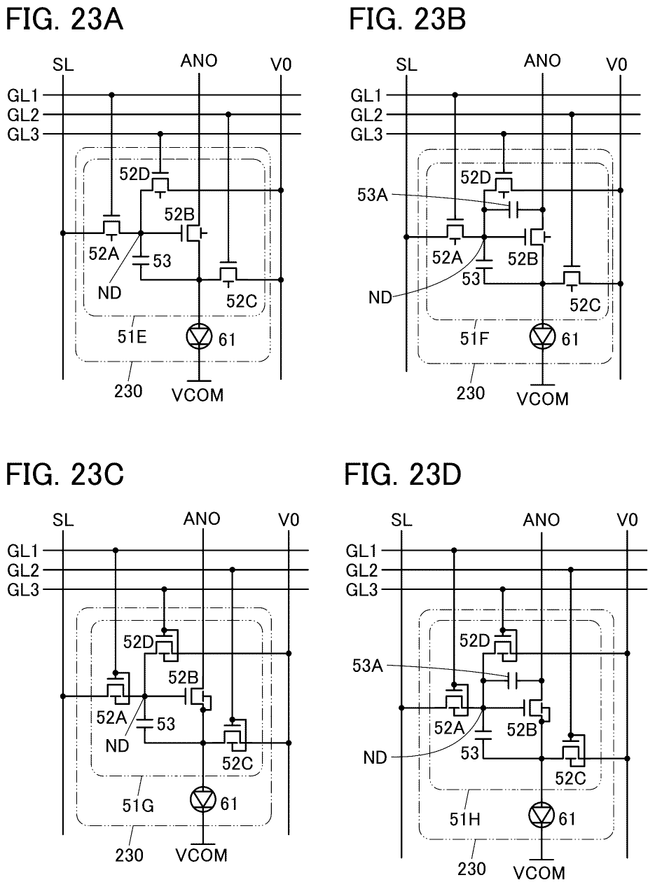

The pixel circuit 51E illustrated in FIG. 23A has a configuration in which a transistor 52D is added to the pixel circuit 51B in FIG. 22B. The pixel circuit 51E illustrated in FIG. 23A is a 4Tr1C pixel circuit including the transistor 52A, the transistor 52B, the transistor 52C, the transistor 52D, and the capacitor 53.

One of a source and a drain of the transistor 52D is connected to the node ND, and the other is connected to the wiring V0. The transistor 52D includes a back gate.

A wiring GL1, a wiring GL2, and a wiring GL3 are connected to the pixel circuit 51E. The wiring GL1 is connected to the gate of the transistor 52A, the wiring GL2 is connected to the gate of the transistor 52C, and the wiring GL3 is connected to a gate of the transistor 52D. In this embodiment and the like, the wirings GL1, GL2, and GL3 are collectively referred to as the wiring GL in some cases. Thus, the wiring GL may be one wiring or a plurality of wirings.

When the transistors 52C and 52D are turned on at the same time, the source and the gate of the transistor 52B have the same potential, so that the transistor 52B can be turned off. Thus, a current flowing to the light-emitting element 61 can be blocked forcibly. Such a pixel circuit is suitable for the case of using a display method in which a display period and an off period are alternately provided.

The pixel circuit 51F illustrated in FIG. 23B is an example in which a capacitor 53A is added to the pixel circuit 51E. The capacitor 53A functions as a storage capacitor. The pixel circuit 51E illustrated in FIG. 23A is a 4Tr1C pixel circuit. The pixel circuit 51F illustrated in FIG. 23B is a 4Tr2C pixel circuit.

The pixel circuit 51G illustrated in FIG. 23C and the pixel circuit 51H illustrated in FIG. 23D have configurations changed from the pixel circuit 51E and the pixel circuit 51F, respectively; specifically, the back gates of the transistors 52A, 52C, and 52D are connected to the respective gates, and the back gate of the transistor 52B is connected to the source thereof.

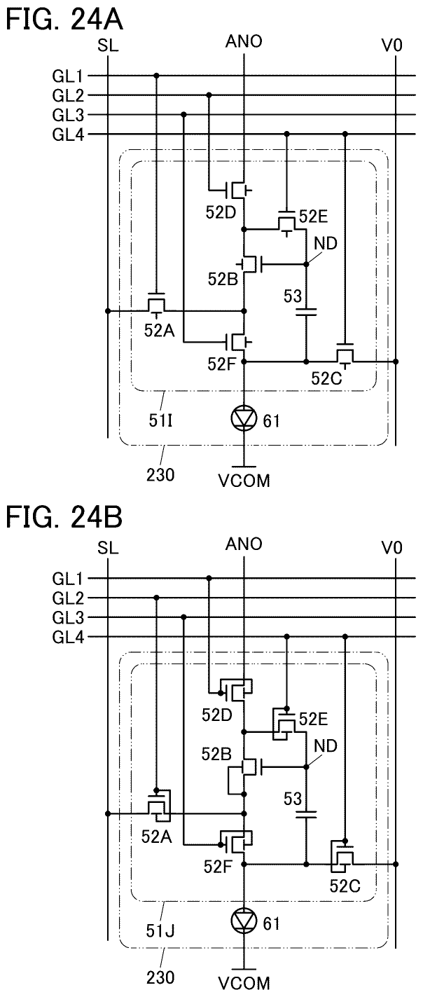

The pixel circuit 51I illustrated in FIG. 24A is a 6Tr1C pixel circuit including the transistor 52A, the transistor 52B, the transistor 52C, the transistor 52D, a transistor 52E, a transistor 52F, and the capacitor 53. Each of the transistors 52A to 52F includes a back gate.

One of the source and the drain of the transistor 52A is connected to the wiring SL, and the gate of the transistor 52A is connected to the wiring GL1. One of the source and the drain of the transistor 52D is connected to the wiring ANO, and the gate of the transistor 52D is connected to the wiring GL2. The other of the source and the drain of the transistor 52D is connected to one of the source and the drain of the transistor 52B. The other of the source and the drain of the transistor 52B is connected to the other of the source and the drain of the transistor 52A and one of a source and a drain of the transistor 52F. A gate of the transistor 52F is connected to the wiring GL3.

One of a source and a drain of the transistor 52E is connected to the other of the source and the drain of the transistor 52D and the one of the source and the drain of the transistor 52B. The other of the source and the drain of the transistor 52E is connected to the gate of the transistor 52B and one terminal of the capacitor 53. The other terminal of the capacitor 53 is connected to the other of the source and the drain of the transistor 52F, the anode of the light-emitting element 61, and one of the source and the drain of the transistor 52C. A gate of the transistor 52E and the gate of the transistor 52C are connected to a wiring GL4. The other of the source and the drain of the transistor 52C is connected to the wiring V0. A region where the other of the source and the drain of the transistor 52E, the gate of the transistor 52B, and the one terminal of the capacitor 53 are connected serves as the node ND.

FIG. 24B illustrates a configuration in which the back gates of the transistors 52A, 52C, 52D, 52E, and 52F are connected to the respective gates, and the back gate of the transistor 52B is connected to the other of the source and the drain thereof.

With the use of the transistor 100 and the like of one embodiment of the present invention in a pixel circuit of a display device, the area occupied by the pixel circuit can be reduced. Thus, the resolution of the display device can be increased. For example, it is possible to achieve a display device with a resolution higher than or equal to 1000 ppi and lower than or equal to 10000 ppi, preferably higher than or equal to 2000 ppi and lower than or equal to 9000 ppi, further preferably higher than or equal to 3000 ppi and lower than or equal to 8000 ppi, still further preferably higher than or equal to 4000 ppi and lower than or equal to 8000 ppi, yet still further preferably higher than or equal to 5000 ppi and lower than or equal to 8000 ppi, yet still further preferably higher than or equal to 6000 ppi and lower than or equal to 8000 ppi.

The reduction in the area occupied by the pixel circuit can increase the number of pixels (definition) of the display device. For example, it is possible to achieve a display device with an extremely high definition of HD (number of pixels: 1280×720), FHD (number of pixels: 1920×1080), WQHD (number of pixels: 2560×1440), WQXGA (number of pixels: 2560×1600), 4K2K (number of pixels: 3840×2160), or 8K4K (number of pixels: 7680×4320).

Accordingly, with the use of the transistor 100 and the like of one embodiment of the present invention in the pixel circuit of the display device, the display quality of the display device can be increased. Moreover, the aperture ratio of pixels can be increased in a bottom-emission display device including EL elements. A pixel with a high aperture ratio can have a lower current density than a pixel with a low aperture ratio when these pixels emit light with the same luminance. Thus, the reliability of the display device can be increased.

The structures described in this embodiment can be used in combination with any of the structures described in the other embodiments as appropriate.

### Embodiment 5

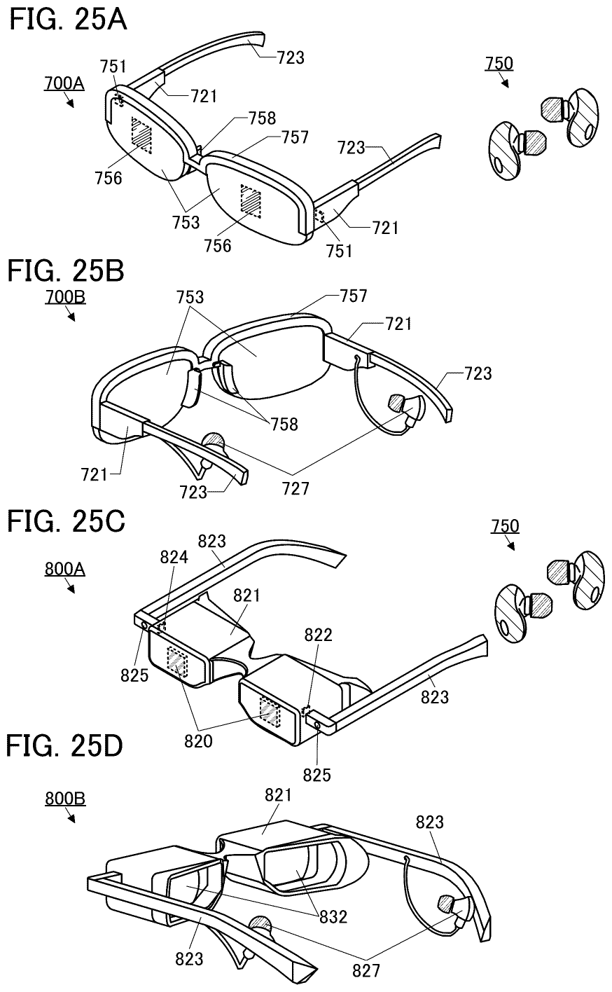

In this embodiment, electronic devices of one embodiment of the present invention will be described with reference to FIGS. 25A to 27G.

Electronic devices in this embodiment are each provided with the display device of one embodiment of the present invention in a display portion. The display device of one embodiment of the present invention can be easily increased in resolution and definition. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook personal computers, a monitor of a computer or the like, digital signage, and a large game machine such as a pachinko machine.

In particular, the display device of one embodiment of the present invention can have a high resolution and thus can be favorably used for an electronic device having a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, definition of 4K, 8K, or higher is preferable. The pixel density (resolution) of the display device of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of data (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIGS. 25A to 25D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 25A and an electronic device 700B illustrated in FIG. 25B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices are capable of performing ultrahigh-resolution display.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic devices 700A and 700B are electronic devices capable of AR display.

In the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic devices 700A and 700B are each provided with a battery (not illustrated) so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be used for the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 25C and an electronic device 800B illustrated in FIG. 25D each include a pair of display portions 820, a housing 821, a communication portion 822, a pair of mounting portions 823, a control portion 824, a pair of image capturing portions 825, and a pair of lenses 832.

The display device of one embodiment of the present invention can be used in the display portions 820. Thus, the electronic devices are capable of performing ultrahigh-resolution display. Such electronic devices provide a high sense of immersion to the user.

The display portions 820 are provided at positions where the user can see through the lenses 832 inside the housing 821. When the pair of display portions 820 display different images, three-dimensional display using parallax can be performed.

The electronic devices 800A and 800B can be regarded as electronic devices for VR. The user who wears the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be mounted on the user's head with the wearing portions 823. FIG. 25C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portion 825 is provided is shown here, a range sensor (hereinafter also referred to as a sensing portion) capable of measuring a distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that serves as a bone-conduction earphone. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic device 800A.

The electronic devices 800A and 800B may each include an input terminal. To the input terminal, a cable for supplying a video signal from a video output device or the like, electric power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 25A has a function of transmitting information to the earphones 750 with the wireless communication function. As another example, the electronic device 800A in FIG. 25C has a function of transmitting information to the earphones 750 with the wireless communication function.

The electronic device may include an earphone portion. The electronic device 700B in FIG. 25B includes earphone portions 727. For example, the earphone portion 727 can be connected to the control portion by wire. Part of a wiring that connects the earphone portion 727 and the control portion may be positioned inside the housing 721 or the mounting portion 723.

Similarly, the electronic device 800B in FIG. 25D includes earphone portions 827. For example, the earphone portion 827 can be connected to the control portion 824 by wire. Part of a wiring that connects the earphone portion 827 and the control portion 824 may be positioned inside the housing 821 or the mounting portion 823. Alternatively, the earphone portions 827 and the wearing portions 823 may include magnets. This structure is preferably employed, in which case the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 700A and 700B) and the goggles-type device (e.g., the electronic devices 800A and 800B) are preferable as the electronic device of one embodiment of the present invention.

The electronic device of one embodiment of the present invention can transmit information to earphones by wire or wirelessly.

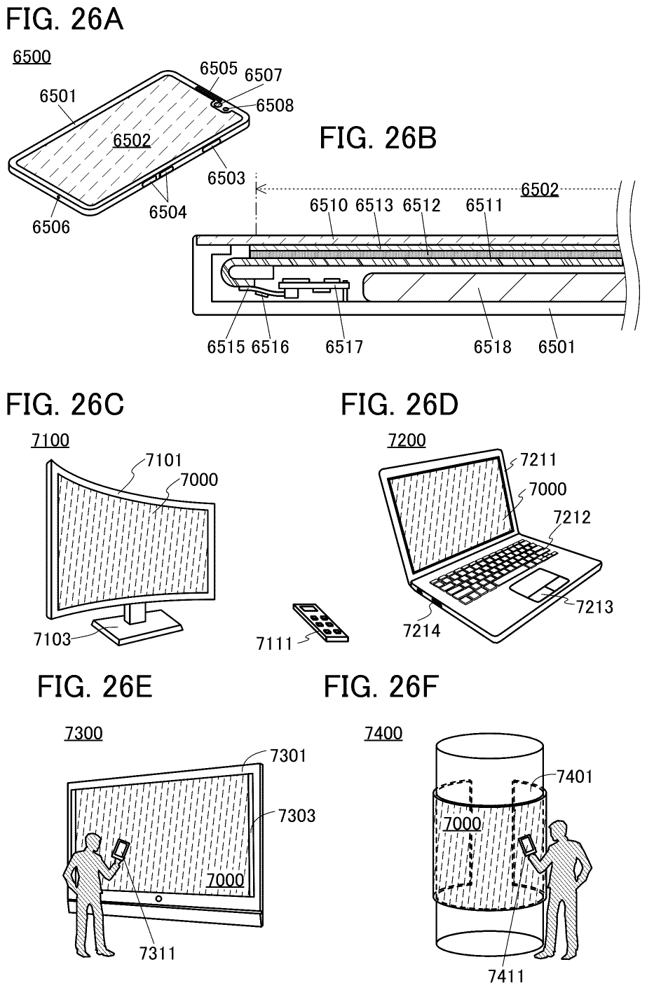

The electronic device 6500 in FIG. 26A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 26B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the display portion 6502, whereby an electronic device with a narrow bezel can be achieved.

FIG. 26C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 26C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 is provided with a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 26D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIGS. 26E and 26F illustrate examples of digital signage.

Digital signage 7300 illustrated in FIG. 26E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 26F is digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIGS. 26E and 26F.

A larger area of the display portion 7000 allows a larger amount of information to be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by the user is possible. Moreover, for an application for providing information such as route information or traffic information, usability can be enhanced by intuitive operation.

As illustrated in FIGS. 26E and 26F, it is preferable that the digital signage 7300 or the digital signage 7400 can work with an information terminal 7311 or an information terminal 7411, such as a smartphone that the user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

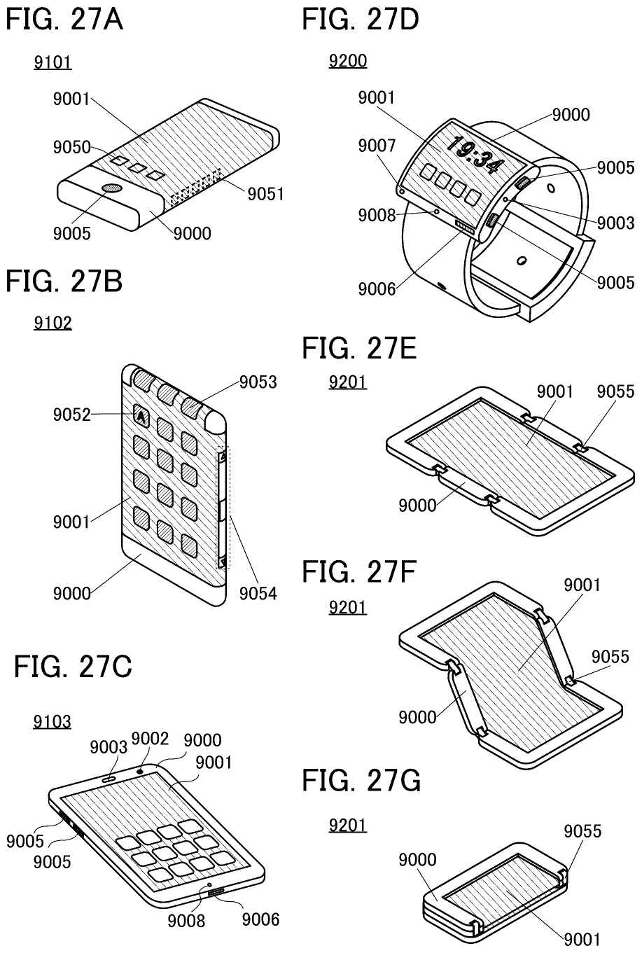

Electronic devices illustrated in FIGS. 27A to 27G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

In FIGS. 27A to 27G, the display device of one embodiment of the present invention can be used in the display portion 9001.

The electronic devices illustrated in FIGS. 27A to 27G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices illustrated in FIGS. 27A to 27G will be described in detail below.

FIG. 27A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 27A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 27B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 27C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 27D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 27E to 27G are perspective views of a foldable portable information terminal 9201. FIG. 27E is a perspective view showing the portable information terminal 9201 that is opened. FIG. 27G is a perspective view showing the portable information terminal 9201 that is folded. FIG. 27F is a perspective view showing the portable information terminal 9201 that is shifted from one of the states in FIGS. 27E and 27G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments as appropriate.

This application is based on Japanese Patent Application Serial No. 2023-149375 filed with Japan Patent Office on Sep. 14, 2023, the entire contents of which are hereby incorporated by reference.

What is claimed is:

1. A semiconductor device comprising:
a first insulating layer;
a second insulating layer;
a third insulating layer; and
a transistor comprising:
a semiconductor layer;
a first conductive layer;
a second conductive layer;
a third conductive layer;
a fourth conductive layer;
a fourth insulating layer;
a fifth insulating layer; and
a sixth insulating layer,
wherein the first conductive layer, the first insulating layer, the third conductive layer, the fifth insulating layer, the second insulating layer, the third insulating layer, and the second conductive layer are stacked in this order and overlap with one another,
wherein the first insulating layer, the third conductive layer, the second insulating layer, the third insulating layer, and the second conductive layer comprise an opening reaching the first conductive layer,
wherein the first insulating layer comprises a portion protruding in the opening more than a side surface of the third conductive layer, a side surface of the second insulating layer, a side surface of the third insulating layer, and a side surface of the second conductive layer,
wherein the fifth insulating layer is in contact with a top surface of the third conductive layer and side surfaces including the side surface of the third conductive layer,
wherein the fourth insulating layer is in contact with a top surface of the first insulating layer in the opening, a side surface of the fifth insulating layer in the opening, and the side surface of the second insulating layer in the opening,
wherein the semiconductor layer is in contact with a top surface of the first conductive layer in the opening, a side surface of the fourth insulating layer in the opening, and a top surface of the second conductive layer,
wherein the sixth insulating layer is in contact with a top surface of the semiconductor layer,
wherein the fourth conductive layer is placed over the sixth insulating layer to overlap with the opening in a plan view,
wherein the third conductive layer comprises a first element, and
wherein the fifth insulating layer comprises an oxide of the first element.

2. The semiconductor device according to claim 1,
wherein the semiconductor layer comprises a metal oxide,
wherein the metal oxide comprises two or three selected from indium, an element M, and zinc,
wherein the element M comprises one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium, and
wherein the fourth insulating layer comprises silicon oxide or silicon oxynitride.

3. The semiconductor device according to claim 1,
wherein the third conductive layer comprises aluminum, and
wherein the fifth insulating layer comprises aluminum oxide.

4. The semiconductor device according to claim 1,
wherein the first insulating layer and the third insulating layer each comprise silicon nitride, silicon nitride oxide, hafnium oxide, or aluminum oxide, and
wherein the second insulating layer comprises silicon oxide or silicon oxynitride.

5. A semiconductor device comprising:
a first insulating layer;
a second insulating layer;
a third insulating layer; and
a transistor comprising:
a semiconductor layer;
a first conductive layer;
a second conductive layer;
a third conductive layer;
a fourth insulating layer;
a fifth insulating layer; and
a sixth insulating layer,
wherein the first conductive layer, the first insulating layer, the second conductive layer, the fifth insulating layer, the second insulating layer, and the third insulating layer are stacked in this order and overlap with one another,
wherein the first insulating layer, the second conductive layer, the second insulating layer, and the third insulating layer comprise an opening reaching the first conductive layer,
wherein the first insulating layer comprises a portion protruding in the opening more than a side surface of the second conductive layer, a side surface of the second insulating layer, and a side surface of the third insulating layer,
wherein the fifth insulating layer is in contact with a top surface of the second conductive layer and side surfaces including the side surface of the second conductive layer,
wherein the fourth insulating layer is in contact with a top surface of the first insulating layer in the opening, a side surface of the fifth insulating layer in the opening, and the side surface of the second insulating layer in the opening,
wherein the semiconductor layer is in contact with a top surface of the first conductive layer in the opening, a side surface of the fourth insulating layer in the opening, and a top surface of the third insulating layer,
wherein the sixth insulating layer is in contact with a top surface of the semiconductor layer,
wherein the third conductive layer is placed over the sixth insulating layer to overlap with the opening in a plan view,
wherein the second conductive layer comprises a first element, and
wherein the fifth insulating layer comprises an oxide of the first element.

6. The semiconductor device according to claim 5,
wherein the semiconductor layer comprises a metal oxide,
wherein the metal oxide comprises two or three selected from indium, an element M, and zinc,
wherein the element M comprises one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium, and
wherein the fourth insulating layer comprises silicon oxide or silicon oxynitride.

7. The semiconductor device according to claim 5,
wherein the second conductive layer comprises aluminum, and
wherein the fifth insulating layer comprises aluminum oxide.

8. The semiconductor device according to claim 5,
wherein the first insulating layer and the third insulating layer each comprise silicon nitride, silicon nitride oxide, hafnium oxide, or aluminum oxide, and
wherein the second insulating layer comprises silicon oxide or silicon oxynitride.

9. A method for manufacturing a semiconductor device, comprising:
forming a first conductive layer;
forming a first insulating film over the first conductive layer;
forming a second conductive layer over the first insulating film to comprise a region overlapping with the first conductive layer;
oxidizing a surface of the second conductive layer, thereby forming a first insulating layer on a top surface and a side surface of the second conductive layer;
forming a second insulating film, a third insulating film, and a third conductive layer in this order over the first insulating film and the first insulating layer;
partly removing the third conductive layer, the third insulating film, the second insulating film, the first insulating layer, and the second conductive layer, thereby forming a first opening and forming a fourth conductive layer, a second insulating layer, a third insulating layer, a fourth insulating layer, and a fifth conductive layer;
oxidizing a side surface of the fifth conductive layer exposed in the first opening, thereby forming the fourth insulating layer on the side surface of the fifth conductive layer;
forming a fourth insulating film in contact with a top surface of the fourth conductive layer, a side surface of the fourth conductive layer in the first opening, a side surface of the second insulating layer in the first opening, a side surface of the third insulating layer in the first opening, a side surface of the fourth insulating layer in the first opening, and a top surface of the first insulating film in the first opening;
partly removing the fourth insulating film and the first insulating film, thereby forming a second opening reaching the first conductive layer and forming a fifth insulating layer comprising a protruding portion in the second opening and a sixth insulating layer in contact with the side surface of the fourth conductive layer in the second opening, the side surface of the second insulating layer in the second opening, the side surface of the third insulating layer in the second opening, the side surface of the fourth insulating layer in the second opening, and a top surface of the protruding portion in the second opening;
forming a semiconductor layer in contact with the top surface of the fourth conductive layer, a side surface of the sixth insulating layer in the second opening, and a top surface of the first conductive layer in the second opening;
forming a seventh insulating layer in contact with a top surface and a side surface of the semiconductor layer, the top surface of the fourth conductive layer, and a top surface of the second insulating layer; and
forming, over the seventh insulating layer, a sixth conductive layer comprising a region overlapping with the semiconductor layer and the sixth insulating layer in a plan view.

10. The method for manufacturing a semiconductor device, according to claim 9,
wherein the first insulating film is partly removed when the first opening is formed, thereby forming an eighth insulating layer comprising a recess portion in a region overlapping with the first opening.
